(19) United States
(12) Patent Application Publication
(10) Pub. No.: US 2025/0228059 A1
(43) Pub. Date: Jul. 10, 2025

(54) PHOTOVOLTAIC CELL AND METHODS OF FABRICATING SAME

(71) Applicants: AUSTRALIAN NATIONAL UNIVERSITY, Australian Capital Territory (AU); THE UNIVERSITY OF MELBOURNE, Victoria (AU)

(72) Inventors: Heping SHEN, Evatt, Australian Capital Territory (AU); Sieu Pheng PHANG, Throsby, Australian Capital Territory (AU); Leiping DUAN, Issacs, Australian Capital Territory (AU); Kylie CATCHPOLE, Waramanga, Australian Capital Territory (AU); Daniel Harold MACDONALD, Watson, Australian Capital Territory (AU); Rabin BASNET, Phillip, Australian Capital Territory (AU); Josua Andreas STÜCKELBERGER, Zurich (CH); James BULLOCK, Ascot Vale, Victoria (AU); Di YAN, Caulfield, Victoria (AU); Jose de Jesus IBARRA MICHEL, Dresden (DE)

(21) Appl. No.: 18/853,669

(22) PCT Filed: Apr. 8, 2023
(86) PCT No.: PCT/AU2023/050286

§ 371 Date: Oct. 2, 2024

(30) Foreign Application Priority Data
Apr. 8, 2022 (AU) 2022900935

(51) Int. Cl. H10K 30/86; H10K 30/40; H10K 30/57; H10K 85/60

(52) U.S. Cl. CPC H10K 30/86; H10K 30/40; H10K 30/57; H10K 85/626

(57) ABSTRACT

The invention relates to (i) a photovoltaic cell, comprising: an absorber layer comprising a perovskite material; and an ultrathin hole-transport layer; (ii) a photovoltaic cell comprising an absorber layer comprising perovskite material, a 5 hole transport layer and a protective layer located between the absorber layer and the hole transport layer, the protective layer having a valence band with an energy level that is between the energy levels of the valence bands of the absorber layer and the hole transport layer; and (iii) a photovoltaic cell comprising a barrier layer located between inner cell layers and an electrode and configured to suppress 0 diffusion of metal from the electrode into the inner layers. Also disclosed are methods of fabricating said photovoltaic cells and methods of fabricating a doped precursor for use in fabricating a photovoltaic cell.

### CROSS REFERENCE TO RELATED APPLICATION

The present application claims priority from Australian Provisional Patent Application No. 2022900935, the entire contents of which are incorporated herein by reference.

### TECHNICAL FIELD

This disclosure relates to photovoltaic cells, including tandem photovoltaic cells, and methods of fabricating the same.

### BACKGROUND ART

Photovoltaic cells, or solar cells as they are more commonly known, are one of the most important technologies driving the renewable energy revolution. Research into solar cells has resulted in significant gains in conversion efficiency. However, it remains desirable to improve the efficiency of photovoltaic modules. Higher efficiency photovoltaic modules can allow the fabrication of a system that is more compact thereby reducing the balance-of-system costs (i.e. the same amount of electricity can be generated with a smaller area panel or with less panels thus resulting in lower balance-of-system costs).

It is desirable to reduce absorption losses while maintaining or increasing voltage in photovoltaic cells generally. In addition, single junction solar cells have an upper efficiency limit (the Shockley-Queisser limit) beyond which efficiency cannot be improved. Given this, one of the strategies to improve efficiency of photovoltaic modules is through the use of a tandem cells.

Tandem cells incorporate multiple sub-cells, comprising materials with different absorption properties, that allow a more efficient light transfer from the solar spectrum. In particular, tandem cells integrate a high-efficiency wide-bandgap upper solar cell with a low-bandgap bottom solar cell to improve overall efficiency.

Tandem configurations allow the high-energy photons to be absorbed in the upper sub-cell, which can generate a high voltage to reduce thermalization loss and allow the lower sub-cell to absorb lower-energy photons (which have been transmitted through the upper sub-cell), thus enabling broader energy harvesting.

Due to its band gap properties, silicon solar cells are often used as the lower sub-cells in tandem configurations. Silicon heterojunction (SHJ) lower sub-cells, dominate tandem research. In order to develop tandem configurations suitable for commercial-scale production, it is desirable to optimise the performance and costs of the lower sub-cell, as well as its compatibility with the subsequent process steps associated with forming the tandem configuration. For example, there are limitations on the consumption of indium, which can affect the commercial implementation of certain solar cell structures to be incorporated in a tandem configuration.

Accordingly, it is desired to address the above or at least provide a useful alternative.

### SUMMARY

A first aspect of the present invention provides a photovoltaic cell, comprising an absorber layer comprising a perovskite material; and an ultrathin hole-transport layer.

In some embodiments, the photovoltaic cell comprises, in order relative to incident light said cell is configured to receive:
a first carrier-selective transport layer;
the absorber layer comprising a perovskite material; and
a second carrier-selective transport layer;
   wherein one of the first carrier-selective transport layer or the second carrier-selective transport layer is an ultrathin hole-transport layer.

A second variant of the first aspect provides embodiments wherein said cell is a tandem photovoltaic cell comprising, in order relative to incident light said cell is configured to receive:
a first sub-cell; and
a second sub-cell;
said first sub-cell comprising:
   the absorber layer; and
   the ultrathin hole-transport layer.

In some embodiments, the photovoltaic cell comprises an interconnecting layer between the second carrier-selective transport layer and the second sub-cell.

In some embodiments, the second carrier-selective transport layer directly contacts the second sub-cell.

In some embodiments, the ultrathin hole-transport layer has a thickness of less than 100 nm. In some embodiments, the ultrathin hole-transport layer has a thickness of less than 50 nm. In some embodiments, the ultrathin hole-transport layer has a thickness between about 5 nm and about 35 nm. In some embodiments, the ultrathin hole-transport layer has a thickness between about 5 nm and about 25 nm. In some embodiments, the ultrathin hole-transport layer has a thickness greater than the largest contour interval in surface roughness of a layer underlying the ultrathin hole-transport layer.

The hole-transport layer may comprise a material selected from the group consisting of: (2,2′,7,7′-Tetra(N,N-di-p-tolyl)amino-9,9-spirobifluorene) (Spiro-TTB); Poly[bis(4-phenyl)(2,4,6-trimethylphenyl)amine](PTAA), Poly(3-hexylthiophene-2,5-diyl) (P3HT); Poly [[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]](PTB7); Poly[(2,6-(4,8-bis(5-(2-ethylhexyl-3-fluoro)thiophen-2-yl)-benzo[1,2-b:4,5-b′]dithiophene))-alt-5,5′-(5,8-bis(4-(2-butyloctyl)thiophen-2-yl)dithieno[3′,2′:3,4;2″,3″:5,6]benzo[1,2-c][1,2,5]thiadiazole)](D18); Poly[(2,6-(4,8-bis(5-(2-ethylhexyl)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5‘-c’]dithiophene-4,8-dione)](PBDB-T); Poly[(5,6-difluoro-2,1,3-benzothiadiazol-4,7-diyl)-alt-(3,3′″-di(2-octyldodecyl)-2,2′;5′,2″;5″,2′″-quaterthiophen-5,5′″-diyl)](PffBT4T-2OD); Tris(8-hydroxyquinoline)aluminium (Alq3); 2,4,5,6-Tetra(9H-carbazol-9-yl)isophthalonitrile (4CzIPN); Tris[2-phenylpyridine]iridium(III) (Ir(ppy)3); F2Irpic, Ir(diFppy)2(pic) (FIrPic); 2,5,8,11-Tetrakis(1,1-dimethylethyl)perylene; 2,5,8,11-Tetra-tert-butylperylene (TBPe); Bis[2-(2-pyridinyl-N)phenyl-C](acetylacetonato)iridium(III) (Ir(ppy)2(acac)); Tris(1-phenylisoquinoline)iridium(III) (Ir(piq)3); Bis(1-phenylisoquinoline)(acetylacetonate)iridium(III) (Ir(piq)2(acac)); 5,6,11,12-Tetraphenylnaphthacene (Rubrene); 1,2-Bis(carbazol-9-yl)-4,5-dicyanobenzene (2CzPN), Tetraphenyldibenzoperiflanthene; Dibenzo{[f,f′]-4,4′,7,7′-tetraphenyl}diindeno[1,2,3-cd:1′,2′,3′-lm]perylene (DBP); 4-(Dicyanomethylene)-2-tert-butyl-6-(1,1,7,7-tetramethyljulolidin-4-yl-vinyl)-4H-pyran (DCJTB); 2-Methyl-9,10-bis(naphthalen-2-yl)anthracene, 2-Methyl-9,10-di(2-naphthyl)anthracene (MADN); 10-(2-Benzothiazolyl)-2,3,6,7-tetrahydro-1,1,7,7-tetramethyl-1H,5H,11H-(1)benzopyropyrano(6,7-8-I,j)quinolizin-11-one(C545T); Bis[2-(2-quinolinyl)phenyl](2,2,6,6-tetramethyl-3,5-heptanedionato)iridium (Ir(dpm)PQ2); Bis(2-(3,5-dimethylphenyl)quinoline-C2,N′)(acetylacetonato)iridium(III) (Ir(dmpq)2(acac)); Tris(1-phenylpyrazolato)iridium (Ir(ppz)₃); 2,3,4,5,6-pentakis(3,6-di-tert-butyl-9H-carbazol-9-yl)benzonitrile (5TCzBN); 2,3,5,6-Tetrakis(3,6-di-tert-butyl-9H-carbazol-9-yl)benzonitrile (4TCzBN); 10,10′-[5-(6-[1,1′-biphenyl]-4-yl-2-phenyl-4-pyrimidinyl)-1,3-phenylene]bis[9,10-dihydro-9,9-dimethyl-acridine](DMAC-BPP); N4,N4,N4″,N4″-tetra([1,1′-biphenyl]-4-yl)-[1,1′:4′,1″-terphenyl]-4,4″-diamine (TaTm); N,N′-Di(1-naphthyl)-N,N′-diphenyl-(1,1′-biphenyl)-4,4′-diamine (NBP); 10-(4-(4,6-diphenyl-1,3,5-triazin-2-yl)phenyl)-10H-phenoxazine (PXZ-TRZ); Tris(dibenzoylmethane)phenanthroline europium(III) (Eu(dbm)3(Phen)); 4,4′-(Diphenylsilanediyl)bis(N,N-diphenylaniline) (TSBPA); 9,9′,9″-(5-(4,6-Diphenyl-1,3,5-triazin-2-yl)benzene-1,2,3-triyl) tris(9H-carbazole) (TCzTRZ); and 9,9′,9″-(5-(4,6-Diphenyl-1,3,5-triazin-2-yl)benzene-1,2,3-triyl) tris(3,6-dimethyl-9H-carbazole) (TmCzTRZ), (2-(3,6-Dimethoxy-9H-carbazol-9-yl)ethyl)phosphonic acid (MeO-2PACz); (2-(9H-carbazol-9-yl)ethyl)phosphonic acid (2PACz).

The hole-transport layer may comprise a material selected from the group consisting of: Spiro-TTB; PTAA; D18; TaTm; and NBP.

In some embodiments, the photovoltaic cell comprises a passivating layer between the ultrathin hole-transport layer and the absorber layer.

In some embodiments, the passivating layer comprises a material selected from the group consisting of: polymethyl methacrylate (PMMA); n-Octylammonium Bromide (OABr); octylammonium iodide (OAI); octylammonium chloride (OACl); butylammonium iodide; butylammo-nium bromide; and phenethylammonium iodide (PEAI).

A second aspect of the present invention provides a photovoltaic cell, comprising:
an absorber layer comprising a perovskite material, said absorber layer having a valence band with a first energy level;
a hole-transport layer, said hole-transport layer having a valence band with a second energy level; and
a protective layer located between the absorber layer and the hole-transport layer, said protective layer having a valence band with an energy level that is between the first and second energy levels.

In some embodiments, the photovoltaic cell comprises, in order relative to incident light said cell is configured to receive:
a first carrier-selective transport layer;
the absorber layer; and
a second carrier-selective transport layer;
   wherein one of the first carrier-selective transport layer or the second carrier-selective transport layer is the hole-transport layer.

A second variant of the second aspect provides embodiments wherein said cell is a tandem photovoltaic cell comprising, in order relative to incident light said cell is configured to receive:
a first sub-cell; and
a second sub-cell;
said first sub-cell comprising:
   the absorber layer;
   the hole-transport layer; and
   the protective layer.

Some embodiments of the second variant comprise an interconnecting layer between the second carrier-selective transport layer and the second sub-cell.

In some other embodiments of the second variant, the second carrier-selective transport layer directly contacts the second sub-cell.

In some embodiments, the protective layer comprises a material selected from the group consisting of Poly(N,N′-bis-4-butylphenyl-N,N′-bisphenyl)benzidine (Poly-TPD), N,N′-Bis(naphthalen-1-yl)-N,N′-bis(phenyl)-2,2′-dimethylbenzidine (α-NPD), N,N′-Bis(3-methylphenyl)-N,N′-diphenylbenzidine (TPD).

In some embodiments, the protective layer comprises poly-TPD.

In some embodiments, the weight average molecular weight of the poly-TPD is greater than 100 kDa.

In some embodiments, the weight average molecular weight of the poly-TPD is in the range of 100 kDa to 500 kDa.

In some embodiments, the photovoltaic cell comprises a passivating layer between the hole-transport layer and the absorber layer.

In some embodiments, the passivating layer comprises a material selected from the group consisting of: polymethyl methacrylate (PMMA); n-Octylammonium Bromide (OABr); octylammonium iodide (OAI); octylammonium chloride (OACl); butylammonium iodide; butylammo-nium bromide; and phenethylammonium iodide (PEAI).

In some embodiments, the hole-transport layer is an ultrathin hole-transport layer such that said photovoltaic cell is a photovoltaic cell in accordance with the first aspect.

In some embodiments of the first and second aspects, the first carrier-selective transport layer is the hole-transport layer and the second carrier-selective transport layer is the electron-transport layer. In some other embodiments of the first and second aspects, the first carrier-selective transport layer is the electron-transport layer and the second carrier-selective transport layer is the hole-transport layer.

In some embodiments, the photovoltaic cell comprises, in order relative to incident light said cell is configured to receive:
a transparent conductor layer on top of the second carrier-selective transport layer; and
a buffer layer between the second carrier-selective transport layer and the transparent conductor layer.

In some embodiments, the buffer layer comprises MoO₃, WO₃, V₂O₅, SnO₂, or TiO₂.

In some embodiments, the buffer layer comprises SnO₂, TiO₂, ZnO.

In some embodiments, the perovskite material comprises a compound of formula (I):

ABX3 (I),
wherein:
   A is a cation selected from a group consisting of: methyl ammonium (MA), formamidinium (FA), Cs, or Rb or any combination thereof;
   B is a metal cation, Pb; and
   X is a halide anion selected from a group consisting of Br, Cl and I so that the ratio of Br:I is in the range of 0:1 to 1:0.

In some embodiments, the ratio of Br:I is in the range of 0:1 to 1:1.

In some embodiments, A comprises one or more cations selected so that the molar percentage of A being: formamidinium ranges from 0% to 100%; methyl ammonium ranges from 0% to 100%; Cs ranges from 0% to 30%; and Rb ranges from 0% to 30%.

In some embodiments, the perovskite material is Cs_{0.05}Rb_{0.05}FA_{0.765}MA_{0.135}PbI_{2.55}Br_{0.45}, Cs_{0.1}FA_{0.765}MA_{0.135}PbI_{2.4}Br_{0.6}, Cs_{0.1}FA_{0.765}MA_{0.135}PbI_{2.22}Br_{0.78}, Cs_{0.1}FA_{0.765}MA_{0.135}PbIBr or Cs_{0.1} Rb_{0.05}FA_{0.765}MA_{0.135}PbI_{2.22}Br_{0.78}Cl_{0.015}.

A third aspect of the present invention provides a photovoltaic cell, comprising:
inner layers including:
   a lower carrier-selective transport layer;
   a crystalline silicon substrate; and
   an upper carrier-selective transport layer;
at least one barrier layer; and
an electrode;
   wherein said barrier layer is located between the inner layers and the electrode and is configured to suppress diffusion of metal from the electrode into the inner layers.

In some embodiments, the photovoltaic cell comprises:
an upper electrode;
the inner layers; and
a lower electrode;
   wherein one of said at least one barrier layer is located between either or each of:
the inner layers and the upper electrode and
the inner layers and the lower electrode.

A second variant of the third aspect provides embodiments wherein said cell is a tandem photovoltaic cell comprising, in order relative to incident light said cell is configured to receive:
a first sub-cell;
a second sub-cell, said second sub-cell comprising the inner layers;
the at least one barrier layer; and
the electrode,
   so that said barrier layer is located between the second sub-cell and the electrode.

In some embodiments of the second variant, said tandem photovoltaic cell is configured such that said photovoltaic cell is a photovoltaic cell in accordance with the first and/or second aspects.

In some embodiments, the barrier layer comprises a material selected from a group consisting of: transition metal oxides, metal halides, transparent conductive oxides, and metal nitrides. The barrier layer may comprise a transition metal oxide selected from a group consisting of: TiO₂, Ta₂O₃, and Ga₂O₃. In some embodiments, the barrier layer comprises a metal halide selected from a group consisting of: LiF and MgF₂. In some embodiments, the barrier layer comprises a metal nitride selected from a group consisting of: TiN and TaN. In some embodiments, the barrier layer is or comprises TiO₂, Ta₂O₃, LiF, MgF₂, TiN, or TaN. In some embodiments, the barrier layer comprises a combination of two or more materials from this group. In some embodiments, the barrier layer comprises two or more sublayers, at least one of said sublayers being a different material from another of said sublayers.

In some embodiments, the electrode comprises a metal selected from a group consisting of: Al, Cu and Ag.

In some embodiments, the lower and upper carrier-selective charge transport layers each comprise polycrystalline silicon.

In some embodiments, a passivating layer is located between each of:
the crystalline silicon substrate and the lower carrier-selective transport layer; and
the crystalline silicon substrate and the upper carrier-selective transport layer.

The first aspect further provides a method of fabricating a photovoltaic cell, said cell comprising an absorber layer comprising a perovskite material and an ultrathin hole-transport layer, said method comprising:
depositing the ultrathin hole-transport layer such that said ultrathin hole-transport layer is located above or below the absorber layer in the photovoltaic cell.

In some embodiments, depositing the ultrathin hole-transport layer comprises a thermal evaporation process.

In some embodiments, the method comprises controlling the thickness of the ultra-thin layer deposited, wherein the ultrathin hole-transport layer is deposited at a deposition rate and controlling deposition of the ultrathin hole-transport layer comprises monitoring the deposition rate.

In some embodiments, the method comprises:
depositing a bottom electrode layer on a substrate;
depositing a second carrier-selective transport layer on top of the bottom electrode layer;
depositing the absorber layer on top of the second carrier layer; and
depositing a first carrier-selective transport layer on top of the absorber layer;
   wherein one of the first carrier-selective transport layer or the second carrier-selective transport layer is the ultrathin hole-transport layer.

In some embodiments, said photovoltaic cell is a tandem cell, said method comprising:
providing a second sub-cell,
depositing a first sub-cell on top of the second sub-cell, said first sub-cell comprising: the absorber layer comprising a perovskite material and the ultrathin hole-transport layer.

In some embodiments, the first sub-cell is deposited directly on top of the second sub-cell.

In some embodiments, the method comprises, before depositing the first sub-cell, depositing an interconnecting layer on top of the second sub-cell.

In some embodiments, depositing the first sub-cell comprises:
depositing a second carrier-selective transport layer;
depositing the absorber layer on top of the second carrier-selective transport layer; and
depositing a first carrier-selective transport layer on top of the absorber layer.

In some embodiments, the first carrier-selective transport layer is the ultrathin hole-transport layer. In some of these embodiments, depositing of the second carrier-selective transport layer may comprise:
depositing an initial sub-layer by Atomic Layer Deposition; and
depositing an upper sub-layer.

In some other embodiments, the second carrier-selective transport layer is the ultrathin hole-transport layer.

In some embodiments, said depositing of the first sub-cell comprises:
before depositing the absorber layer, annealing the second carrier-selective transport layer.

In some embodiments, depositing of the first sub-cell comprises:
fabricating a transparent conductor layer on top of the first carrier-selective transport layer; and
depositing a top electrode on the transparent conductor layer.

In some embodiments, said depositing of first sub-cell comprises:
before depositing the absorber layer, depositing a second passivating layer on the second carrier-selective transport layer so that said second passivating layer is between the first carrier-selective transport layer and the absorber layer; and/or
before depositing the first carrier-selective transport layer, depositing a first passivating layer on the absorber layer so that said first passivating layer is between the absorber layer and the second carrier-selective transport layer.

In some embodiments, said depositing of the first sub-cell comprises:
before fabricating the transparent conductor layer, depositing a buffer layer on the first carrier-selective transport layer so that said buffer layer is between the first carrier-selective transport layer and the transparent conductor layer.

In some embodiments, said providing of the second sub-cell comprises:
providing a crystalline silicon substrate;
depositing an upper carrier-selective transport layer on top of the crystalline silicon substrate;
depositing a lower carrier-selective transport layer below the crystalline silicon substrate; and
depositing a lower electrode layer on the lower carrier-selective transport layer.

In some embodiments, the method comprises, after providing the crystalline silicon substrate, passivating the crystalline silicon substrate so that:
upper and lower passivating layers are provided on each side of the crystalline silicon substrate;
the upper passivating layer is between the crystalline silicon substrate and
the upper carrier-selective transport layer; and
the lower passivating layer is between the crystalline silicon substrate and
the lower carrier-selective transport layer.

The second aspect of the present invention further provides a method of fabricating a photovoltaic cell, said cell comprising:
an absorber layer comprising a perovskite material, said absorber layer having a valence band with a first energy level;
a hole-transport layer, said hole-transport layer having a valence band with a second energy level; and
a protective layer having a valence band with an energy level that is between the first and second energy levels,
   said method comprising:
depositing the hole-transport layer such that said hole-transport layer is located above or below the absorber layer in the photovoltaic cell; and
depositing the protective layer so that said protective layer is located between the absorber layer and the hole-transport layer.

In some embodiments, depositing the hole-transport layer comprises a thermal evaporation process.

In some embodiments, the hole transport layer is an ultrathin hole-transport layer.

In some embodiments, the method comprises controlling the thickness of the ultra-thin layer deposited, wherein the ultrathin hole-transport layer is deposited at a deposition rate and controlling deposition of the ultrathin hole-transport layer comprises monitoring the deposition rate.

In some embodiments, depositing the protective layer comprises a spin-coating process.

In some embodiments, the method comprises:
depositing a bottom electrode layer on a substrate;
depositing a second carrier-selective transport layer on top of the bottom electrode layer;
depositing the absorber layer on top of the second carrier layer;
depositing the protective layer on top of the absorber layer; and
depositing a first carrier-selective transport layer on top of the protective layer;
   wherein one of the first carrier-selective transport layer or the second carrier-selective transport layer is the hole-transport layer.

In some embodiments, said photovoltaic cell is a tandem cell, said method comprising:
providing a second sub-cell,
depositing a first sub-cell on top of the second sub-cell, said first sub-cell comprising:
   the absorber layer;
   the hole-transport layer; and
   the protective layer.

In some embodiments, the first sub-cell is deposited directly on top of the second sub-cell. In some other embodiments, the method comprises before depositing first sub-cell, depositing an interconnecting layer on top of the second sub-cell.

In some embodiments, depositing the first sub-cell comprises:
depositing a second carrier-selective transport layer;
depositing the absorber layer on top of the second carrier-selective transport layer; and
depositing a first carrier-selective transport layer on top of the absorber layer.

In some embodiments, the second carrier-selective transport layer is the hole-transport layer.

In some embodiments, said depositing of first sub-cell comprises:
before depositing the absorber layer, depositing a second passivating layer on the protective layer so that said second passivating layer is between the protective layer and the absorber layer; and/or
before depositing a first carrier-selective transport layer, depositing a first passivating layer on the absorber layer so that said first passivating layer is between the absorber layer the first carrier-selective transport layer.

In some embodiments, the first carrier-selective transport layer is the hole-transport layer.

In some embodiments, said depositing of first sub-cell comprises:
before depositing the absorber layer, depositing a second passivating layer on the second carrier-selective transport layer so that said second passivating layer is between the second carrier-selective transport layer and the absorber layer; and/or
before depositing the protective layer, depositing a first passivating layer on the absorber layer so that said first passivating layer is between the absorber layer the protective layer.

In some embodiments, depositing of the second carrier-selective transport layer comprises:
depositing an initial sub-layer by Atomic Layer Deposition; and
depositing an upper sub-layer.

In some embodiments, said depositing of the first sub-cell comprises: before depositing the absorber layer, annealing the second carrier-selective transport layer.

In some embodiments, depositing of the first sub-cell comprises:
fabricating a transparent conductor layer on top of the first carrier-selective transport layer; and
depositing a top electrode on the transparent conductor layer.

In some embodiments, said depositing of the first sub-cell comprises:
before fabricating the transparent conductor layer, depositing a buffer layer on the first carrier-selective transport layer so that said buffer layer is between the first carrier-selective transport layer and the transparent conductor layer.

In some embodiments, said providing of the second sub-cell comprises:
providing a crystalline silicon substrate;
depositing an upper carrier-selective transport layer on top of the crystalline silicon substrate;
depositing a lower carrier-selective transport layer below the crystalline silicon substrate; and
depositing a lower electrode layer on the lower carrier-selective transport layer.

In some embodiments, the method of the second aspect comprises, after providing the crystalline silicon substrate, passivating the crystalline silicon substrate so that:
upper and lower passivating layers are provided on each side of the crystalline silicon substrate;
the upper passivating layer is between the crystalline silicon substrate and the upper carrier-selective transport layer; and
the lower passivating layer is between the crystalline silicon substrate and the lower carrier-selective transport layer.

The third aspect of the present invention further provides a method of fabricating a photovoltaic cell, comprising:
providing a precursor comprising:
   a lower carrier-selective transport layer
   a crystalline silicon substrate; and
   an upper carrier-selective transport layer;
depositing a barrier layer on one or both of the lower carrier-selective transport layer and the upper carrier-selective transport layer; and
fabricating an electrode on the or each barrier layer, said barrier layer being configured to suppress diffusion of metal from the electrode into layers of the precursor.

In some embodiments, depositing the barrier layer comprises an Atomic Layer Deposition process.

In some embodiments, said photovoltaic cell is a tandem cell, said method comprising:
providing a second sub-cell, said providing comprising:
   providing the precursor; and
depositing a first sub-cell on top of the second sub-cell.

In some embodiments, depositing of the first sub-cell is performed in accordance with a method of the first aspect and/or second aspect.

A fourth aspect of the present invention provides a method of fabricating a doped precursor for use in fabricating a photovoltaic cell, said method comprising:
providing an initial precursor comprising first and second polycrystalline silicon layers with a crystalline silicon substrate therebetween; and
subjecting the initial precursor to a doping process to form a doped precursor, said doping process comprising:
   doping the first polycrystalline silicon layer with a first dopant using a thermal diffusion process to produce a first doped layer; and
   arranging the precursor in a back-to-back configuration with another precursor so that the first doped layers of each precursor are abutting;
   when in back-to-back configuration, doping the second polycrystalline silicon layer with a second dopant using a thermal diffusion process to produce a second doped layer;
   wherein the first dopant is one of a p-type dopant or a n-type dopant and the second dopant is the other of a p-type dopant or a n-type dopant.

In some embodiments of the fourth aspect a method of fabricating a doped precursor for use in fabricating a photovoltaic cell is provided, said method comprising:
providing an initial precursor comprising first and second polycrystalline silicon layers with a crystalline silicon substrate therebetween; and
subjecting the initial precursor to a doping process to form a doped precursor, said doping process comprising:
   arranging the initial precursor in a back-to-back configuration with another initial precursor so that the second polycrystalline silicon layers of each precursor are abutting;
   doping the first polycrystalline silicon layer with a first dopant using a thermal diffusion process to produce a first doped layer; and
   arranging the precursor in a back-to-back configuration with another precursor so that the first doped layers of each precursor are abutting;
   when in back-to-back configuration, doping the second polycrystalline silicon layer with a second dopant using a thermal diffusion process to produce a second doped layer;
   wherein the first dopant is one of a p-type dopant or a n-type dopant and the second dopant is the other of a p-type dopant or a n-type dopant.

In some embodiments of the fourth aspect, the method further comprises: before doping the first polycrystalline silicon layer, annealing the first and second polycrystalline silicon layers in an inert atmosphere.

In some embodiments of the fourth aspect, the first dopant is the p-type dopant and the second dopant is the n-type dopant.

A fifth aspect of the present invention provides a method of fabricating a doped precursor for use in fabricating a photovoltaic cell, said method comprising:
providing an initial precursor comprising first and second polycrystalline silicon layers with a crystalline silicon substrate therebetween;
annealing the first and second polycrystalline silicon layers in an inert atmosphere; and
after annealing, subjecting the initial precursor to a doping process to form a doped precursor, said doping process comprising:
   doping the first polycrystalline silicon layer with a first dopant to produce a first doped layer; and
   doping the second polycrystalline silicon layer with a second dopant to produce a second doped layer
   wherein the first dopant is one of a p-type dopant or a n-type dopant and the second dopant is the other of a p-type dopant or a n-type dopant.

In some embodiments of the fourth and/or fifth aspects, the annealing is performed at a temperature of from about 900° C. to about 1100° C. for about 5 mins to about 120 mins. In some embodiments, the annealing is performed at a temperature of about 1000° C. In some embodiments the annealing is performed for about 60 mins.

In a first option of the fifth aspect:
doping the first polycrystalline silicon layer comprises subjecting the first polycrystalline silicon layer to a thermal diffusion process using a p-type dopant to produce a p-type doped layer;
doping the second polycrystalline silicon layer comprises subjecting the second polycrystalline silicon layer to a thermal diffusion process using a n-type dopant to produce a n-type doped layer; and
the doping of the first polycrystalline silicon layer is performed before doping the second polycrystalline silicon layer.

In some embodiments of the fourth and/or fifth aspects:
doping of the first polycrystalline silicon layer is performed before doping the second polycrystalline silicon layer; and
doping of the first polycrystalline silicon layer is performed such that a first dopant glass formed on the first polycrystalline silicon layer provides a masking layer.

In some other embodiments of the fourth and/or fifth aspects, doping of the first polycrystalline silicon layer is performed before doping the second polycrystalline silicon layer; and said method further comprises:
between doping of the first and second polycrystalline silicon layers, forming a dielectric layer on the first polycrystalline silicon layer to provide a masking layer. Said dielectric layer may be SiO₂.

In some embodiments of the fourth and/or fifth aspects, the first dopant is the p-type dopant and doping the first polycrystalline silicon layer comprises:
diffusing the p-type dopant at a temperature of between about 850° C. to about 1050° C. for about 15 mins to about 60 mins; and
subjecting the first polycrystalline silicon layer to a thermal dopant drive-in process at a temperature of between about 850° C. to about 1050° C. for up to about 60 mins.

In some embodiments, diffusing the p-type dopant is performed at a temperature of about 980° C. In some embodiments, diffusing the p-type dopant is performed for about 25 mins.

The thermal dopant drive-in process is optional. When performed, it may be performed for at least 10 mins. In some embodiments, the thermal dopant drive-in process is performed at a temperature of about 980° C. In some embodiments, the thermal dopant drive-in process is performed for about 25 mins.

In some embodiments of the fourth and/or fifth aspects, the second dopant is the n-type dopant and doping the second polycrystalline silicon layer comprises:
diffusing the n-type dopant at a temperature of between about 800° C. to about 1050° C. for about 15 mins to about 60 mins; and
subjecting the second polycrystalline silicon layer to a thermal dopant drive-in process at a temperature of between about 800° C. to about 1050° C. for up to about 60 mins.

In some embodiments, diffusing the n-type dopant is performed at a temperature of about 820° C. In some embodiments, diffusing the n-type dopant is performed for about 25 mins.

The thermal dopant drive-in process is optional. When performed, it may be performed for at least 10 mins. In some embodiments, the thermal dopant drive-in process is performed at a temperature of about 900° C. In some embodiments, the thermal dopant drive-in process is performed for about 25 mins.

In a second option of the fifth aspect:
doping the first polycrystalline silicon layer comprises contacting the first polycrystalline silicon layer with a liquid p-type dopant-source; and
doping the second polycrystalline silicon layer comprises contacting the second polycrystalline silicon layer with a liquid n-type dopant-source.

In some embodiments, contacting the first polycrystalline silicon layer with a liquid p-type dopant-source comprises spin-on coating the first polycrystalline silicon layer with the liquid p-type dopant-source. In some other embodiments, contacting the first polycrystalline silicon layer with the liquid p-type dopant-source comprises spray-on coating the first polycrystalline silicon layer with the liquid p-type dopant-source.

In some embodiments, contacting the second polycrystalline silicon layer with the liquid n-type dopant-source comprises spin-on coating the second polycrystalline silicon layer with the liquid n-type dopant-source. In some other embodiments, contacting the second polycrystalline silicon layer with the liquid n-type dopant-source comprises spray-on coating the second polycrystalline silicon layer with the liquid n-type dopant-source.

In some embodiments:
after contacting the first polycrystalline silicon layer with the liquid p-type dopant-source, doping the first polycrystalline silicon layer comprises:
   subjecting the first polycrystalline silicon layer to a first annealing at a first temperature of between about 80° C. to about 150° C. for about 10 mins to about 30 mins; and
   after the first annealing, subjecting the first polycrystalline silicon layer to a second annealing at a second temperature of between about 150° C. to about 250° C. for about 5 mins to 60 mins.

In some embodiments, the first annealing is performed at a temperature of about 110° C. In some embodiments, the first annealing is performed for about 15 mins.

In some embodiments, the second annealing is performed at a temperature of about 200° C. In some embodiments, the second annealing is performed for about 8 mins.

In some embodiments, the first annealing and/or the second annealing is performed in an oxygen-containing atmosphere.

In some embodiments:
after contacting the second polycrystalline silicon layer with the liquid n-type dopant-source, doping the second polycrystalline silicon layer comprises:
   subjecting the second polycrystalline silicon layer to a third annealing at a third temperature of between about 80° C. to about 150° C. for about 10 mins to about 30 mins; and
   after the third annealing, subjecting the second polycrystalline silicon layer to a fourth annealing at a fourth temperature of between about 150° C. to about 250° C. for about 5 mins to about 60 mins.

In some embodiments, the third annealing is performed at a temperature of about 110° C. In some embodiments, the third annealing is performed for about 15 mins. In some embodiments, the fourth annealing is performed at a temperature of about 200° C. In some embodiments, the fourth annealing is performed for about 8 mins.

In some embodiments, the third annealing and/or the fourth annealing is performed in an oxygen-containing atmosphere.

In some embodiments, the doping of the second polycrystalline silicon layer is performed before doping the first polycrystalline silicon layer. In some of these embodiments, the method comprises:
after doping of the second polycrystalline silicon layer and before doping the first polycrystalline silicon layer, subjecting the precursor to an intermediate annealing in an inert atmosphere.

In some embodiments, the intermediate annealing is performed at a temperature of from about 350° C. to about 550° C. for about 10 mins to about 60 mins. In some embodiments, the intermediate annealing is performed at a temperature of about 450° C. In some embodiments, the intermediate annealing is performed for about 25 mins.

In some embodiments, providing the initial precursor comprises: depositing the first and second polycrystalline silicon layers on the crystalline silicon substrate. In some of these embodiments, the depositing is performed using low pressure chemical vapor deposition. In some embodiments, the depositing is performed at a temperature of from about 500° C. to about 650° C. for about 15 mins to about 120 mins. In some embodiments, the depositing is performed at a temperature of about 570° C.

In some embodiments of the fourth and/or fifth aspects, each of the first polycrystalline layer and the second polycrystalline layer has a thickness of about 15 to about 150 nm.

In some embodiments of the fourth and/or fifth aspects, providing the initial precursor comprises passivating the crystalline silicon substrate so that:
passivating layers are provided on each side of the crystalline silicon substrate;
a first passivating layer is between the crystalline silicon substrate and the first polycrystalline silicon layer; and
a second passivating layer is between the crystalline silicon substrate and the second polycrystalline silicon layer.

In some embodiments of the fourth and/or fifth aspects, the p-type dopant is boron.

In some embodiments of the fourth and/or fifth aspects, the n-type dopant is phosphorus.

In some embodiments of the fourth and/or fifth aspects, the method further comprises, after the doping process: subjecting either or each of the first doped layer and the second doped layer to a hydrogen passivation process. The hydrogen passivation process may comprise:
depositing one or more hydrogen-containing dielectric layers on either or each of the first doped layer and the second doped layer;
subjecting the one or more hydrogen-containing dielectric layers to a thermal annealing step or a firing step to effect hydrogenation of the layer on which said one or more hydrogen-containing dielectric layers is deposited; and
removing the one or more hydrogen-containing dielectric layers from the doped precursor.

In some embodiments, the one or more hydrogen-containing dielectric layers comprises a first hydrogen-containing dielectric layer and a second hydrogen-containing dielectric layer; wherein:
a first hydrogen-containing dielectric layer is deposited on either or each of the first doped layer and the second doped layer; and
a second first hydrogen-containing dielectric layer is deposited on the or each first hydrogen-containing dielectric layer.

In some embodiments, the first hydrogen-containing dielectric layer comprises Al₂O₃ and the second hydrogen-containing dielectric layer comprises SiNₓ.

A sixth aspect of the present invention provides a method of fabricating a photovoltaic cell, said method comprising:
providing a doped precursor, said doped precursor fabricated according to the method of the fourth and/or fifth aspects; and
depositing an electrode layer on one of the p-type doped layer and the n-type doped layer.

A seventh aspect of the present invention provides a method of fabricating a tandem photovoltaic cell, said method comprising:
fabricating a second sub-cell using a doped precursor fabricated according to the method of the fourth and/or fifth aspects such that said second sub-cell comprises, in order relative to incident light said photovoltaic cell is configured to receive:
   an upper carrier-selective transport layer
   the crystalline silicon substrate; and
   a lower carrier-selective transport layer;
   wherein the upper carrier-selective transport layer comprises one of the p-type doped layer or the n-type doped layer and the lower carrier-selective transport layer comprises the other of the p-type doped layer or the n-type doped layer; and
depositing a first sub-cell on top of the second sub-cell.

An eighth aspect of the present invention provides method of fabricating a tandem photovoltaic cell, said method comprising:
fabricating a second sub-cell such that said second sub-cell comprises, in order relative to incident light said tandem photovoltaic cell is configured to receive:
   an upper carrier-selective transport layer
   a crystalline silicon substrate; and
   a lower carrier-selective transport layer;
said fabricating comprising:
   providing an initial precursor comprising first and second polycrystalline silicon layers with the crystalline silicon substrate therebetween; and
   subjecting the initial precursor to a doping process to form a doped precursor, said doping process comprising:
      doping the first polycrystalline silicon layer with a p-type dopant to produce a p-type doped layer, said doping comprising contacting the first polycrystalline silicon layer with a liquid p-type dopant-source; and
      doping the second polycrystalline silicon layer with a n-type dopant to produce a n-type doped layer, said doping comprising contacting the second polycrystalline silicon layer with a liquid n-type dopant-source;
   wherein the upper carrier-selective transport layer comprises one of the p-type doped layer or the n-type doped layer and the lower carrier-selective transport layer comprises the other of the p-type doped layer or the n-type doped layer; and
depositing a first sub-cell on top of the second sub-cell.

In some embodiments of the eighth aspect, the doped precursor is fabricated in accordance with the method of the fourth and/or fifth aspects as described above.

In some embodiments of the seventh or eighth aspects, the first sub-cell is deposited directly onto an upper carrier-selective transport layer of the second sub-cell.

In some embodiments of the seventh or eighth aspects, the method comprises, before depositing the first sub-cell, depositing an interconnecting layer onto an upper carrier-selective transport layer of the second sub-cell.

In some embodiments of the seventh or eighth aspects, the method comprises, depositing a lower electrode layer on the lower carrier-selective transport layer.

In some embodiments of the method of the third aspect, the precursor is a doped precursor fabricated according a method of the fourth and/or fifth aspects.

In some embodiments of the fourth, fifth and/or sixth aspects, when the cell is a tandem cell:
the first sub-cell is a first sub-cell according to the first aspect and/or second aspect; or
said method is a method in accordance with the first aspect and/or second aspect.

In some embodiments of the fourth, fifth and/or sixth aspects, when the cell is a tandem cell, wherein:
the photovoltaic cell is a photovoltaic cell according to the third aspect; or
said method is a method in accordance with the third aspect

Also provided is photovoltaic cell fabricated according to the method of the present invention.

### BRIEF DESCRIPTION OF THE DRAWINGS

Embodiments will now be described by way of example only, with reference to the accompanying drawings in which:

FIG. 1 is a schematic view of a first form of photovoltaic cell comprising an ultrathin hole transport layer and an absorber according to the present invention;

FIG. 2 is a schematic view of one embodiment of the first form of the photovoltaic cell according to the present invention;

FIG. 3 is a schematic view of a second form of a photovoltaic cell comprising an absorber layer, an ultrathin hole transport layer and a protective layer according to the present invention;

FIG. 4 is a schematic view of one embodiment of the second form of the photovoltaic cell according to the present invention;

FIG. 5 is a schematic view of a third form of the invention, being a tandem photovoltaic cell comprising an absorber, an ultrathin hole transport layer and an interconnecting layer according to the present invention;

FIG. 6 is a schematic view of one embodiment of the third form according to the present invention;

FIG. 7 is a schematic of a fourth form of the invention, being a tandem photovoltaic cell comprising an absorber layer, a hole transport layer, a protective layer and an interconnecting layer according to the present invention;

FIG. 8 is a schematic of one embodiment of the second variation of the tandem photovoltaic cell according to the present invention;

FIG. 9 is a schematic of a fifth form of the present invention, illustrating a photovoltaic cell comprising inner layers, an electrode and a barrier layer according to the present invention;

FIGS. 10A and 10B show schematics of options for a sixth form including two barrier layers according to the present invention;

FIG. 11 is a schematic of a seventh form of the present invention, illustrating a tandem photovoltaic cell comprising an absorber layer, a hole transport layer, a protective layer, a barrier layer and an interconnecting layer according to the present invention;

FIG. 12 is a schematic of one embodiment of the seventh form of the tandem photovoltaic cell according to the present invention;

FIG. 13 is a schematic of the photovoltaic cell of Example 1;

FIG. 14 is a schematic of the photovoltaic cell of Example 2;

FIG. 15(a) is a graph of bias (V) and current density (mAcm⁻²) (a current density (J)—voltage (V) curve (a J-V curve)) illustrating the results of Example 3 for a cell without a protective layer;

FIG. 15(b) is a graph of bias (V) and current density (mAcm⁻²) (a current density (J)—voltage (V) curve (a J-V curve)) illustrating the results of Example 3 for a cell with a protective layer;

FIG. 16A is a sectional Scanning Electron Microscopy image of the device of Example 6 including a protective layer, with FIG. 16B being a drawing reflecting FIG. 16A;

FIG. 17 is a graph of bias (V) and current density (mAcm⁻²) (a current density (J)—voltage (V) curve (a J-V curve)) for Example 4;

FIG. 18 is a graph of bias (V) and current density (mAcm⁻²) (a current density (J)—voltage (V) curve (a J-V curve)) for Example 5;

FIG. 19 is a graph illustrating the absorption properties of the perovskite compositions of Example 7;

FIG. 20 is a schematic of an initial precursor for fabricating a photovoltaic cell in accordance with the present invention;

FIG. 21 (a)-(c) illustrate the steps involved in the thermal diffusion process for fabrication of the initial precursor according to FIG. 20;

FIG. 22 (a)-(d) illustrate the steps involved in the spin-on process for fabrication of the initial precursor according to FIG. 20;

FIGS. 23(a) and (b) illustrate the steps involved in the hydrogen passivation process for treatment of the initial precursor according to FIG. 20 formed from a thermal diffusion or spin-on process;

FIG. 24 is a schematic of the photovoltaic cell of Example 9;

FIG. 25A is an image illustrating photoluminescence of the sample of Example 10, with FIG. 25B being an image reflecting FIG. 25A;

FIG. 26 is a graph showing the resistivity behaviour of Samples 1 to 3 of Example 11 that have different hole transport layers: Spiro-OMeTAD, Spiro-TTB, Poly-TPD/Spiro-TTB;

FIG. 27 is a graph of the performance characteristics of Samples 1 to 3 of Example 11;

FIG. 28 is a schematic illustrating energy levels of different layers of Sample 3 of Example 11;

FIG. 29 is a graph of bias (V) and current density (mAcm⁻²) (a current density (J) voltage (V) curve (a J-V curve)) of Samples 1 to 3 of Example 11;

FIG. 30 is a graph of photoluminescence intensity (PL intensity) and wavelength (nm) of Samples 1 to 4 of Example 14;

FIG. 31 is a graph of PL intensity and time of Samples 1 to 4 of Example 14, with FIG. 31A being a version of FIG. 31 in colour;

FIG. 32 is an x-ray diffraction (XRD) plot of Samples 1 and 4 of Example 14;

FIGS. 33A and 33B are x-ray photoelectron spectroscopy (XPS) plots of Samples 1 and 4 of Example 14;

FIG. 34 is a graph of concentration of electrons and holes of Sample 4 of Example 14;

FIG. 35 is a graph of the performance characteristics of the tandem cell of Example 15;

FIG. 36 is a graph of bias (V) and current density (mAcm⁻²) (a current density (J) voltage (V) curve (a J-V curve)) of the tandem cell of Example 15;

FIG. 37 is a graph of external quantum efficiencies of the different sub-cells of the tandem cell of Example 15;

FIG. 38 is a graph of the variation of different performance characteristics with time for the tandem cell of Example 15;

FIGS. 39A and B illustrate, respectively, PL images and corresponding contour plots for n-type polycrystalline silicon samples with 17 nm (top row) and 28 nm (bottom row) TiO₂ barrier layers, before and after cumulative annealing steps;

FIGS. 40A and B illustrate, respectively, PL images and corresponding contour plots, for pre-annealed n-type polycrystalline silicon samples with 17 nm (top row) and 28 nm (bottom row) TiO₂ barrier layers, before and after cumulative annealing steps;

FIGS. 41A and B illustrate, respectively, PL images and corresponding contour plots, for n-type polycrystalline silicon samples with 28 nm ZnO:Al barrier layers, before and after cumulative annealing steps;

FIGS. 42A and B illustrate, respectively, PL images and corresponding contour plots, for n-type polycrystalline silicon samples with 45 nm MgF₂ barrier layers, before and after cumulative annealing steps;

FIGS. 43A and B illustrate, respectively, PL images and corresponding contour plots, for n-type polycrystalline silicon samples with 30 nm LiF barrier layers, before and after cumulative annealing steps. Areas coated with ˜200 nm thick Al layer are indicated by dashed outline;

FIG. 44 is a graph of contact resistivity (ρ_{c}) and annealing temperature (° C.) for n-type polycrystalline silicon contacts, with and without various barrier layers;

FIG. 45 shows graphs of the V_{oc}, J_{sc}, FF, and PCE values for the samples of Example 12;

FIG. 46 shows a graph of the lowest trap-filled limited voltage of the samples of Example 14;

FIG. 47 shows a graph of the V_{oc}, J_{sc}, FF, and PCE values for the light-dark cycle testing of Example 15;

FIG. 48 shows a graph of the V_{oc}, J_{sc}, FF, and PCE values for the damp-heat testing of Example 15;

FIGS. 48A and 48B show simulated JV curves as a function of HTL ionisation potential for (FIG. 48A) a device without non-radiative recombination and (FIG. 48B) a device with non-radiative recombination. FIG. 48B has a truncated x-axis for legibility;

FIGS. 49A and 49B show energy band diagram of perovskite solar cell at perovskite-HTL interface, for IP_{HTL}=2.25 eV, and without, any non-radiative recombination, respectively;

FIGS. 50A and 50B show energy diagram of quasi-Fermi level for holes at perovskite-HTL interface for (FIG. 50A) IP_{HTL}=2.25 eV, and (FIG. 50B) IP_{HTL}=2.40 eV at 20 mA/cm². In the latter case, hole transport losses are 130 mV lower than in the former case;

FIG. 51 shows a graph of the average photoluminescence intensity of the MgF₂ barrier layers of Example 17;

FIG. 52 shows a graph of the average photoluminescence intensity of the TiO₂ barrier layers of Example 17;

FIG. 53 shows a graph contact resistivity ρc values of n-type polycrystalline silicon contacts of the Example 17 samples with MgF₂ barrier layers;

FIG. 54 shows a graph contact resistivity ρc values of n-type polycrystalline silicon contacts of the Example 17 samples with TiO₂ barrier layers;

FIGS. 55A and 56A illustrate, respectively, PL images and corresponding contour plots, for a n-type polycrystalline silicon sample with a 30 nm TiO₂ barrier layer after Al deposition (see Example 17);

FIGS. 55B and 56B illustrate, respectively, PL images and corresponding contour plots, for a n-type polycrystalline silicon sample with a 60 nm TiO₂ barrier layer after Al deposition (see Example 17);

FIGS. 55C and 56C illustrate, respectively, PL images and corresponding contour plots, for a n-type polycrystalline silicon sample with a 90 nm TiO₂ barrier layer after Al deposition (see Example 17);

FIGS. 55D and 56D illustrate, respectively, PL images and corresponding contour plots, for a n-type polycrystalline silicon sample with a 120 nm TiO₂ barrier layer after Al deposition (see Example 17);

FIGS. 55E and 56E illustrate, respectively, PL images and corresponding contour plots, for a n-type polycrystalline silicon sample with a 30 nm TiO₂ barrier layer after Al deposition and a 400° C. anneal in air (see Example 17);

FIGS. 55F and 56F illustrate, respectively, PL images and corresponding contour plots, for a n-type polycrystalline silicon sample with a 60 nm TiO₂ barrier layer after Al deposition and a 400° C. anneal in air (see Example 17);

FIGS. 55G and 56G illustrate, respectively, PL images and corresponding contour plots, for a n-type polycrystalline silicon sample with a 90 nm TiO₂ barrier layer after Al deposition and a 400° C. anneal in air (see Example 17);

FIG. 55H illustrates a PL image for a n-type polycrystalline silicon sample with a 120 nm TiO₂ barrier layer after Al deposition and a 400° C. anneal in air (see Example 17);

FIGS. 57A and 58A illustrate, respectively, PL images and corresponding contour plots, for a n-type polycrystalline silicon sample with a 30 nm MgF₂ barrier layer after Al deposition (see Example 17);

FIGS. 57B and 58B illustrate, respectively, PL images and corresponding contour plots, for a n-type polycrystalline silicon sample with a 60 nm MgF₂ barrier layer after Al deposition (see Example 17);

FIGS. 57C and 58C illustrate, respectively, PL images and corresponding contour plots, for a n-type polycrystalline silicon sample with a 90 nm MgF₂ barrier layer after Al deposition (see Example 17);

FIGS. 57D and 58D illustrate, respectively, PL images and corresponding contour plots, for a n-type polycrystalline silicon sample with a 120 nm MgF₂ barrier layer after Al deposition (see Example 17);

FIGS. 57E and 58E illustrate, respectively, PL images and corresponding contour plots, for a n-type polycrystalline silicon sample with a 30 nm MgF₂ barrier layer after Al deposition and a 400° C. anneal in air (see Example 17);

FIGS. 57F and 58F illustrate, respectively, PL images and corresponding contour plots, for a n-type polycrystalline silicon sample with a 60 nm MgF₂ barrier layer after Al deposition and a 400° C. anneal in air (see Example 17);

FIGS. 57G and 58G illustrate, respectively, PL images and corresponding contour plots, for a n-type polycrystalline silicon sample with a 90 nm MgF₂ barrier layer after Al deposition and a 400° C. anneal in air (see Example 17);

FIG. 55H illustrates a PL image for a n-type polycrystalline silicon sample with a 120 nm MgF₂ barrier layer after Al deposition and a 400° C. anneal in air (see Example 17);

FIG. 59 illustrates the tandem solar cell structure used for the simulations of Example 18; and

FIGS. 60A and B illustrate, respectively, PL images and corresponding contour plots for n-type polycrystalline silicon samples with no barrier layers (reference samples), before and after cumulative annealing steps.

### DETAILED DESCRIPTION

Photovoltaic cells can comprise in order relative to incident light, a first carrier-selective transport layer, the absorber and a second carrier-selective transport layer. The carrier-selective transport layers (CSL) selectively allow one type of charge carrier that is generated in the absorber to pass through them and be fed into an external circuit while blocking the oppositely charged carrier. The CSL may either be an electron transport layer (ETL) or a hole transport layer (HTL). That is, one of the first and second carrier-selective layers may be the ultrathin HTL described above. Thus, the other of the first and second carrier-selective layer may be an ETL. The HTL may be located either above or below the absorber in order relative to incident light. Accordingly, the ETL may be located below or above the absorber respectively. The first aspect of the present invention provides a photovoltaic cell, comprising: an absorber layer comprising a perovskite material and an ultrathin hole-transport layer. The photovoltaic cell may be configured to absorb light from the high energy/low wavelength spectrum of sunlight. For example, the cell may be able to absorb energy from blue light (i.e. wavelengths of approximately 300-800 nm).

Perovskites are known for their large bandgap tunability, low materials cost, and simple processing requirements. The perovskite material used in the absorber includes but is not limited to organometal halide perovskites, inorganic perovskite (such as CsPbI₃) and hybrid organic-inorganic mixed halides perovskites.

The ultrathin hole-transport layer facilitates the transfer of holes generated during excitation of the absorber while blocking the transfer of electrons through it. The use of an ultrathin hole-transport layer can assist in minimizing the absorption loss and reducing charge transport resistance. For example, the reduced absorption by an ultrathin layer may result in more light reaching the absorber. This may result in an increased charge carrier generation thus improving performance of the cell.

As used herein, the term ‘ultrathin’ refers to a characteristic thickness of the hole-transport layer. In general, the thickness of the layer is such that it substantially covers the layer underlying it. A layer that is too thin will include pin holes or similar defects that will lead to a poor-quality hole-transport layer. Accordingly, in the first aspect of the invention, the ultrathin HTL is thick enough to substantially cover the topology of the layer onto which the HTL has been deposited. In some embodiments, the ultrathin hole-transport layer has a thickness greater than the largest contour interval in surface roughness of a layer underlying the ultrathin hole-transport layer. That is, the ultrathin hole-transport layer has a thickness greater than the largest vertical distance or difference in elevation between points on the surface of a layer underlying the ultrathin hole-transport layer.

In some embodiments, the ultrathin hole-transport layer has a thickness of less than 100 nm, such as a thickness of less than 50 nm. For example, the ultrathin hole-transport layer may have a thickness between about 5 nm and about 35 nm or between about 5 nm and about 25 nm.

As noted above, the ultrathin HTL may be located above or below the absorber. Thus, in some embodiments of the first aspect, there is provided photovoltaic cell comprising, in order relative to incident light said cell is configured to receive: a first carrier-selective transport layer; the absorber layer comprising a perovskite material; and a second carrier-selective transport layer; wherein one of the first carrier-selective transport layer or the second carrier-selective transport layer is an ultrathin hole-transport layer.

In some embodiments, the material for the ultrathin hole-transport layer may be selected from a group consisting of: Poly[bis(4-phenyl)(2,4,6-trimethylphenyl)amine](PTAA), Poly(3-hexylthiophene-2,5-diyl) (P3HT); Poly [[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]](PTB7); Poly[(2,6-(4,8-bis(5-(2-ethylhexyl-3-fluoro)thiophen-2-yl)-benzo[1,2-b:4,5-b′]dithiophene))-alt-5,5′-(5,8-bis(4-(2-butyloctyl)thiophen-2-yl)dithieno[3′,2′:3,4;2″,3″:5,6]benzo[1,2-c][1,2,5]thiadiazole)](D18); Poly [(2,6-(4,8-bis(5-(2-ethylhexyl)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5‘-c’]dithiophene-4,8-dione)](PBDB-T); Poly[(5,6-difluoro-2,1,3-benzothiadiazol-4,7-diyl)-alt-(3,3′″-di(2-octyldodecyl)-2,2′;5′,2″;5″,2′″-quaterthiophen-5,5′″-diyl)](PffBT4T-2OD); Tris(8-hydroxyquinoline)aluminium (Alq3); 2,4,5,6-Tetra(9H-carbazol-9-yl)isophthalonitrile (4CzIPN); Tris[2-phenylpyridine]iridium(III) (Ir(ppy)3); F2Irpic, Ir(diFppy)2(pic) (FIrPic); 2,5,8,11-Tetrakis(1,1-dimethylethyl)perylene; 2,5,8,11-Tetra-tert-butylperylene(TBPe); Bis[2-(2-pyridinyl-N)phenyl-C](acetylacetonato)iridium(III) (Ir(ppy)2(acac)); Tris(1-phenylisoquinoline)iridium(III) (Ir(piq)3); Bis(1-phenylisoquinoline)(acetylacetonate)iridium(III) (Ir(piq)2(acac)); 5,6,11,12-Tetraphenylnaphthacene (Rubrene); 1,2-Bis(carbazol-9-yl)-4,5-dicyanobenzene (2CzPN), Tetraphenyldibenzoperiflanthene; Dibenzo{[f,f′]-4,4′,7,7′-tetraphenyl}diindeno[1,2,3-cd:1′,2′,3′-lm]perylene (DBP); 4-(Dicyanomethylene)-2-tert-butyl-6-(1,1,7,7-tetramethyljulolidin-4-yl-vinyl)-4H-pyran (DCJTB); 2-Methyl-9,10-bis(naphthalen-2-yl)anthracene, 2-Methyl-9,10-di(2-naphthyl)anthracene (MADN); 10-(2-Benzothiazolyl)-2,3,6,7-tetrahydro-1,1,7,7-tetramethyl-1H,5H,11H-(1)benzopyropyrano(6,7-8-I,j)quinolizin-11-one(C545T); Bis[2-(2-quinolinyl)phenyl](2,2,6,6-tetramethyl-3,5-heptanedionato)iridium (fr(dpm)PQ2); Bis(2-(3,5-dimethylphenyl)quinoline-C2,N′)(acetylacetonato)iridium(III) (Ir(dmpq)2(acac)); Tris(1-phenylpyrazolato)iridium (Ir(ppz)3); 2,3,4,5,6-pentakis(3,6-di-tert-butyl-9H-carbazol-9-yl)benzonitrile (5TCzBN); 2,3,5,6-Tetrakis(3,6-di-tert-butyl-9H-carbazol-9-yl)benzonitrile (4TCzBN); 10,10′-[5-(6-[1,1′-biphenyl]-4-yl-2-phenyl-4-pyrimidinyl)-1,3-phenylene]bis[9,10-dihydro-9,9-dimethyl-acridine](DMAC-BPP); N4,N4,N4″,N4″-tetra([1,1′-biphenyl]-4-yl)-[1,1′:4′,1″-terphenyl]-4,4″-diamine (TaTm); N,N′-Di(1-naphthyl)-N,N′-diphenyl-(1,1′-biphenyl)-4,4′-diamine (NBP); 10-(4-(4,6-diphenyl-1,3,5-triazin-2-yl)phenyl)-10H-phenoxazine (PXZ-TRZ); Tris(dibenzoylmethane)phenanthroline europium(III) (Eu(dbm)3(Phen)); 4,4′-(Diphenylsilanediyl)bis(N,N-diphenylaniline) (TSBPA); 9,9′,9″-(5-(4,6-Diphenyl-1,3,5-triazin-2-yl)benzene-1,2,3-triyl) tris(9H-carbazole) (TCzTRZ); and 9,9′,9″-(5-(4,6-Diphenyl-1,3,5-triazin-2-yl)benzene-1,2,3-triyl) tris(3,6-dimethyl-9H-carbazole) (TmCzTRZ), (2-(3,6-Dimethoxy-9H-carbazol-9-yl)ethyl)phosphonic acid (MeO-2PACz); (2-(9H-carbazol-9-yl)ethyl)phosphonic acid (2PACz). In some embodiments, the hole-transport layer comprises a material selected from the group consisting of: Spiro-TTB; PTAA; D18; TaTm; and NBP.

The thickness of the ultrathin HTL may be selected based on the material used. In general, less absorptive and more conductive hole transport layer materials will be deposited in a relatively thicker layer.

The deposition of the ultrathin HTL can be accomplished using various techniques such as thermal evaporation, atomic layer deposition (ALD), sputtering, and solution-processed method including spin-coating, blade-coating and slot-die coating etc. Different parameters of the deposition method can be monitored and controlled to obtain the desired thickness of the ultrathin HTL. For example, in the thermal evaporation technique, the thickness of the ultrathin HTL can be controlled by monitoring and controlling the deposition rate. This may be accomplished for example using crystal sensors located in the deposition system.

The ETL for the photovoltaic cell may be selected from a group including, but not limited to, Nb₂O₅, Ta₂O₅, SrTiO₃, SnO₂, TiO₂ and C₆₀. The ETL may be deposited via ALD, solution processing or sputtering methods.

In some embodiments, deposition of the CSL may comprise: depositing an initial sub-layer; and depositing an upper sub-layer. Such a deposition method may be advantageous when using solution-based deposition methods. In embodiments in which the layer underlying the CSL may be damaged by solvent exposure, the initial layer may be first deposited using a low-solvent method. For example, in some embodiments, the initial sub-layer may be deposited by ALD. The ALD sub-layer may be suitably dense to block permeation of the solvent used for depositing the upper sub-layer into the underlying layer.

The photovoltaic cell can also comprise a passivation layer between the HTL and the absorber layer. The passivation layer performs the critical function of preventing recombination of photogenerated charge carriers at surface defects present in the absorber. For example, the surface of a perovskite material can have defects such as ‘dangling bonds’. These dangling bonds provide sites where the generated electron-hole pair may recombine, resulting in loss of the charge carriers before they can be separated and made to flow in an external circuit. Preventing such recombination may provide higher efficiencies from the cell. The passivation layer may also be configured such that it does not substantially interfere with the movement of the generated charge carriers to the ultrathin HTL.

The passivation layer can be selected from the group including, but not limited to: polymethyl methacrylate (PMMA); n-Octylammonium Bromide (OABr); octylammonium iodide (OAI); octylammonium chloride (OACl); butylammonium iodide; butylammonium bromide (BABr); and phenethylammonium iodide (PEAI).

In one variant of the photovoltaic cell of the first aspect, the photovoltaic cell is a single junction cell. In a second variant of the first aspect, the photovoltaic cell is a tandem photovoltaic cell.

In the first variant, the photovoltaic cell generally comprises top and bottom electrodes connected to the first and second CSL. The electrodes function to collect the charge carriers from the respective CSL and provide a pathway for charge carriers to exit the cell and flow through to an external circuit in order to recombine with oppositely charged carriers. The top electrode can be located above and connected to the first CSL. It is vital that the top electrode is optically transparent in order to allow incident light to reach the absorbers located in the cell. The top electrode may include but is not limited to, transparent conductive oxides (such as ITO: indium doped tin oxide, IZO: indium doped zinc oxide, AZO: aluminium doped zinc oxide, ZTO: zinc tin oxide), graphene, Ag nanowire or combinations thereof. The top electrode may be a full area contact formed from gold. Similarly, the bottom electrode can be located below and connected to the second CSL. The bottom electrode can be chosen from a group comprising Ag, Al, Cu, ITO, IZO, AZO, ZTO, graphene, Ag nanowires and combinations thereof.

For the first variant, the photovoltaic cell can be formed on a substrate. The substrate provides a supporting surface that is robust and able to withstand the processing conditions and chemicals utilized in the fabrication of the cell. The substrate may be glass.

When fabricating a cell of the first variant, first the bottom electrode layer can be deposited on the substrate. Following this, the second CSL can be deposited on top of the bottom electrode layer. Next the absorber layer can be deposited on top of the second CSL. Next, the first CSL can be deposited on top of the absorber layer. As discussed above, one of the first or second CSL can be an ultrathin hole-transport layer. Thus, in some embodiment, the first aspect provides a method comprising: depositing a bottom electrode layer on a substrate; depositing a second carrier-selective transport layer on top of the bottom electrode layer; depositing the absorber layer on top of the second carrier layer; and depositing a first carrier-selective transport layer on top of the absorber layer; wherein one of the first carrier-selective transport layer or the second carrier-selective transport layer is the ultrathin hole-transport layer.

In some embodiments, the photovoltaic cell may comprise an anti-reflection (AR) coating between top electrode and the first CSL. The AR coating may suppress Fresnel reflection losses, increase the amount of light entering the cell and hence, to enhance the power conversion efficiency. The AR coating may be a thermally evaporated MgF₂ layer or a mechanically attached silicone texture foil.

As noted above, in a second variant of the first aspect, the photovoltaic cell may be a tandem cell. Thus, in the second variant of the first aspect, there is provided a photovoltaic cell, wherein said cell is a tandem photovoltaic cell comprising, in order relative to incident light said cell is configured to receive: a first sub-cell; and a second sub-cell; said first sub-cell comprising: the absorber layer; and the ultrathin hole-transport layer.

It is to be understood that, except where expressly indicated otherwise, the term ‘first sub-cell’ is intended to refer to an uppermost sub-cell (relative to incident light), while the term ‘second sub-cell’ is intended to refer to a lower sub-cell, relative to the first sub-cell. In this regard, the tandem cell may be constructed by a process including the fabrication of the second sub-cell, prior to the fabrication of the first sub-cell, above and in a stacked relationship with the first sub-cell.

The first, or uppermost, sub-cell is configured to absorb light from the high energy/low wavelength spectrum of sunlight. For example, the first sub-cell may be able to absorb energy from blue light (i.e. wavelengths of approximately 300-800 nm). The first sub-cell may further be substantially transparent to low energy/high wavelength light, to allow such light to pass to the second (or lower) sub-cell of the tandem cell.

The second variant may also provide a method of fabricating a tandem cell. In some embodiments, there is provided a method wherein said photovoltaic cell is a tandem cell, said method comprising: providing a second sub-cell, depositing a first sub-cell on top of the second sub-cell, said first sub-cell comprising: the absorber layer comprising a perovskite material and the ultrathin hole-transport layer.

In some embodiments of the method of the second variant of the first aspect, depositing of the first sub-cell comprises: fabricating a transparent conductor layer on top of the first carrier-selective transport layer; and depositing a top electrode on the transparent conductor layer. As with the top electrode of the first variant, it is vital that the top electrode is optically transparent in order to allow incident light to reach the absorbers located in the cell. Furthermore, ideally a portion of the incident light can reach the underlying second sub-cell of the tandem cell. The top electrode of some embodiments of the second variant of the first aspect may include but is not limited to, transparent conductive oxides (such as ITO: indium doped tin oxide, IZO: indium doped zinc oxide, AZO: aluminium doped zinc oxide, ZTO: zinc tin oxide), graphene, Ag nanowire or combinations thereof. The top electrode may be a full area contact formed from gold.

As with the first variant, in the second variant, an AR coating may be provided. Alternatively or additionally, the transparent conductor layer may have AR properties.

The second sub-cell may comprise a crystalline silicon substrate that is configured to absorb light from the low energy/higher wavelength spectrum of sunlight. For example, the second sub-cell may be able to absorb energy from red/near-infrared light (i.e. wavelengths of ˜1200 nm). Accordingly, the second sub-cell may comprise a relatively low band gap material.

The first and second sub-cells are generally connected in series, allowing the voltage across the two sub-cells to additively combine. Thus, by stacking multiple cells on top of one another, it is possible to increase the voltage generated from the tandem (provided the absorbers in each sub-cell of the tandem are capable of being excited).

The first and second sub-cells may be connected through an interconnect layer (ICL) (also referred to herein as an interconnecting layer). The ICL may be referred to as a recombination layer. An ICL may allow electrical connection to be established between the two sub-cells in order to complete the electrical circuit. It may function as a low resistivity layer that allows recombination of charge carriers from the first and second sub-cells. The ICL may be deposited between the first and second sub-cells. Thus, the ICL may be capable of forming an interface with both the sub-cells. Charges from the second carrier-selective transport layer of the first sub-cell will be transferred to the ICL under the influence of an electric field to promote such recombination in the ICL.

In particular, the second CSL of the first sub-cell may be connected to the ICL between the two sub-cells. This may allow the charges accumulated on the second CSL to recombine with charges from a CSL of the upper side of the second sub-cell (described in more detail below) in the ICL. For example, if the second CSL is an ultrathin HTL, then the holes generated during the excitation in the absorber layer will be transferred to the ultrathin HTL and eventually to the ICL where they will combine with electrons that have been generated and gathered by the CSL of the upper side of the second sub-cell. Alternately, if the second CSL is an ETL, then the electrons generated and gathered by it will be able to recombine with holes generated and gathered from the CSL on the upper side of the second sub-cell.

The ICL may be chosen from a variety of materials including but not limited to transparent conductive oxides such as Indium tin oxide (ITO), Indium zinc oxide (IZO), zinc tin oxide (ZTO), alumina doped zinc oxide (AZO). The ICL can be deposited either via sputtering or the solution method. The ICL may, in some alternative embodiments, be in the form of a tunnelling junction layer. During fabrication of the tandem cell, the ICL may be deposited on top of the second sub-cell before depositing the first sub-cell.

In some embodiments of the tandem cell, the first and second sub-cell may be directly connected without the ICL. In particular, the second CSL of the first sub-cell directly contacts the second sub-cell. In particular, the second CSL of the first sub-cell may contact the CSL on the upper side of the second sub-cell. The direct-contact interface formed between the first and second sub-cells can perform the function of the ICL (i.e. providing a low resistive layer where recombination may occur). Accordingly, the direct-contact interface ideally has low resistivity and allows for a recombination of electrons and holes from the first and second-sub cells. The direct-contact interface is formed between complementary CSLs. This is critical to promote recombination of holes and electrons at the interface. For example, the HTL/ETL of the first and second sub-cells may be in direct contact with each other. More specifically, the ETL of the first sub-cell may be in direct contact with the HTL of the second sub-cell. Alternatively, the HTL of the first sub-cell may be in contact with the ETL of the second sub-cell to form this interface. Such an interface may not be formed between a HTL of the first sub-cell and the HTL of the second sub-cell (or an ETL of the first sub-cell and an ETL of the second sub-cell). Pairs of carrier-selective transport layers at the interface that may form a direct-contact interface include, but are not limited to, each of the ETL materials disclosed above and a p-type doped polycrystalline silicon CSL in the second sub-cell; or each of the HTL materials disclosed above and a n-type doped polycrystalline silicon CSL in the second sub-cell. Pairs of carrier-selective transport layers at the interface that may form a direct-contact interface include, but are not limited to: TiOₓ/p-type doped polycrystalline silicon CSL (p+ poly-Si); SnOₓ/p+ poly-Si; MoOₓ/n-type doped polycrystalline silicon CSL (n+ poly-Si); and VOₓ/n+ poly-Si. Deposition of the first sub-cell can take place directly on top of the second sub-cell.

Embodiments in which deposition of the second (lower) CSL of the first sub-cell comprises: depositing an initial sub-layer; and depositing an upper sub-layer, may be particularly advantageous for fabricating embodiments of the tandem photovoltaic cell in which the CSL directly contacts the second sub-cell. As these embodiments do not include an ICL, the second sub-cell may be more exposed to the deposition conditions used for the second CSL of the first cell. Thus, depositing the initial sub-layer of the second CSL of the second sub-cell (e.g. by a method such as ALD) may assist in minimising or reducing damage to the second sub-cell. In embodiments in which the layer underlying the CSL may be damaged by solvent exposure, the initial layer may be first deposited using a low-solvent method. For example, in some embodiments, the initial sub-layer may be deposited by ALD. The ALD sub-layer may be suitably dense to block permeation of the solvent used for depositing the upper sub-layer into the second sub-cell.

Production of the first sub-cell may involve one or more annealing processes. These annealing processes may be performed at temperatures up to about 500° C. The temperature may be selected depending on the material composition of the first sub-cell and/or the fabrication process(es) used. For example, some materials for use as a CSL for the first sub-cell may require annealing at higher temperatures. Annealing at higher temperatures may result in better crystallisation and, thus, conductivity. Materials that may be annealed at higher temperatures include transition metal oxides, such as NiOₓ and TiO₂.

It is desirable to select a material for the second sub-cell that is capable of withstanding the annealing conditions used for fabrication of the first sub-cell.

In addition, solvents are used during the fabrication of the first sub-cell. Common solvents include H₂O, ethanol, Isopropyl alcohol (IPA), Dimethylformamide (DMF), Dimethyl sulfoxide. These solvents can cause damage to the components of the second sub-cell. Thus, it is important to select materials for the second sub-cell that are compatible with the solvents to be used. Otherwise, solvent exposure during fabrication of the first sub-cell may cause degradation of the second sub-cell and attendant losses in cell performance.

Generally, the fabrication of the tandem cell involves deposition of the second sub-cell followed by the first sub-cell on top of the second sub-cell. For example, during fabrication, the second sub-cell may be fabricated in an initial step and the first sub-cell may be subsequently deposited on top of the second sub-cell.

As discussed above, the first sub-cell may be directly deposited on top of the second sub-cell. In this regard, the second CSL of the first sub-cell may be deposited on top of the second sub-cell. This step is followed by depositing the absorber layer on top of the second CSL. Finally, the first CSL is deposited on top of the absorber layer.

Alternatively, before depositing the first sub-cell, the interconnect layer may be deposited on top of the second sub-cell. In this regard, the second CSL of the first sub-cell may be deposited on top of the ICL. This step is followed by depositing the absorber layer on top of the second CSL. Finally, the first CSL is deposited on top of the absorber layer.

In some embodiments, the depositing of the first cell comprises, before depositing the absorber layer, an annealing step of the second CSL. Such an annealing step may be critical in fabricating a high performance TiO₂ layer.

In some embodiments of the first aspect, the method of fabricating the photovoltaic cell may comprise, before depositing the absorber layer, deposition of a second passivating layer on the second CSL. Thus, the second passivation layer is located between the second carrier-selective transport layer and the absorber layer. Alternatively or additionally, the method may comprise, before depositing the first CSL, depositing a first passivating layer on the absorber. Thus, the first passivation layer is between the absorber layer and the second CSL. In some embodiments of the second variant, said depositing of first sub-cell comprises: before depositing the absorber layer, depositing a second passivating layer on the second carrier-selective transport layer so that said second passivating layer is between the first carrier-selective transport layer and the absorber layer; and/or, before depositing the first carrier-selective transport layer, depositing a first passivating layer on the absorber layer so that said first passivating layer is between the absorber layer the second carrier-selective transport layer.

In some embodiments of the first aspect, the method of fabricating the photovoltaic cell may comprise, deposition of a buffer layer on the first CSL. For example, in embodiments of the method of the second variant, depositing of the first sub-cell may comprise: before fabricating the transparent conductor layer, depositing a buffer layer on the first carrier-selective transport layer so that said buffer layer is between the first carrier-selective transport layer and the transparent conductor layer.

Accordingly, the cell of the first variant, or the first sub-cell of the second variant, may comprise a buffer layer. The buffer layer may be provided to protect the underlying layers from damage resulting from the use of a plasma during the top transparent contact deposition through sputtering. In some embodiments in which the cell (or first sub-cell) is configured with a n-i-p structure, the buffer layer may be selected from a group including, but not limited to, MoOₓ, WOₓ, VOₓ, SnO₂, and TiO₂. In some embodiments in which the cell (or the first sub-cell) is configured with a p-i-n, the buffer layer material may be selected from a group including, but not limited to SnO₂, TiO₂, ZnO. The deposition of the buffer layer may be performed via ALD or thermal evaporation methods. The thickness of the buffer layer may range from about 0 to 30 nm.

The second aspect of the invention provides a photovoltaic cell comprising: an absorber layer comprising a perovskite material, said absorber layer having a valence band with a first energy level, a hole-transport layer (HTL) having a valence band with a second energy level and a protective layer located between the absorber layer and the hole-transport layer, said protective layer have a valence band with an energy level that is between the first and second energy levels. In some embodiments, there is provided a photovoltaic cell comprising, in order relative to incident light said cell is configured to receive: a first carrier-selective transport layer; the absorber layer; and a second carrier-selective transport layer; wherein one of the first carrier-selective transport layer or the second carrier-selective transport layer is the hole-transport layer.

The second aspect may further provide a method of fabricating a photovoltaic cell, said cell comprising: an absorber layer comprising a perovskite material, said absorber layer having a valence band with a first energy level; a hole-transport layer, said hole-transport layer having a valence band with a second energy level; and a protective layer having a valence band with an energy level that is between the first and second energy levels, said method comprising: depositing the hole-transport layer such that said hole-transport layer is located above or below the absorber layer in the photovoltaic cell; and depositing the protective layer so that said protective layer is located between the absorber layer and the hole-transport layer.

The material and deposition of the HTL may be as described above for the first aspect, but with the HTL having a conventional thickness (such as 50-100 nm). Alternatively, in some embodiments, the cell of the second aspect is also in accordance with the first aspect and, as such, comprise an ultrathin HTL.

Without being bound by theory, the protective layer may act as an intermediate layer that provides a cascading layer configuration that facilitates the transfer of the holes from the absorber to the HTL. The protective layer may provide a better energy alignment with the perovskite layer. For example, the HOMO level of a hole-transport layer comprising Spiro-TTB can be approximately 5.25 eV while the valence band of the perovskite can be around 5.56 eV. Such a large gap can result in the reduced hole extraction and transport efficiency. This can, consequently, result in V_{OC} and fill factor losses. A suitable protective layer for such an embodiment may have an energy level of 5.4 eV, thereby providing an intermediate layer with an energy level that is nearer to that of the perovskite layer than the HTL. This may facilitate the transfer of holes from the perovskite to the protective layer. Likewise, since the energy level of the protective layer is relatively nearer to that of the HTL, holes may more readily transfer across from the protective layer to the HTL.

Alternatively or additionally, the protective layer may suppress oxygen and/or moisture ingress into the absorber layer. Suppression may include reduction or prevention. The suppression of oxygen and/or moisture ingress into the absorber layer may enhance device stability. Thus, in one variant, the second aspect of the present invention provides a photovoltaic cell, comprising: an absorber layer comprising a perovskite material; a hole-transport layer; and a protective layer located between the absorber layer and the hole-transport layer, said protective layer configured to suppress oxygen and/or moisture ingress into the absorber layer.

The protective layer may be a material selected from the group consisting of Poly(N,N′-bis-4-butylphenyl-N,N′-bisphenyl)benzidine (Poly-TPD), N,N′-Bis(naphthalen-1-yl)-N,N′-bis(phenyl)-2,2′-dimethylbenzidine (α-NPD), N,N′-Bis(3-methylphenyl)-N,N′-diphenylbenzidine (TPD). In some embodiments, the protective layer comprises poly-TPD.

Without being bound by theory, it is believed that the molecular weight of the polymers may affect performance of the protective layer. In general, higher molecular weight polymers are expected to provide better performance. The weight average molecular weight of the material of the protective layer may be greater than 100 kDa, such as in the range of 100 kDa to 500 kDa. In some embodiments, the protective layer comprises poly-TPD and the weight average molecular weight of the poly-TPD greater than 100 kDa. For example, poly-TPD with weight-average molecular weights in the range of 100 kDa to 500 kDa may be particularly suitable for use as protective layer. It is considered that polymers of higher molecular weight can usually adopt a planar 7-stacked configuration more readily compared to lower molecular weight polymers. A planar π-stacked configuration may improve the interchain connections necessary for charge transport. The effect of adjusting weight-average molecular weight on the charge transport performance of a protective layer may be evaluated by checking the photovoltaic metrics, particularly the fill factor (FF). Good charge transport generally leads to high FF.

Without being bound by theory, it is believed that the concentration of the polymer in the precursor solution may affect the thickness of the layer and, accordingly, performance of the protective layer, with higher concentrations associated with thicker layers. Increasing the concentration of the polymer in the precursor solution may result in a protective layer that is more compact, potentially as well as being thicker. The polymer concentration may be about 0.1 mg/mL to about 1 mg/mL, such as about 0.25 mg/mL to about 0.75 mg/mL, for example about 0.5 mg/mL. If the concentration is too low, the resulting protective layer may be too thin or discontinuous (e.g. will include pin holes or similar defects that will lead to a poor-quality protective layer).

The deposition of the protective layer may comprise a spin-coating process.

In some embodiments of the second aspect, the photovoltaic cell also comprises one or more passivation layers deposited on one or both sides of the absorber. Each passivation layer may have the same characteristics and performs the same function as the passivation layer described above for the first aspect of the photovoltaic cell.

The cell may comprise a passivating layer between the hole-transport layer and the absorber layer. When fabricating the cell of the second aspect, a passivation layer may be deposited on top of the absorber. As noted above, the passivation layer may have the same characteristics and perform the same function as the passivation layer described above for the first aspect of the photovoltaic cell. Thus, a passivation layer of the first aspect may be used in the second aspect. The protective layer may be deposited on top of the passivation layer. In this regard, the protective layer may provide an additional passivating effect as well. For example, it may prevent recombination of generated charge carriers at the interface of the perovskite/passivation layers.

In some embodiments, the protective layer may have suitable passivation characteristics such that a separate passivation layer is not required between the the hole-transport layer and the absorber layer.

The passivation layer and HTL material selected may each affect the selection of the protective layer. Ideally, the protection layer may be deposited on to the passivation layer without any damage for the underlying layer. For example, for a protective layer that is deposited by solution processing method, the solvent used ideally does not materially dissolve the passivation layer. In addition, it is also desirable for the protective layer to be deposited such that substantially covers the HTL. Physical/chemical properties including molecule orientation and the hydrophilic/hydrophobic properties of the passivation layer and HTL are considered when selecting the material for the protective layer.

By way of example, one selection method is to first identify the energy levels of the perovskite material to be employed in the absorber. Next, suitable semiconducting materials with a work function that is close to the valence band of the perovskite such that they enable an efficient charge transfer while minimizing energy loss may be identified.

The photovoltaic cell of the second aspect may be configured to receive, in order relative to incident light: a transparent conductor layer on top of the first CSL, a buffer layer between the first CSL and the transparent conductor layer.

The buffer layer may be provided to protect the underlying layers of the photovoltaic cell from damage resulting from the use of a plasma during the top transparent contact deposition through sputtering. In some embodiments in which the cell is configured with a n-i-p structure, the buffer layer may be selected from a group including, but not limited to, MoOₓ, WOₓ, VOₓ, SnO₂, and TiO₂. In some embodiments in which the cell is configured with a p-i-n structure, the buffer layer material may be selected from a group including, but not limited to SnO₂, TiO₂, ZnO. The deposition of the buffer layer may be performed via ALD or thermal evaporation methods. The thickness of the buffer layer may range from about 0 to 30 nm.

For the second aspect, a transparent conductor on top of the second CSL is ideally used in order for the light to reach the active components located within cell (i.e. the absorber). The transparent conductor may include, but is not limited to, transparent conductive oxides (such as ITO: indium doped tin oxide, IZO: indium doped zinc oxide, AZO: aluminium doped zinc oxide, ZTO: zinc tin oxide), graphene, Ag nanowire or combinations thereof.

Similarly to the first aspect, in a first variant of the photovoltaic cell of the second aspect, the photovoltaic cell is a single junction cell. In a second variant of the second aspect, the photovoltaic cell is a tandem photovoltaic cell.

In the second variant of the second aspect, there may be provided a photovoltaic cell, wherein said cell is a tandem photovoltaic cell comprising, in order relative to incident light said cell is configured to receive: a first sub-cell; and a second sub-cell; said first sub-cell comprising: the absorber layer; the hole-transport layer; and the protective layer. When the photovoltaic cell is a tandem cell, the method of fabricating a photovoltaic cell in accordance with the second aspect may comprise: providing a second sub-cell, depositing a first sub-cell on top of the second sub-cell, said first sub-cell comprising: the absorber layer; the hole-transport layer; and the protective layer.

In the second variant, the second sub-cell may include a crystalline silicon substrate that is configured to absorb light from the low energy/higher wavelength spectrum of sunlight. For example, the second sub-cell may be able to absorb energy from red/near-infrared light (i.e. wavelengths of 800 to 1200 nm). Accordingly, the second sub-cell may comprise a relatively low band gap material.

Some embodiments of the second variant of the second aspect may comprise an interconnecting layer between the second carrier-selective transport layer and the second sub-cell. The interconnecting layer may be as describe above with reference to the first aspect.

In some other embodiments, the second carrier-selective transport layer directly contacts the second sub-cell. That is, the first sub-cell may be deposited directly on top of the second sub-cell.

In some embodiment in accordance with the second variant of the first and/or second aspects, providing the second sub-cell comprises: providing a crystalline silicon substrate; depositing an upper carrier-selective transport layer on top of the crystalline silicon substrate; depositing a lower carrier-selective transport layer below the crystalline silicon substrate; and depositing a lower electrode layer on the lower carrier-selective transport layer. The upper and lower carrier elective layers may be doped polycrystalline silicon layers.

In some embodiment in accordance with the second variant of the first and/or second aspects, the method may comprise, after providing the crystalline silicon substrate, passivating the crystalline silicon substrate so that: upper and lower passivating layers are provided on each side of the crystalline silicon substrate; the upper passivating layer is between the crystalline silicon substrate and the upper carrier-selective transport layer; and the lower passivating layer is between the crystalline silicon substrate and the lower carrier-selective transport layer. The passivating layers may be silicon oxide layers.

The first and second aspects each relate to cells including an absorber layer comprising a perovskite material. For either or each of the first and second aspects, the perovskite material may comprise a compound of formula (I):

ABX3 (I),

wherein:
A is a cation selected from a group consisting of: methyl ammonium (MA), formamidinium (FA), Cs, or Rb or any combination thereof;
B is a metal cation Pb; and
X is a halide anion selected from a group consisting of Br, Cl and I so that the ratio of Br:I is in the range of 0:1 to 1:0. The ratio of Br:I may be in the range of 0:1 to 1:1.

In some embodiments, A comprises one or more cations selected so that the molar percentage of A being: formamidinium ranges from 0% to 100%; methyl ammonium ranges from 0% to 100%; Cs ranges from 0% to 30%; and Rb ranges from 0% to 30%.

The perovskite material may be Cs_{0.05}Rb_{0.05}FA_{0.765}MA_{0.135}PbI_{2.55}Br_{0.45}, Cs_{0.1}FA_{0.765}MA_{0.135}PbI_{2.4}Br_{0.6}, Cs_{0.1}FA_{0.765}MA_{0.135}PbI_{2.22}Br_{0.78}, or Cs_{0.1}FA_{0.765}MA_{0.135}PbIBr.

A third aspect of the present invention provides a photovoltaic cell including a crystalline silicon substrate. In are first variant of the photovoltaic cell of the third aspect, the photovoltaic cell is a single junction cell. In a second variant of the third aspect, the photovoltaic cell is a tandem photovoltaic cell. Thus, the second variant may provide a configuration of a second sub-cell.

The third aspect of the invention provides a photovoltaic cell, photovoltaic cell, comprising: inner layers (the inner layers including: a lower carrier-selective transport layer; a crystalline silicon substrate; and an upper carrier-selective transport layer); at least one barrier layer; and an electrode; wherein said barrier layer is located between the inner layers and the electrode and is configured to suppress diffusion of metal from the electrode into the inner layers. Suppression may include reduction or prevention of diffusion.

The third aspect further provides a method of fabricating a photovoltaic cell, comprising: providing a precursor comprising: a lower carrier-selective transport layer a crystalline silicon substrate; and an upper carrier-selective transport layer; depositing a barrier layer on one or both of the lower carrier-selective transport layer and the upper carrier-selective transport layer; and fabricating an electrode on the or each barrier layer, said barrier layer being configured to suppress diffusion of metal from the electrode into layers of the precursor.

In the second variant of the third aspect, the method may comprise: providing a second sub-cell (said providing comprising: providing the precursor); and depositing a first sub-cell on top of the second sub-cell. Deposition of the first sub-cell may be performed in accordance with the first and/or second aspect of the invention. In the second variant, tandem photovoltaic cell may be provided, said cell comprising, in order relative to incident light said cell is configured to receive: a first sub-cell; a second sub-cell, said second sub-cell comprising the inner layers; the at least one barrier layer; and the electrode, so that said barrier layer is located between the second sub-cell and the electrode.

In each of the first and second variants, the crystalline silicon substrate may be as described above for the second sub-cell of the first aspect and/or second aspect. The upper and lower carrier elective layers may be doped polycrystalline silicon layers.

In a conventional photovoltaic cell, a metal electrode is in direct contact with one of the inner layers. For example, it is usually the case that one the CSL in a photovoltaic cell is in contact with the metal electrode. The metals may diffuse into the other, especially at the higher temperatures employed during the fabrication of the cells. Such diffusion can cause unwanted contamination of layers adjacent to the metal electrode. The resulting contamination can affect cell performance. Accordingly, in conventional photovoltaic cells, it may be desirable to control the fabrication conditions and/or choose metals that are less reactive (e.g. Ag).

The barrier layer may be advantageous in suppressing diffusion from the metal electrode and, consequently reaction between the CSL and the metal when the CSL is polycrystalline silicon-based. The efficacy of the barrier layer is dependent on its thickness. A thicker barrier layer will be more effective in preventing diffusion whereas a thinner layer will function better in allowing collection of charge carriers from the CSL and transfer of them to the electrode. A barrier layer that is too thick will perform well as a diffusion barrier. However, too thick layer will impede transfer of charge carriers leading to a high series resistance for the cell. Thus, the thickness of the barrier layer needs to be optimized in order to be able to perform its role as a diffusion barrier while not interfering with the functioning of the cell.

Depending upon the barrier layer composition and the type of photovoltaic cell, suitable barrier layer thicknesses may range from approximately 10 nm to 150 nm, such as about 17 nm to about 120 nm, or about 15 nm to about 50 nm, or 30 nm to about 120 nm for example. The barrier layer may be about 90 nm or less, such as about 60 nm or less. In some embodiments, the barrier layer may be about 100 nm.

As noted above the thickness of the barrier layer may be selected based on the desired suppression of diffusion and control of resistivity. In some other embodiments, the barrier layer thickness may also be selected based on the optical characteristics of the barrier layer material(s).

Some barrier layer materials, such as TiO₂ and MgF₂, may have a desirable refractive index and absorption co-efficient so that a barrier layer thickness can be selected to improve reflection at the rear interface. In this way, the barrier layer may improve overall performance of the sub-cell, in addition to enabling a greater variety of electrode materials to be used. In some embodiments, for an effective optical enhancement, the barrier layer it may be desirable to select a barrier layer having a refractive index between that of silicon and the metal electrode being used. Ideally, the barrier layer will also have a relatively low absorption coefficient. Generally, a lower absorption coefficient leads to better performance.

In some embodiments, it is desirable to select a barrier layer as thin as possible (e.g. around 15 nm to around 35 nm). In some of such embodiment, a thinner layer may be selected when the barrier layer is not being selected to also provide an optical enhancement. In some other embodiments, a thicker barrier layer (e.g. around 90 nm to around 110 nm, such as around 100 nm) may be selected. A thicker barrier layer may be selected based on the optical characteristics of the barrier layer material as well as the diffusion and resistivity. In some embodiments, a barrier layer of around 90 nm to around 120 nm (e.g. ˜100 nm), such as a TiO₂ and MgF₂ barrier layer, may provide improved reflection. Increasing the thickness of the barrier layer may result in an improvement in optical enhancement and overall current density yield. This can be observed from the average current density value (mAcm⁻²) with changing thickness. As noted above, increasing thickness also enhances diffusion suppression, but increases resistivity. Thus, the desired or optimised thickness may be selected to balance these factors.

In some embodiments, the barrier lay may enable use of relatively thinner polycrystalline silicon-based layers (e.g. 10 nm to 50 nm). The use of relatively thinner polycrystalline silicon-based CSLs may reduce parasitic absorption of light in the photovoltaic cell. In single junction cells, parasitic absorption results in a current loss of about 0.4-0.5 mA/cm2 for each 10 nm of polycrystalline silicon-based CSL when it is placed at the front of the silicon solar cells. A similar effect can be seen in tandem cells. Thus, in the tandem structure also, use of a thinner CSL may be beneficial. A thinner polycrystalline silicon-based layer has lower free carrier absorption of longer wavelength light, which allows more light to pass into the second sub-cell.

The use of a barrier layer enables the ability to employ harsher fabrication conditions in general for the photovoltaic cell. For example, use of higher temperatures during cell fabrication that can increase diffusion from metal electrodes, is possible with a barrier layer. Locating the barrier layer between the electrode and the inner layers creates a physical barrier through which diffusion of metal from the electrode may be reduced significantly even at elevated temperatures. In some cases, in a tandem cell without such a barrier layer, the process temperature for fabricating the upper (the first) sub-cell may be limited at about 200-300° C. In some embodiments in accordance with the second variant of the third aspect, the process temperature for fabricating the first sub-cell may be up to 500° C.

The use of a barrier layer may facilitate the employment of cheaper, and/or more widely available metals for the electrode. For example, electrodes made from Al and Cu may be relatively affordable and more readily available to Ag which is a more expensive and less available metal. However, Al and Cu are more reactive compared to Ag. These metals can diffuse more easily in the absence of a barrier layer, thus causing problems. Accordingly, the barrier layer may facilitate the use of Al and Cu electrodes which are more prone to diffusion.

In some embodiments, the photovoltaic cell comprises an upper electrode, the inner layers described above and a lower electrode. The barrier layer can be located either between the inner layers and the upper electrode or the inner layers and the lower electrode. Thus, the cell may comprise just one barrier layer that will prevent diffusion from that metal electrode that is blocked by the barrier layer from contacting the inner layers. Alternatively, a barrier layer can be located between both the inner layers and the upper electrode and the inner layers and the lower electrode. Such a configuration will prevent diffusion from metal electrodes located on either side of the inner layers.

In some embodiments, such as in some embodiments of the first variant, the photovoltaic cell includes an anti-reflection (AR) coating that extends in between the parts of the upper electrodes and is on the top of the upper CSL. The AR coating may reduce reflection from the surface of the silicon substrate (which is known to be as high as 30% of incident light) and direct more of the incident light into the silicon substrate. The AR coatings are also transparent to incident light so as to allow maximum light to enter the cell. Generally, they are a dielectric material that causes destructive interference of the reflected light from the upper CSL surface AR coatings can be chosen from a group of dielectric materials, such as silicon nitrides (SiNₓ), silicon oxides (SiOₓ), and titanium oxides (TiO₂). The AR layer can be deposited through chemical vapor depositions, physical evaporations or the solution methods. AR coatings may be either a single layer or a stack of dielectric layers, e.g. SiOₓ/SiNₓ.

In some other embodiments, the AR coating is formed using two or more sub-layers, with one of the sub-layers being the barrier layer. That is, the barrier layer may have antireflection properties. Accordingly, in some embodiments, the AR coating may comprise a stack including a dielectric layer and the barrier layer. For example, a stack comprising TiOₓ (the barrier layer) and SiOₓ may provide AR functions. Thus, in some embodiments, the AR coating of the cell comprises a stack comprising TiOₓ (the barrier layer) and SiOₓ. In some embodiments, the use of a stack to form the AR coating may enable the thickness of the coating and/or the barrier layer to be optimised to enhance the absorption of the silicon solar cells. The other sub-layer forming the AR coating may be deposited on top of the barrier layer, between the separate elements of the electrode. That is, the barrier layer will be deposited between the electrode and the inner layers of the cell, while the other sub-layer will extend in between the parts of the electrode on top of the barrier layer.

Alternatively, in some embodiments, the barrier layer acts as the AR coating. For example, in some embodiments, the barrier layer comprises a TCO. The TCO may have suitable AR properties such that a separate AR coating is not required.

As noted about, in embodiments of the second variant, the photovoltaic cell is a tandem cell comprising a first sub-cell and the second sub-cell. The second sub-cell comprises the inner layers. The photovoltaic cell comprises the at least one barrier layer and the electrode so that the at least one barrier layer can be located between the second sub-cell and the electrode.

Some embodiments of the second variant of the third aspect may comprise an interconnecting layer between the second carrier-selective transport layer and the second sub-cell. The interconnecting layer may be as described above with reference to the first aspect.

In some other embodiments, the second carrier-selective transport layer directly contacts the second sub-cell. That is, the first sub-cell may be deposited directly on top of the second sub-cell.

During fabrication of a tandem cell, the first sub-cell is usually deposited on the second sub-cell. Thus, the components of the second sub-cell are ideally able to withstand the fabrication conditions employed for the first sub-cell. The presence of a barrier layer may allow the use of higher temperatures during the fabrication of the first sub-cell. For example, in the tandem cell comprising a first sub-cell similar to that cell described above in the first aspect, TiO₂ layers are used as the ETL for the first sub-cell. In general, annealing temperatures of 500° C. are required to produce good quality TiO₂ layers. However, such a high temperature would result in diffusion from of aluminium from the electrode into the overlying CSL of the second sub-cell (in this case, poly-Si (n-) charge transport layers). The use of the barrier layer may allow a temperature of up to 500° C. to be applied enabling fabrication of good quality TiO₂ layers.

The barrier layer can comprise a transition metal oxide selected from a group consisting of transition metal oxides, transparent conductive oxides (TCOs), metal halides and metal nitrides. When the barrier layer is a TCO, it may be a TCO selected from the group comprising: indium tin oxide (ITO); tin-oxide (SnOₓ); GaInO; GaInSnO; ZnInO (IZO); ZnInSnO; Zinc Tin Oxide (ZTO); Ta or Nb-doped titanium oxide; F-doped tin oxide (FTO); aluminium doped zinc-oxide (ZnO:Al), and Ga doped zinc-oxide (ZnO:Ga). Transition metal oxides may include TiO₂, Ta₂O₃ and Ga₂O₃. In some embodiments, the barrier layer can comprise a metal halide selected from a group consisting of LiF and MgF₂. In other embodiments, the barrier layer comprises a metal nitride selected from a group consisting of TiN and TaN. That is, in some embodiments, the barrier layer is a TCO, TiO₂, Ta₂O₃, LiF, MgF₂, TiN, or TaN.

Metal nitrides, including titanium nitride (TiN) for example, have previously been considered for diffusion barriers for metallization systems. See for example C. Y. Ting, “TiN formed by evaporation as a diffusion barrier between Al and Si”, Journal of Vacuum Science and Technology 21, 14-18 (1982) and Park, K C., Kim, K B. “A Comparative Study on the Titanium Nitride (TiN) as a Diffusion Barrier Between Al/Si and Cu/Si: Failure Mechanism and Effect of “Stuffing”, MRS Online Proceedings Library 391, 211 (1995), each of which are incorporated by reference herein. The diffusion barrier properties of these materials may be utilized in the present invention in order to provide a suitable barrier layer between silicon layer and the metal contact layer.

Generally, the choice of a barrier layer depends on its work function, conductivity and thermal stability. In effect, it functions as a layer that prevents reactions from occurring between the electrode and overlying layers while allowing the cell to function.

The or each barrier layers can be deposited through different processes, including but not limited to ALD, thermal evaporation, sputtering and PECVD.

The electrode can be chosen from a metal selected from a group consisting of Al, Cu and Ag.

In some embodiments, the photovoltaic cell can comprise a passivating layer between each of the crystalline silicon substrate and the lower CSL and the crystalline silicon substrate and the upper CSL. The method of the third aspect may comprise, after providing the crystalline silicon substrate, passivating the crystalline silicon substrate so that: upper and lower passivating layers are provided on each side of the crystalline silicon substrate; the upper passivating layer is between the crystalline silicon substrate and the upper carrier-selective transport layer; and the lower passivating layer is between the crystalline silicon substrate and the lower carrier-selective transport layer. The passivating layers may be silicon oxide layers.

The second variants of the first and second aspects, as well as the third aspect of the present invention, relate to photovoltaic cells (in the case of the second variants of the first, second and third aspects: tandem photovoltaic cells) including a crystalline silicon substrate and CSLs. The fourth and fifth aspects provide methods of fabricating a doped precursor for use in fabricating a photovoltaic cell, in particular a doped precursor including a silicon substrate. Thus, embodiments of the first, second and/or third aspects may be fabricated in accordance with the methods of the fourth and/or fifth aspects.

The fourth aspect of the invention discloses a method of fabricating a doped precursor for use in fabricating a photovoltaic cell, said method comprising: providing an initial precursor comprising first and second polycrystalline silicon layers with a crystalline silicon substrate therebetween; and subjecting the initial precursor to a doping process to form a doped precursor, said doping process comprising: doping the first polycrystalline silicon layer with a first dopant using a thermal diffusion process to produce a first doped layer; and arranging the precursor in a back-to-back configuration with another precursor so that the first doped layers of each precursor are abutting; when in back-to-back configuration, doping the second polycrystalline silicon layer with a second dopant using a thermal diffusion process to produce a second doped layer; wherein the first dopant is one of a p-type dopant or a n-type dopant and the second dopant is the other of a p-type dopant or a n-type dopant. The p-type dopant may be boron. The n-type dopant may be phosphorus.

In some embodiments, the first dopant may be the p-type dopant and the second is the n-type dopant or vice versa.

In general, thermal diffusion is a high temperature process that is often used on an industrial scale to fabricate products. The process involves the use of high temperatures to enhance diffusion rates so as speed up desired reactions thereby creating products in a shorter span of time. By nature, the thermal diffusion process accelerates not only desired reactions but also undesirable reactions. One such undesirable reaction in case of the fabrication of silicon photovoltaic cells is contamination of parts of the precursor with a dopant when doping another part of the precursor to the cell. Charge transport layers based on silicon obtain their transport properties by virtue of specific dopants (p/n-type) being incorporated into the silicon. Mixing of the p- and n-type dopants can result in the layer losing its specific charge transport property.

In the past, the fabrication of double-sided polycrystalline silicon CSL has relied on the use of different technologies (such as ion implantation, in-situ doping though LPCVD), including using different techniques for each side of the silicon substrate. The use of different techniques, including a mixture of techniques for each side has been selected in the past to reduce the risk of the doping of the second side degrading the performance of the first doped layer due to contamination.

Embodiments of the fourth aspect of the invention relate to a method in which the same doping technique (thermal diffusion) can be used on each side. In accordance with the fourth aspect, the doping process may be performed without significant contamination of charge transport layers with undesired dopants. For example, contamination of a first doped polycrystalline silicon layer by the second dopant can be minimized/prevented.

In the fourth embodiment, unwanted doping of the first layer may be suppressed during doping of the second layer by arranging the precursors in a back-to-back configuration so that the first doped layers of each precursor are abutting. In this back-to-back configuration, exposure of the first doped layers to the second dopant is suppressed. The level of suppression achieved is affected by the alignment of the precursors in the back-to-back configuration. In some embodiments, to further enhance alignment, it may be advantageous to use polished wafers to form the precursor.

In some embodiments, before doping with the first dopant, the method may comprise arranging the precursor in a back-to-back configuration with another precursor so that the second polycrystalline layers of each precursor are abutting.

The present invention further provides a fifth aspect directed to a method of fabricating a doped precursor for use in fabricating a photovoltaic cell, said method comprising: providing an initial precursor comprising first and second polycrystalline silicon layers with a crystalline silicon substrate therebetween; annealing the first and second polycrystalline silicon layers in an inert atmosphere; and after annealing, subjecting the initial precursor to a doping process to form a doped precursor, said doping process comprising: doping the first polycrystalline silicon layer with a first dopant to produce a first doped layer; and doping the second polycrystalline silicon layer with a second dopant to produce a second doped layer wherein the first dopant is one of a p-type dopant or a n-type dopant and the second dopant is the other of a p-type dopant or a n-type dopant.

In a first option of the fifth aspect, the doping may be effected using thermal diffusion. Thus, in some embodiments, the method is in accordance with the fourth and fifth aspects. For example, some embodiments of the fourth aspect further comprise: before doping the doping the first polycrystalline silicon layer, annealing the first and second polycrystalline silicon layers in an inert atmosphere. In some other embodiments, other doping methods are used, which will be discussed further below.

The initial precursor of the fourth and fifth aspects comprises first and second polycrystalline silicon layers. These layers may be fabricated by depositing intrinsic polycrystalline silicon on two sides of a crystalline silicon substrate. Various techniques such as low pressure chemical vapor deposition (LPCVD) can be employed to grow the layers of intrinsic polycrystalline silicon. The key deposition control parameters are temperature and deposition pressure, as both increase deposition rate and can affect the resultant crystallinity. The flow rate of the precursor gas (Silane) should also be sufficiently high to avoid depletion of the precursor gas. In terms of output parameters for assessing the control of the deposition of the first and second polycrystalline silicon layers, thickness and uniformity within wafers and between wafers may be the main parameters. The deposition conditions may be controlled to control the thickness of the layer grown. For example, the temperature may be controlled from about 500° C. to 650° C. for about 15-120 minutes to fabricate intrinsic polycrystalline silicon layers of different thickness as desired. The thickness of the layers so obtained can range from 15 to 150 nm.

Typically, the initial precursor is provided with a passivating layer between the substrate and each of the polycrystalline layers. Commonly, the passivating layer is SiO₂. Thus, in embodiments in accordance with the fourth and/or fifth aspect, providing the initial precursor may comprise passivating the crystalline silicon substrate so that: passivating layers are provided on each side of the crystalline silicon substrate; a first passivating layer is between the crystalline silicon substrate and the first polycrystalline silicon layer; and a second passivating layer is between the crystalline silicon substrate and the second polycrystalline silicon layer. Most commonly the passivating layers (e.g. SiO₂) are formed using thermal oxidation, either in a separate process, or in situ before deposition of the polycrystalline silicon layers. Thin silicon oxide can also be grown chemically, most commonly through submersion in hot nitric acid. Or by applying UV radiation in ozone atmosphere.

In accordance with the fifth aspect, the initial precursor can be subjected to an annealing step in an inert atmosphere. Such an annealing step may improve the stability of the interfacial oxide and may increase the crystallinity of the polycrystalline silicon layers. Accordingly, the annealing step may improve both performance of the resulting cell and reproducibility of fabrication. The annealing may be performed at a temperature of from about 900° C. to about 1100° C. for about 5 mins to about 120 mins. In some embodiments, the annealing is performed at a temperature of about 1000° C. Alternatively or additionally, the annealing is performed for about 60 mins. The annealing of the initial precursor may be performed in a temperature range of about 950° C. to 1050° C. for a duration of 60 minutes. The inert atmosphere can be nitrogen gas.

After annealing, in accordance with the fifth aspect, the initial precursor fabricated can be subjected to a doping process using appropriate dopants to form a doped precursor. For example, the precursor may be treated with a boron and/or phosphorous containing dopant to form a doped precursor containing boron and/or phosphorous. The doping process can comprise doping the first polycrystalline silicon layer with a first dopant using a thermal diffusion process to produce a first doped layer. The first dopant can be made to contact the first polycrystalline silicon layer to form a first doped layer while avoiding contact with the second polycrystalline silicon layer.

In both the fourth and the fifth aspects, the conditions used during this process can affect the final concentration of the dopant in the layers. For example, the temperature and time of treatment may both be controlled to limit the diffusion to the desired extent (e.g. desired level of conductivity). Typically, thermal diffusion processes utilise two key steps: a diffusing (also known as a depositing or deposition) step in which the dopant source is supplied onto the surface of the precursor; and a drive in step in which the source dopants are diffused into the wafer by thermal energy to provide a suitable or desired concentration profile. In some embodiment, the drive-in step may be omitted or performed simultaneously with the deposition step. That is, the temperature and time conditions selected for the diffusing (deposition) step are suitable to effect dopant drive-in also.

During the diffusing step, a dopant glass is formed on the surface of the polycrystalline layer that is being subjected to this step. For example, in some embodiments, doping of the first polycrystalline silicon layer is performed before doping the second polycrystalline silicon layer; and doping of the first polycrystalline silicon layer is performed such that a first dopant glass forms on the first polycrystalline silicon layer (or vice versa). The first and second dopant glass layers are removed from the (now doped) first and second polycrystalline silicon layer, respectively, in a separate step before the precursor is used to fabricate a photovoltaic cell.

During the doping process, to suppress exposure of the initially doped layer to the dopant used to dope the other layer, the initial doping step may be performed such that the dopant glass may provide a masking layer. Thus, in some embodiments, doping of the first polycrystalline silicon layer is performed before doping the second polycrystalline silicon layer; and doping of the first polycrystalline silicon layer is performed such that a first dopant glass formed on the first polycrystalline silicon layer provides a masking layer (or vice versa).

Alternatively or additionally, a discrete masking layer may be deposited on to the initially doped layer to suppress exposure of the initially doped layer to the dopant used to doped the other layer. In some embodiments, doping of the first polycrystalline silicon layer is performed before doping the second polycrystalline silicon layer; and said method further comprises: between doping of the first and second polycrystalline silicon layers, forming a dielectric layer on the first polycrystalline silicon layer to provide a masking layer. Alternatively, doping of the second polycrystalline silicon layer may be performed before doping the first polycrystalline silicon layer; and said method may further comprises: between doping of the first and second polycrystalline silicon layers, forming a dielectric layer on the second polycrystalline silicon layer to provide a masking layer. In these embodiments, the dielectric layer may be SiO₂.

Returning to the diffusing and drive in steps that may be used for thermal diffusion in the fourth and/or fifth aspects, the temperature and time to be employed for these steps may vary depending on the type of dopant. For example, a temperature of 850° C. to about 1050° C. may be employed for each step with a p-type dopant. Similarly, the thermal diffusion may be performed for about 15 to 60 minutes for each step for a p-type dopant. A temperature of 800° C. to 1050° C. may be employed for each of the diffusing and drive-in steps for an n-type dopant with a time of about 15 to 60 minutes.

The doping of the first and second polycrystalline layers can be done sequentially. For example, the first polycrystalline layer may be subjected to a doping via thermal diffusion. This may be followed by a doping of the second polycrystalline layer.

In some embodiments of the fifth aspect, the doping process may use a method other than thermal diffusion. In particular, in a second option of the fifth aspect, the doping of the first and second polycrystalline silicon layers maybe accomplished by contacting them respectively with a p-type and n-type liquid dopant source. That is, in some embodiments of the fourth aspect, doping the first polycrystalline silicon layer comprises contacting the first polycrystalline silicon layer with a liquid p-type dopant-source; and doping the second polycrystalline silicon layer comprises contacting the second polycrystalline silicon layer with a liquid n-type dopant-source. Contacting the first polycrystalline silicon layer with a liquid p-type dopant-source may comprise spin-on or spray-on coating the first polycrystalline silicon layer with the liquid p-type dopant-source. Contacting the second polycrystalline silicon layer with a liquid n-type dopant-source may comprise spin-on or spray-on coating the second polycrystalline silicon layer with the liquid n-type dopant-source. In some embodiments, spin-on coating may be used for one layer and spray-on coating for the other.

Both spin-on or spray-on coating offer the ability to control the amount and thickness of the dopant source layer by controlling the spin speed or the amount of liquid that is deposited.

In some embodiments, spray-coating may advantageously enable large area substrates can be fabricated. Furthermore, spray coating may also enable better control over the deposition of the liquid dopant-source, thus minimising waste. Spray-on coating may allow precise control of the amount of liquid to be deposited for any given substrate.

The liquid dopant source can be chosen from commercially available doped spin-on glass mediums. For example, suitable liquid dopant sources may be obtained from Desert Silicon of 941 S. Park Lane Tempe, AZ 85281. As an example, P-250 as the n-type liquid dopant source. B-1500 may be used as the p-type liquid dopant source.

The first and second polycrystalline silicon layers can be deposited on the silicon substrate by employing the same methods as described above. Once the first and second polycrystalline silicon layers are fabricated, the initial precursor is contacted with the dopant source.

The silicon substrates can be coated (e.g. by spin-on coating) with and subsequently doped using the liquid dopant source in a series of steps.

In a one series of steps, after contacting the first polycrystalline silicon layer with a liquid p-type dopant-source (or alternatively a liquid n-type dopant-source), doping the first polycrystalline silicon layer may comprise: subjecting the first polycrystalline silicon layer to a first annealing at a first temperature of between about 80° C. to about 150° C. for about 10 mins to about 30 mins; and after the first annealing, subjecting the first polycrystalline silicon layer to a second annealing at a second temperature of between about 150° C. to about 250° C. for about 5 mins to 60 mins.

In some embodiments, only the second annealing may be performed. However, in some embodiments, the first annealing may be advantageous for the formation of a dopant precursor layer. In general, the liquid dopant-source that is contacting the polycrystalline silicon layer is subjected to one or two stages of annealing in order to convert or cure the liquid dopant-source and form a dopant precursor layer. The dopant precursor layer may be a dopant-containing glass. For example, the liquid dopant-source may be polysilazane-based such that the annealing converts the liquid dopant-source into a silicon-oxide-based layer.

The use of the first annealing may enhance the quality of the dopant precursor layer that is formed. In some embodiments, the first annealing is performed at a temperature of about 110° C. The first annealing may be performed for about 15 mins.

The second annealing may be performed at a temperature of about 200° C. In some embodiments, the second annealing is performed for about 8 mins.

The first annealing and/or the second annealing may be performed in an oxygen-containing atmosphere. In some embodiments, first annealing and/or the second annealing may be performed in air.

After formation of the dopant precursor layer on the first polycrystalline silicon layer, an intermediate annealing process may be performed. When doping the precursor using liquid dopant-sources, there can be a risk of auto-doping from the first doped surface to the second doped surface (e.g. from the phosphorus doped surface to the boron doped surface). Auto-doping can affect the reliability of a photovoltaic cell fabricated using the precursor. In particular, auto-doping may lead to both polycrystalline silicon layers being doped with the first-applied dopant. By including an intermediate annealing step, the consolidation of the dopant precursor layer formed from the first-applied liquid dopant-source may be enhanced. The migration of dopant from the dopant precursor layer into the opposite polycrystalline layer (i.e. the layer on which the dopant precursor layer has not been formed) may be suppressed. Thus, in the second option of the fifth aspect, the method may comprise: subjecting the precursor to an intermediate annealing in an inert atmosphere. The inert atmosphere may be used to provide an atmosphere that is free of impurities during annealing. Typically, an inert atmosphere is used when only the thermal effect is desired. The inert atmosphere can be nitrogen gas. In some embodiments, the inert atmosphere is provided by high purity nitrogen. However, in some other embodiments, the annealing may be performed in an oxygen-containing atmosphere, such as in air.

The intermediate annealing is performed at a temperature that is higher than the temperature typically used for forming the dopant precursor layer, but lower than the temperature used to activate the dopant (i.e. the temperature at which drive-in of the dopant into the underlying polycrystalline layer is performed). In some embodiments, intermediate annealing may be performed at a temperature of from about 350° C. to about 700° C., such as from about 350° C. to 550° C. (e.g. around 500° C.) for about 10 mins to about 60 mins. The intermediate annealing may be performed at a temperature of about 450° C. The intermediate annealing may be performed for about 25 mins.

Following intermediate annealing, the process may proceed to another series of steps in which, after contacting the second polycrystalline silicon layer with a liquid n-type dopant-source (or alternatively a liquid p-type dopant-source), doping the second polycrystalline silicon layer may comprise: subjecting the second polycrystalline silicon layer to a third annealing at a third temperature of between about 80° C. to about 150° C. for about 10 mins to about 30 mins; and after the third annealing, subjecting the second polycrystalline silicon layer to a third annealing at a fourth temperature of between about 150° C. to about 250° C. for about 5 mins to 60 mins.

In some embodiments, only the fourth annealing may be performed. However, in some embodiments, the third annealing may be advantageous for the formation of a dopant precursor layer. In general, as with the series of steps for the first polycrystalline layer, the liquid dopant-source that is contacting the polycrystalline silicon layer is subjected to one or two stages of annealing in order to convert or cure the liquid dopant-source and form a dopant precursor layer. The dopant precursor layer may be a dopant-containing glass. For example, the liquid dopant-source may be polysilazane-based such that the annealing converts the liquid dopant-source into a silicon-oxide-based layer.

The use of the third annealing may enhance the quality of the dopant precursor layer that is formed. In some embodiments, the third annealing is performed at a temperature of about 110° C. The third annealing may be performed for about 15 mins.

The fourth annealing may be performed at a temperature of about 200° C. In some embodiments, the fourth annealing is performed for about 8 mins.

The third annealing and/or the fourth annealing may be performed in an oxygen-containing atmosphere.

In some embodiments, the series of steps for the second polycrystalline layer may be performed first, followed by the series of steps for the first polycrystalline layer. Thus, in some embodiments, the doping of the second polycrystalline silicon layer is performed before doping the first polycrystalline silicon layer. In some of these embodiments, after doping of the second polycrystalline silicon layer and before doping the first polycrystalline silicon layer, subjecting the precursor to the intermediate annealing (as described above) in an inert atmosphere.

The silicon substrate comprising the first and second dopant precursor layers can be subjected to an activation annealing step that results in the dopants being diffused into the first and second polycrystalline silicon layer. That is, during activation annealing, the dopants from the dopant precursor layers are diffused into the relevant underlying polycrystalline silicon layers by thermal energy to provide a suitable or desired concentration gradient. Accordingly, in this step, the dopants residing in the first and second dopant are subjected to a high temperature in order to drive them into the polycrystalline layer. The temperature employed for this step may be in the range of about 900° C. to about 1050° C., such as about 950° C.-1050° C.

In some embodiments, before the activation annealing step, a masking layer may be deposited on either or each of the first and second dopant precursor layers. The masking layer(s) may reduce or prevent substantial cross-doping during activation annealing. In some embodiments, depositing the or each masking layer comprises forming a dielectric layer. The dielectric layer may be SiO₂ or SiNₓ.

In some embodiments, the first dopant precursor layers may be arranged in a back-to-back configuration such that they about each other. This may suppress migration of the dopant from the first dopant precursor layers into the second polycrystalline silicon layers and vice versa. Alternatively, the second dopant precursor layers may be arranged in a back-to-back configuration. The use of the back-to-back configuration may suppress contamination of the dopants into the opposite polycrystalline layer.

As noted above, in some embodiments, the liquid dopant sources may be deposited using a spray-on coating technique or a spin-coating coating. The above methods of fabricating a first and second doped layer are equally applicable to each deposition technique.

In some embodiments of the fourth and fifth aspects, the doped precursor may be subjected to a hydrogen passivation step before being used for fabrication of a photovoltaic cell. In some embodiments, the method comprises subjecting either or each of the first doped layer and the second doped layer to a hydrogen passivation process. In some embodiments, it may be beneficial to improve the levels of surface passivation provided by the polycrystalline silicon layers. For example, it may be advantageous to passivate electronically active Si dangling bonds at the c-Si/SiO₂ interface by hydrogenation. In general, the hydrogen passivation process provides an external source of hydrogen in order to effect hydrogenation. The hydrogen passivation process may comprise exposing either or each of the first doped layer and the second doped layer to hydrogen plasma.

Alternatively (or additionally), the hydrogen passivation process may comprise: depositing one or more hydrogen-containing dielectric layers on either or each of the first doped layer and the second doped layer; subjecting the one or more hydrogen-containing dielectric layers to a thermal annealing step or a firing step to effect hydrogenation of the layer on which said one or more hydrogen-containing dielectric layers is deposited; and removing the one or more hydrogen-containing dielectric layers from the doped precursor. The or each hydrogen-containing dielectric layer may comprise Al₂O₃, SiNₓ, or a transparent conductive oxide. The hydrogen-containing dielectric layer may act as hydrogen source because they typically also contain hydrogen from the precursors used to grow the layers either using ALD or PECVD. e.g. PECVD SiNₓ typically uses Dichlorosilane (SiH₂Cl₂) and Ammonia gas (NH₃) as precursors. The one or more hydrogen-containing dielectric layers may be deposited by atomic layer deposition (ALD), PE-CVD or sputtering. When used, the Al₂O₃ thickness may be between 5-25 nm, The SiNₓ thickness may typically 50-90 nm.

As noted above, after hydrogenation has been affected, the one or more hydrogen-containing dielectric layers may be removed from the doped precursor. In some other embodiments, the hydrogen-containing dielectric layer may form a passivation layer or an anti-reflection coating that it retained on the precursor for inclusion in the photovoltaic cell that is fabricated.

In some embodiments, the one or more hydrogen-containing dielectric layers comprises a first hydrogen-containing dielectric layer and a second hydrogen-containing dielectric layer; wherein: a first hydrogen-containing dielectric layer is depositing on either or each of the first doped layer and the second doped layer; and a second first hydrogen-containing dielectric layer is deposited on the or each first hydrogen-containing dielectric layer. The first hydrogen-containing dielectric layer may comprise Al₂O₃ and the second hydrogen-containing dielectric layer may comprise SiNₓ.

After deposition, the one or more hydrogen-containing dielectric layers are subjected to a thermal annealing or firing step that results in hydrogenation of of the layer on which said one or more hydrogen-containing dielectric layers is deposited. For example, the one or more hydrogen-containing dielectric layers may be subjected to a firing step. In the firing step, the one or more hydrogen-containing dielectric layers may be exposed to the peak firing temperature for a relatively short time interval (<10 s). The peak firing temperature may be from about 750 to about 900° C. In some embodiments, the firing step comprises passing the precursor through a furnace using a conveyor belt.

In some embodiments of the thermal annealing step, the one or more hydrogen-containing dielectric layers are subjected to a thermal annealing at a temperature from about 400° C. to about 750° C., for a duration of 1 min to 60 mins.

Following hydrogenation, the dielectric layers may be removed by subjecting the layers to etching in HF. The doped precursor may now be ready for use in the fabrication of a photovoltaic cell.

In a sixth aspect, the present invention provides a method of fabricating a photovoltaic cell, said method comprising: providing a doped precursor, said doped precursor fabricated according to the fourth and/or fifth aspects; and depositing an electrode layer on one of the p-type doped layer and the n-type doped layer. The electrode may be deposited in line with known processes for cells having polycrystalline silicon CSLs. In some embodiments, the deposition of the electrode is in accordance with the third aspect. Accordingly, some embodiments of the sixth aspect include a barrier layer.

In a seventh aspect, the present invention provides a method of fabricating a tandem photovoltaic cell, said method comprising: fabricating a second sub-cell using a doped precursor fabricated according to the the fourth and/or fifth aspects such that said second sub-cell comprises, in order relative to incident light said photovoltaic cell is configured to receive: an upper carrier-selective transport layer; the crystalline silicon substrate; and a lower carrier-selective transport layer; wherein the upper carrier-selective transport layer comprises one of the p-type doped layer or the n-type doped layer and the lower carrier-selective transport layer comprises the other of the p-type doped layer or the n-type doped layer; and depositing a first sub-cell on top of the second sub-cell. In some embodiments, the deposition of a first sub-cell on top of the second sub-cell is performed in accordance with the second variants of the first, second and/or third aspects.

In an eight aspect, there is provides a method of fabricating a tandem photovoltaic cell, said method comprising: fabricating a second sub-cell such that said second sub-cell comprises, in order relative to incident light said tandem photovoltaic cell is configured to receive: an upper carrier-selective transport layer; the crystalline silicon substrate; and a lower carrier-selective transport layer; said fabricating comprising: providing an initial precursor comprising first and second polycrystalline silicon layers with the crystalline silicon substrate therebetween; and subjecting the initial precursor to a doping process to form a doped precursor, said doping process comprising: doping the first polycrystalline silicon layer with a p-type dopant to produce a p-type doped polycrystalline silicon layer, said doping comprising contacting the first polycrystalline silicon layer with a liquid p-type dopant-source; and doping the second polycrystalline silicon layer with a n-type dopant to produce a n-type doped polycrystalline silicon layer, said doping comprising contacting the second polycrystalline silicon layer with a liquid n-type dopant-source; wherein the upper carrier-selective transport layer comprises one of the p-type doped layer or the n-type doped layer and the lower carrier-selective transport layer comprises the other of the p-type doped layer or the n-type doped layer; and depositing a first sub-cell on top of the second sub-cell. In the eighth aspect, the second sub-cell may be fabricated in accordance with the second option of the fifth aspect of the invention. In some embodiments, the deposition of a first sub-cell on top of the second sub-cell is performed in accordance with the second variants of the first, second and/or third aspects.

### Description of Illustrated Embodiments

In the following detailed description, reference is made to accompanying drawings which form a part of the detailed description. The illustrative embodiments described in the detailed description, depicted in the drawings and defined in the claims, are not intended to be limiting. Other embodiments may be utilised and other changes may be made without departing from the spirit or scope of the subject matter presented. It will be readily understood that the aspects of the present disclosure, as generally described herein and illustrated in the drawings can be arranged, substituted, combined, separated and designed in a wide variety of different configurations, all of which are contemplated in this disclosure.

In the figures below, like reference numbers have been used to denote like parts.

### First Illustrated Form

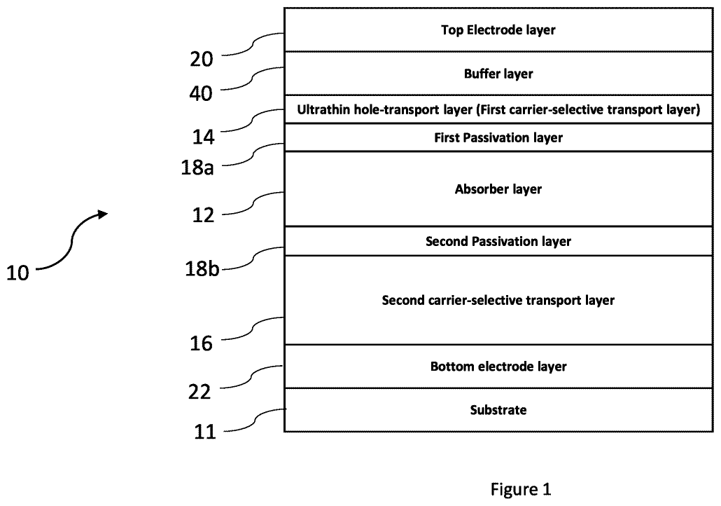

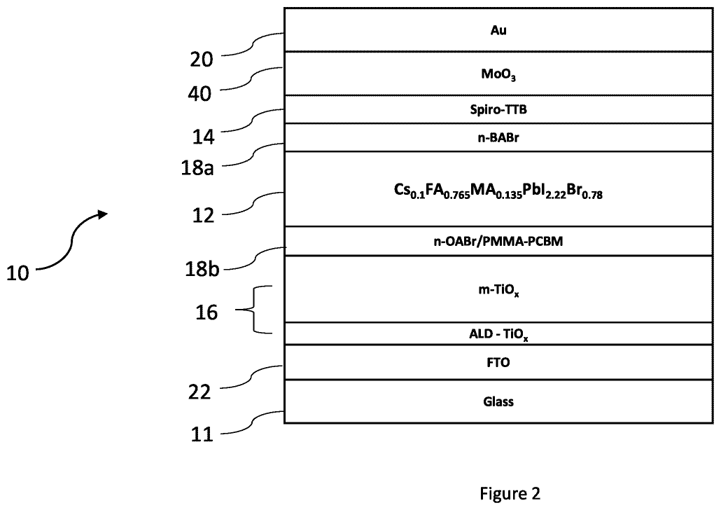

A first form of the invention according to the first aspect of the invention will now be described with reference to FIGS. 1 and 2.

Disclosed in FIG. 1 is a photovoltaic cell 10 according to the first aspect. FIG. 2 shows the schematic of a first specific embodiment according to the first aspect. In this example, the cell 10 is a single junction photovoltaic cell.

The cell 10 comprises an absorber layer 12 in the form of a perovskite-based material.

The cell 10 comprises a first carrier-selective transport layer 14 and a second carrier-selective layer 16. The first and second carrier-selective charge transport layers enable oppositely charged carriers generated during excitation of the absorber to be transported away from the cell 10. The first carrier-selective transport layer 14 is located above the absorber 12 while the second carrier-selective transport layer 16 is located below the absorber 12.

In this example, the first carrier-selective transport layer 14 is an ultrathin HTL. Thus, the second carrier-selective transport layer 16 is an ETL. In other embodiments, the second carrier-selective transport layer 16 can be an ultrathin HTL and the first carrier-selective transport layer can be an ETL. The ultrathin HTL 14 provides a pathway for transport of the holes generated during excitation of the absorber 12.

The cell 10 comprises a first passivation layer 18a in contact with the upper surface of the absorber 12 and a second passivation layer 18b in contact with a lower surface of the absorber 12.

The cell 10 comprises a top electrode layer 20 and a bottom electrode layer 22 that provide a pathway for charge carriers to exit the cell and flow through an external circuit in order to recombine with oppositely charged carriers generated during excitation.

The cell 10 can be deposited on a substrate 11. In this example, the substrate used is glass.

### Absorber Layer 12

The absorber layer 12 may comprise a perovskite material with a formula of ABX₃, wherein: A is a cation such as (but is not limited to) methyl ammonium (MA), formamidinium (FA), Cs, Rb, and mixtures thereof; B is Pb, X is a halide such as (but is not limited to) I, Br, Cl. The composition of the cation A may be a composition in which: the molar percentage of FA ranges from 0% to 100%, MA ranges from 0% to 100%, Cs ranges from 0% to 30%, and Rb ranges from 0% to 30%.

The absorber layer 12 is conductive. The conductivity can be adjusted by composition adjustment, process control to modify crystallization parameters, material doping, film morphology and post-treatment conditions, for example.

The band gap of the perovskite may be tuned by adjusting the ratio of Br and I from 0:1 to 1:0. For example, the ratio of Br:I can be adjusted from 0:1 to 0.5:0.5 to achieve a bandgap of 1.55˜1.85 eV. This is possible as the valence band of perovskite is dominated by halide orbitals from the X-site halide anions. For example, the band gap of MAPbI₃ is around 1.55 eV while the band gap of MaPbBr₃ is 2.2 eV.

The ratio between the cations affects the material structure/phase stability. This ratio can be fixed once the desired band gap is achieved by adjusting the ratio of Br:I.

In the illustrated embodiment, the perovskite material is Cs_{0.1}FA_{0.765}MA_{0.135}PbI_{2.22}Br_{0.78}. In other embodiments, the perovskite material may be Cs_{0.05}Rb_{0.05}FA_{0.765}MA_{0.135}PbI_{2.55}Br_{0.45}, Cs_{0.1}FA0.765MA_{0.135}PbI_{2.4}Br_{0.6}, Cs_{0.1}FA_{0.765}MA_{0.135}PbIBr or Cs_{0.1} Rb_{0.05}FA_{0.765}MA_{0.135}PbI_{2.22}Br_{0.78}Cl_{0.015}.

The perovskite layer can be prepared by the evaporation method or the solution method.

For solution-processed perovskite, the precursor concentration may include 0.96M PbI₂, 0.99M FAI, 0.165M PbBr₂, 0.18M MABr and 0.13M CsI in 1 ml of N,N′-dimethylformamide (DMF)/dimethyl sulfoxide (DMSO) (8:2, v/v). In other embodiments, the precursor concentration may range from 0.5 M to 1.5 M.

The perovskite solution is spin-coated on to a substrate with one step or two steps. For the one-step method, the perovskite may be spin-coated at a rate in the range of 1000 rpm/s to 8000 rpm/s. For the two-step spin-coating process, the first step may have a spin-coating speed of 1000 rpm/s with ramping of 100 rpm/s for 10 s. The second step has a spin-coating speed of 4000 rpm/s, with ramping of 1000 rpm/s for 25 s. A chlorobenzene dripping process occurs 5 s before the spin-coating process ends. Chlorobenzene dripping volume may be 150 μl for a substrate size of 1.2 cm×1.4 cm.

The thickness of the perovskite layer can be adjusted by controlling the deposition conditions. For example, thickness in the range of 100 nm to 1500 nm may be achieved.

### Ultrathin Hole-Transport Layer 14

As described above, the ultrathin HTL 14 facilitates the transfer of holes generated in the absorber 12.

In the illustrated embodiment of FIG. 2, the ultrathin HTL 14 is composed of 2,2′,7,7′-Tetra(N,N-di-p-tolyl)amino-9,9-spirobifluorene (Spiro-TTB).

The layer underlying the ultrathin HTL in this embodiment described is the first passivation layer 18a. Thus, the ultrathin HTL 14 needs to be thick enough so as to substantially cover the first passivation layer 18a.

In some embodiments, the thickness of the ultrathin HTL 14 can vary between 5 nm-25 nm. In other embodiments, the thickness of the ultrathin HTL 14 can vary between 5 nm to 35 nm. In some embodiments, the ultrathin HTL 14 has a thickness of less than 100 nm while in other embodiments, the ultrathin HTL 14 has a thickness of less than 50 nm.

In this example, the ultrathin HTL 14 is deposited on the first passivation layer 18a. In other embodiments, the ultrathin HTL may be deposited on a bottom electrode layer 20.

### Electron-Transport Layer 16

In the embodiment shown in FIG. 2, the electron transport layer (ETL) 16 is formed of two sub-layers. A first, denser TiO₂ sub-layer deposited using ALD, with a second sub-layer of mesoporous TiO₂ deposited on top of it.

### Passivating Layers 18a, 18b

As described earlier, the cell 10 comprises passivation layers 18a and 18b to achieve passivation on both sides of the absorber 12. The passivation layers prevent recombination of charge carriers generated in the absorber 12 at the surface of the absorber and allow the charge carriers to be move towards the ultrathin HTL 14 and the ETL 16. In this example, the first passivation layer 18a is in contact with the front surface of the absorber 12 while the passivation layer 18b is in contact with the rear surface of the absorber 12. The passivation layer is intrinsic in nature (i.e. non-conducting). Thus, the thickness of the layer may be controlled such that it permits movement of holes/electrons through to the ultrathin HTL 14/ETL 16, while sufficiently covering the front/rear surface of the absorber 12 to prevent recombination.

In some embodiments of the present invention, the passivation layer can be chosen from a variety of materials/combination of materials thereof selected from the group consisting of: polymethyl methacrylate (PMMA); n-Octylammonium Bromide (OABr); octylammonium iodide (OAI); octylammonium chloride (OACl); butylammonium iodide; butylammo-nium bromide; phenethylammonium iodide (PEAI); and phenyl-C61-butyric acid methyl ester (PCBM).

In the illustrated embodiment, the passivation layer 18a comprises n-BABr while the passivation layer 18b comprises a combination of PMMA/PCBM and n-OABr.

The layer thickness can be controlled within a specific range by controlling the deposition conditions. For example, to prepare the passivation layer 18a, n-BABr solution (2 mg/mL in Isopropanol) was utilized. A layer of n-BABr was deposited on the perovskite layer by spinning the solution at 5000 rpm for 15 s, followed by another annealing step at 100° C. for 10 minutes.

Similarly, to prepare the passivation layer 18b, the PMMA/PCBM passivation sub-layer may be prepared by spin coating the precursor solution at 4000 rpm for 30 s. The precursor solution may be prepared by dissolving 1 mg PMMA (Mw˜120000, Sigma Aldrich) and 3 mg PC61BM (Sigma Aldrich) into 1 mL Chlorobenzene. The n-OABr passivation sub-layer may be prepared from an n-OABr solution (2 mg/mL in Isopropanol). A layer of n-OABr may be deposited on the substrate by spinning the solution at 5000 rpm for 15 s, followed by annealing at 100° C. for 10 minutes.

### Buffer Layer 40

The cell 10 also comprises a buffer layer 40 in contact with the ultrathin HTL 14. The buffer layer functions to avoid or minimize damage to the underlying components, from plasma damage during sputtering. The buffer layer needs to be transparent to visible as well as near-infra red light as it is located at the top of the cell 10.

In the illustrated embodiment of FIG. 2, this buffer layer is made up of MoO₃ and protects the underlying Spiro-TTB ultrathin HTL 14 from plasma damage. In other embodiments, it can be chosen from a group including: V₂O₅, WO₃, SnO₂ or TiO₂. The thickness of the buffer layer can range from 1 to 30 nm. As above, this can be controlled by controlling the deposition conditions.

In embodiments in which the first carrier selective transport layer 14 is an ETL and not an ultrathin HTL, the buffer layer can be chosen from a group including: SnO₂, TiO₂, ZnO.

These materials can be deposited to form a dense layer by techniques such as thermal evaporation and atomic layer deposition (ALD). Further, these materials also display a suitable energy level alignment between the carrier selective charge transport layers 14/16 and the electrode thereby allowing the charges to be transported through them to the electrode.

### Top and Bottom Electrode Layers 20, 22

The cell 10 comprises a top electrode 20 connected to the buffer layer 40. As discussed above, the top electrode 20 provides a pathway for charge carriers (holes in this instance) to exit the cell 10 and flow through to an external circuit in order to recombine with oppositely charged carriers.

The cell 10 also comprises a bottom electrode 22 connected to the second carrier selective charge transport layer 16 and performs a similar function to the top electrode 20. In the illustrated embodiment, the bottom electrode is formed from a transparent conducting oxide (TCO) Fluorine-doped Tin Oxide (FTO).

### Substrate 11

The cell 10 is fabricated on a substrate 11. The substrate 11 provides a supporting surface that is robust and that is able to withstand the processing conditions and chemicals utilized in the fabrication of the cell 10. In the illustrated embodiment, the substrate 11 is glass.

It is essential that the substrate 11 is cleaned thoroughly prior to the start of the deposition processes to avoid contamination of the various components. In this regard, a sequential cleaning process is employed to prepare the substrate 11. The process involves sonicating the substrate with detergent, acetone, isopropanol, ethyl alcohol and deionized water (DI) water for 10 minutes with each of them. Following this, the substrate 11 is UV-Ozone treated for 15 minutes. After completing the cleaning procedures, the substrate is directly transferred to an ALD chamber for deposition of the next layer.

### Second Illustrated Form

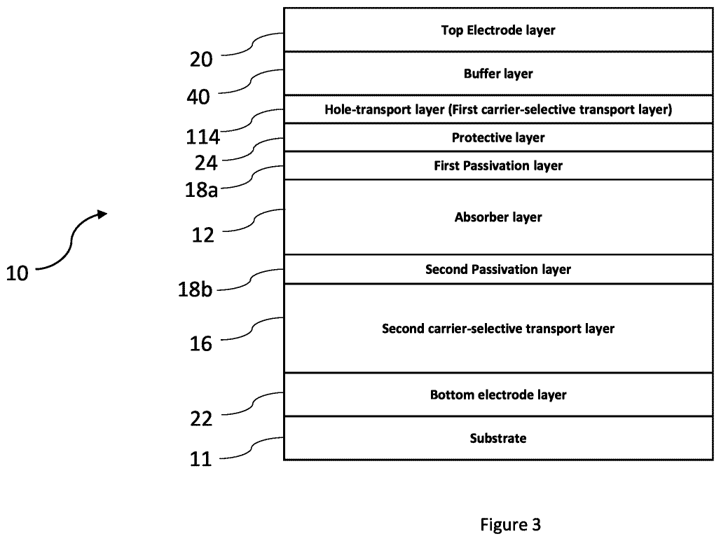

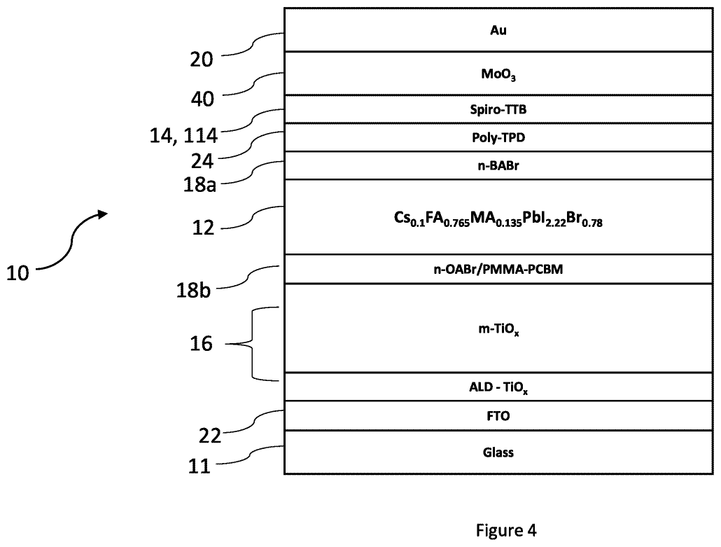

Disclosed in FIGS. 3 and 4 is a second form of the photovoltaic cell 10 according to the first and second aspects. All the components described for the first form are present. However, there are two differences between the first form embodiments and this second form embodiments. Firstly, the hole transport layer (HTL) 114 can be a conventional HTL (i.e. not necessarily an ultrathin HTL). Secondly, an additional protective layer 24 is located between the first passivation layer 18a and the HTL 114. The protective layer 24 has an energy level that is between that of the absorber 12 and the HTL 114. In this manner, the protective layer 24 may function to facilitate the transfer of the generated holes from the absorber 12. Thus, the protective layer 24 may act to improve the performance of the cell 10 compared to a cell without the protective layer 24.

The protective layer 24 may facilitate passivation of the perovskite surface. This passivating effect may be similar to that produced by the passivation layer 18a deposited on top of the absorber 12. In this sense, the protective layer 24 may perform two functions—i) facilitating charge transfer by providing an intermediate energy level and ii) preventing recombination of charge carriers although the former is the primary function, the latter being an additional useful function.

The protective layer 24 is chosen depending on the energy level alignment and polarity of the device. Thus, the energy level of the perovskite absorber 12 and the HTL 114 are identified. Then semiconducting materials with a work function that are close to the valence band of the absorber 12 are identified so as to not only enable an efficient charge transfer but also minimize the energy loss.

In the illustrated embodiment, the protective layer 24 is composed of poly(N,N′-bis-4-butylphenyl-N,N′-bisphenyl)benzidine (Poly-TPD). In other embodiments, the protective layer 24 can be chosen from the group consisting of: N,N′-Bis(naphthalen-1-yl)-N,N′-bis(phenyl)-2,2′-dimethylbenzidine (α-NPD) and N,N′-Bis(3-methylphenyl)-N,N′-diphenylbenzidine (TPD).

The charge transport properties of the protective layer can be varied by varying the molecular weight of the poly-TPD. Higher molecular weight poly-TPD can adopt a planar π-stacked configuration more easily, which improves the interchain connections necessary for charge transport.

In some embodiments, the weight molecular weight can be greater than 100K. In other embodiments, the weight average molecular weight of the poly-TPD can vary between 100K to 500K kDa.

### Third Illustrated Form

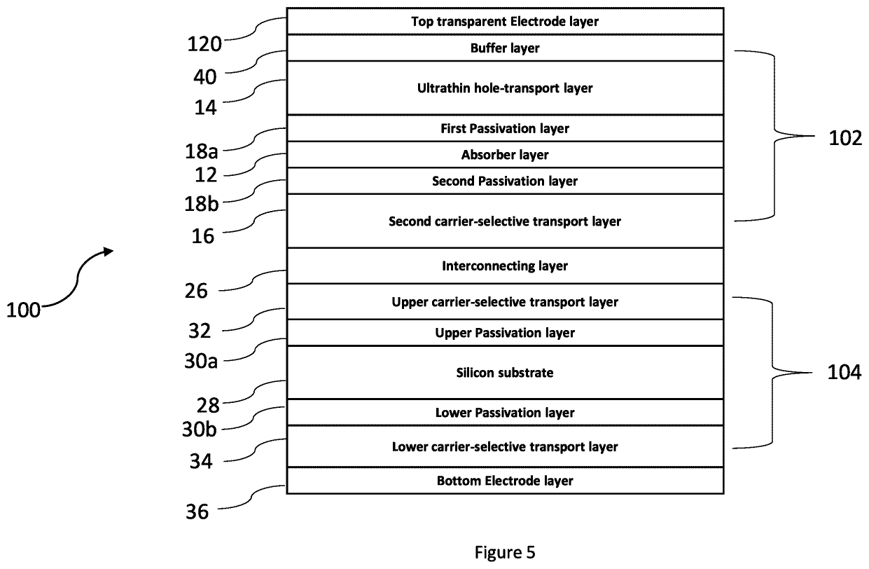

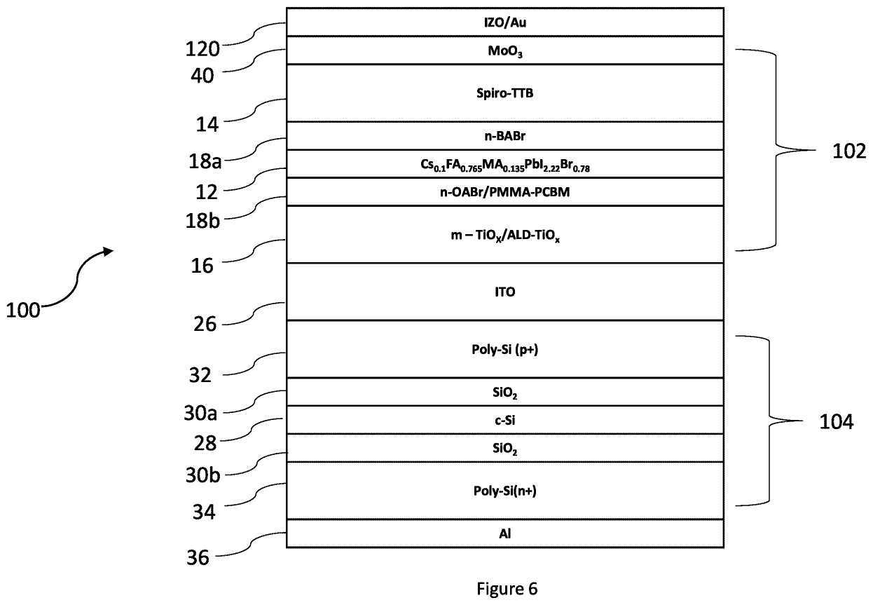

A third illustrated form of the invention will now be described with reference to FIGS. 5 and 6. Like reference numbers have been used to denote like parts. The common components may be as described above with reference to FIGS. 1 to 4. Thus, these components will not be redescribed, and the above description can be taken to apply equally to the embodiment of FIGS. 5 and 6.

Disclosed in FIG. 5 is a schematic of a tandem photovoltaic cell 100 according to the second variant of the first aspect of the present invention. FIG. 6 shows the schematic of a specific embodiment of the third form according to the second variant of the first aspect. The tandem cell 100 comprises a first sub-cell 102 and a second sub-cell 104. The tandem cell 100 may further comprise an interconnecting layer 26 that is located between the two sub-cells. Each sub-cell 102, 104 is able to trap light of different wavelength ranges, thereby enabling higher generation of charge carriers in the tandem cell 10 as a whole. During operation of the tandem cell 100, light (such as sunlight) that is incident on the first sub-cell 102 passes through it before reaching the second sub-cell 104. As light passes through the first sub-cell 102, the high energy/low wavelength portion of the light (blue light) is substantially absorbed by the perovskite-based material 12. The portion of light that is not significantly absorbed (i.e. red/near-infrared light) passes through the first sub-cell 102 and reaches the second sub-cell 104. In this manner, the tandem cell 100 utilizes a larger portion of the incident light to enable generation of more charge carriers that can be separated.

In this example, the first sub-cell 102 is in line with the first specific embodiment of the first form described above comprising an absorber layer 12 and an ultrathin hole transport layer 14. However, the bottom electrode layer 22 and the substrate 11 are not present. Rather, the first sub-cell 102 is connected to the second sub-cell 104. Further, the top electrode layer 120 is a transparent electrode layer (whereas the top electrode layer 20 in the first form embodiment was a full area gold layer). The top transparent contact may be formed of a TCO such as Indium tin oxide (ITO), indium zinc oxide (IZO), Zinc Tin Oxide (ZTO), Alumina doped zinc oxide (AZO). The TCO layer thickness may range from 5 nm to 150 nm. The TCO may be deposited with the sputter method or the solution method. For the sputter method, the TCO can be deposited with RF or DC mode. The power of the sputtering ranges from 20 W to 60 W. In the illustrated embodiment, the top electrode 120 was fabricated by sputtering ˜40-nm IZO on the buffer layer 40. The sputtering was performed for 60 min with 30 W of RF power under an Ar plasma, with a chamber pressure of 1.5 mTorr. Following this, gold fingers and busbars may be deposited on the IZO surface by thermal evaporation and using shadow masks. In one example, 100-300 nm gold metal electrode busbars may be be deposit on the full-area IZO surface by thermal evaporation with a metal mask. After finishing the IZO surface, the device will be transferred into the thermal evaporator chamber with pressure at around 10⁻⁵ pa. Then the gold will be deposited at a rate of 1 Å/s to form the metal electrode.

The second sub-cell 104 comprises an absorber in the form of a crystalline silicon substrate 28. The second sub-cell 104 is located below the first sub-cell 102. The second sub-cell 104 further comprises an upper passivation layer 30a deposited on the upper side of the silicon substrate 28 and a lower passivation layer 30b deposited on the lower side of the silicon substrate 28.

### Silicon Substrate 28

In the illustrated embodiment, the silicon substrate 28 utilized as part of the second sub-cell 14 comprises crystalline silicon (c-Si). There are two types of c-Si available
monocrystalline and multicrystalline silicon. In some embodiments, monocrystalline silicon may be utilized. In some other embodiments, multicrystalline silicon may also be utilized. In practice, monocrystalline silicon is most commonly used.

The silicon substrate 28 is also conductive. Conductivity is tuned by doping the silicon substrate by n-type dopants such as phosphorus, or p-type dopants such as gallium or boron. However, in some embodiments of the present invention, a crystalline silicon substrate with a high resistivity (i.e. very low dopant content) can be used.

The thickness of the silicon wafers may be in the range of 150 μm-400 μm. The resistivity of the wafers may range from 0.5-15 ohmcm.

The silicon substrate 28 may be subjected to a surface preparation treatment, such as a polishing or texturing process. The silicon substrate may be subjected to a surface preparation process to make it double-side polished, double-side textured, or one-side polished and the other side textured. In the illustrated embodiment, the silicon substrate 28 comprises a polished front surface adjacent a first passivation layer 30a and textured rear surface adjacent a second passivation layer 30b (i.e. one-side polished and the other side textured surface).

The silicon substrate 28 is fabricated from high quality silicon wafers which may be obtained from suppliers such as Silchem, Longi etc.

The silicone substrate 28 is thoroughly cleaned to substantially remove any impurities. Impurities can have a significant effect on the performance, especially if they diffuse into the wafer during high temperature processing, or diffuse outwardly into the equipment used for handling the wafers, causing significant issues in a production line. An RCA process may be employed to clean the silicon substrates 18. In some embodiments, the RCA cleaning process may comprise the following protocol: RCA1=10 minutes, 80° C. dip in 5:1:1 NH₄OH: H₂O₂:H₂O; 1% wt HF dip for 1 min; RCA2=10 minutes, 80° C. dip in 5:1:1 HCl:H₂O₂:H₂O; 1% wt HF dip for 1 min. After each step, the wafers may be dipped in deionized water for thorough cleaning before the next step. The cleaned wafers may then be dried with N₂.

### Upper and Lower Carrier Selective Charge Transport Layers 32 and 34

The upper and lower carrier selective charge transport layers 32 and 34 are each polycrystalline silicon-based layers. The layers 32, 34 are provided by first depositing intrinsic polycrystalline silicon and then subjecting the layers to a doping process. The upper carrier selective charge transport layer 32 is a p-type doped layer, which has been doped with boron. The lower carrier selective charge transport layer 34 is a n-type doped layer, which has been doped with phosphorus. In some other embodiments, the upper carrier selective charge transport layer 32 is a n-type doped layer and the lower carrier selective charge transport layer 34 is a p-type doped layer.

### Passivation Layers 30a, 30b

The passivation layers 30a, 30b are layers of silicon oxide.

### Bottom Electrode 36

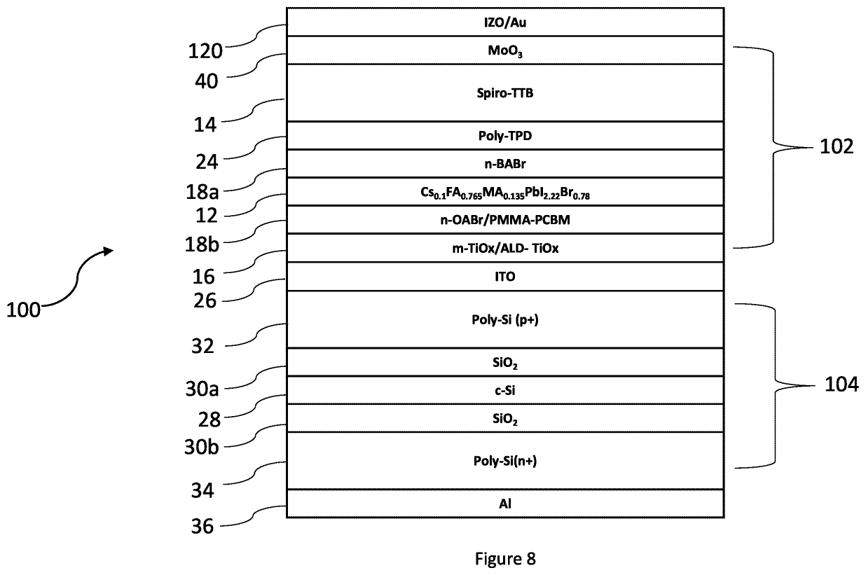

The cell 100 comprises a bottom electrode 36 that is connected to the lower carrier-selective transport layer 34. Similar to the bottom electrode 22 in the first and second form embodiments, the bottom electrode 36 provides a pathway for charge carriers (holes in this instance) to exit the cell 100 and flow through to an external circuit in order to recombine with oppositely charged carriers. In the illustrated embodiment, the bottom layer is composed of Al (as shown in FIG. 8). In other embodiments, Ag, Cu or a stack of one or more of these metals may be used. The thickness of the electrode may range from 100 nm to 3000 nm.

Cell with Interconnecting Layer

The first sub-cell 102 can be connected to the second sub-cell 104 in two ways. In one embodiment, an interconnecting layer 26 (ICL) is located between the ETL 16 and the second sub-cell 104 (as best shown in FIGS. 5 and 6). The ICL may be referred to as a recombination layer. An ICL may allow electrical connection to be established between the two sub-cells in order to complete the electrical circuit. It may function as a low resistivity layer that allows recombination of charge carriers from the first and second sub-cells. The ICL may be deposited between the first and second sub-cells. Thus, the ICL may be capable of forming an interface with both the sub-cells.

Charges from the ETL 16 will be transferred to the ICL under the influence of electric field to promote such recombination in the ICL. For example, in the illustrated embodiments, the electrons gathered by the ETL 16 will be able to combine with holes that are generated in the second sub-cell 104 in the ICL. Alternatively, in embodiments where the second carrier selective transport layer 16 is a hole transport layer, holes gathered in that layer will be able to combine with electrons generated in the second sub-cell 104. The ICL may be chosen from a variety of materials including but not limited to transparent conductive oxides such as Indium tin oxide (ITO), Indium zinc oxide (IZO), zinc tin oxide (ZTO), alumina doped zinc oxide (AZO). The ICL can be deposited either via sputtering or the solution method. The ICL may, in some alternative embodiments, be in the form of a tunnelling junction layer.

### Interconnect Free Cell

In a second option (not shown), the ETL 16 directly contacts the second sub-cell 104. Thus, in some embodiments, the first and second sub-cells may be connected directly without the ICL. The direct-contact interface formed between the first and second sub-cells can perform the function of the ICL (i.e. providing a low resistive layer where recombination may occur). Accordingly, the direct-contact interface ideally has low resistivity and allows for a recombination of electrons and holes from the first and second-sub cells.

The direct-contact interface is formed between complementary charge transport layers. This is critical to promote recombination of holes and electrons at the interface. For example, the hole transport or electron transport layers of the first and second sub-cells may be in direct contact with each other. More specifically, the electron transport layer of the first sub-cell may be in direct contact with the hole transport layer of the second sub-cell. Alternatively, the HTL of the first sub-cell may be in contact with the ETL of the second sub-cell to form this interface. Such an interface may not be formed between a HTL of the first sub-cell and the HTL of the second sub-cell (or an ETL of the first sub-cell and an ETL of the second sub-cell). Pairs of carrier selective transport layers that may form a direct-contact interface include, but are not limited to: TiOₓ/p-type doped polycrystalline silicon CSL (p+ poly-Si); SnOₓ/p+ poly-Si; MoOₓ/n-type doped polycrystalline silicon CSL (n+ poly-Si); and VOₓ/n+ poly-Si.

### Fourth Illustrated Form

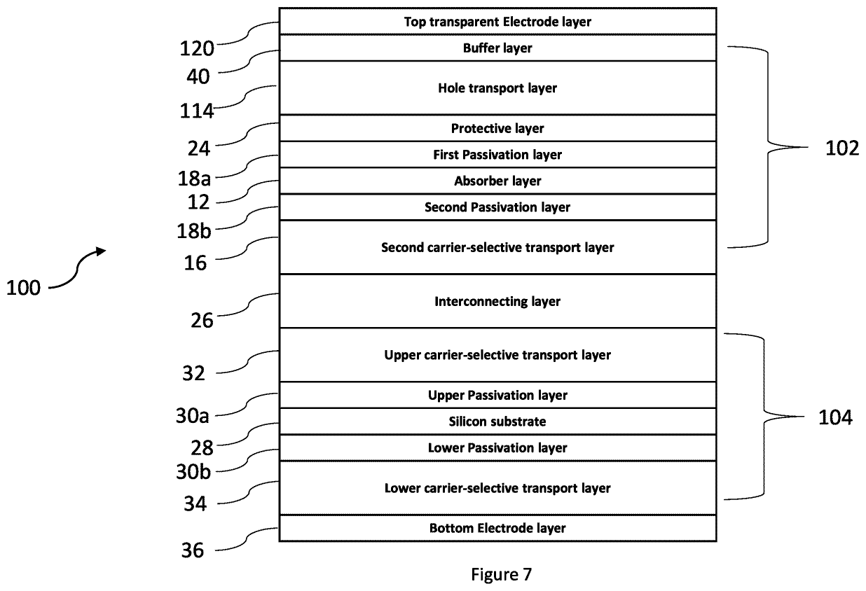

Disclosed in FIG. 7 is a schematic of a tandem photovoltaic cell 100 according to a second variant of the second aspect of the present invention. FIG. 8 shows the schematic of a specific embodiment of the fourth form according to second variant of the second aspect of the invention. The tandem photovoltaic cell comprises a first sub-cell 102 and a second sub-cell 104. The first sub-cell 102 is according to the second form embodiment of the invention according to the second aspect described above (i.e. including a protective layer). Similar to the third form embodiment described above, the first sub-cell 102 does not have the bottom electrode layer 22 and substrate 11 and is instead connected to the second sub-cell 104. The first sub-cell 102 can be connected to the second sub-cell 104 in two ways—either through an ICL 26 (as best shown in FIGS. 7 and 8) or directly (not shown). The description of the connection between the two sub-cells above is equally applicable to this embodiment.

### Fifth Illustrated Form

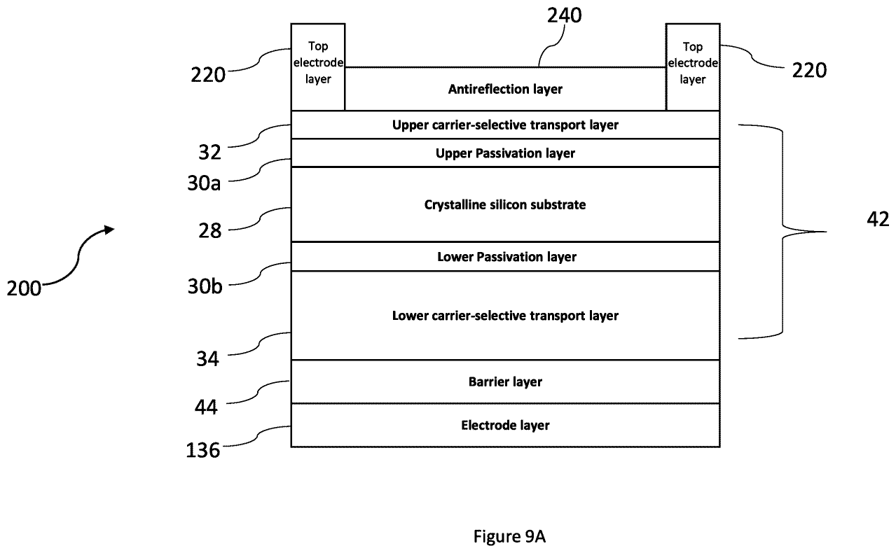

A fifth form of the invention according to the third aspect will now be described with reference to FIG. 9. Disclosed in FIG. 9 is a schematic of a photovoltaic cell 200. The photovoltaic cell 200 is a single junction cell comprising, in order relative to incident light, layers 42 overlying the electrode 136. The inner layers 42 includes a crystalline silicon substrate 28 and a lower carrier-selective transport layer 34. The description of the like-numbered layers provided above in the third form specific embodiment (see FIG. 6) of the invention are equally applicable here.

With respect to the substrate 28, often, for single junction cells the substrate 28 has a thickness of >150 μm.

### Electrode 136

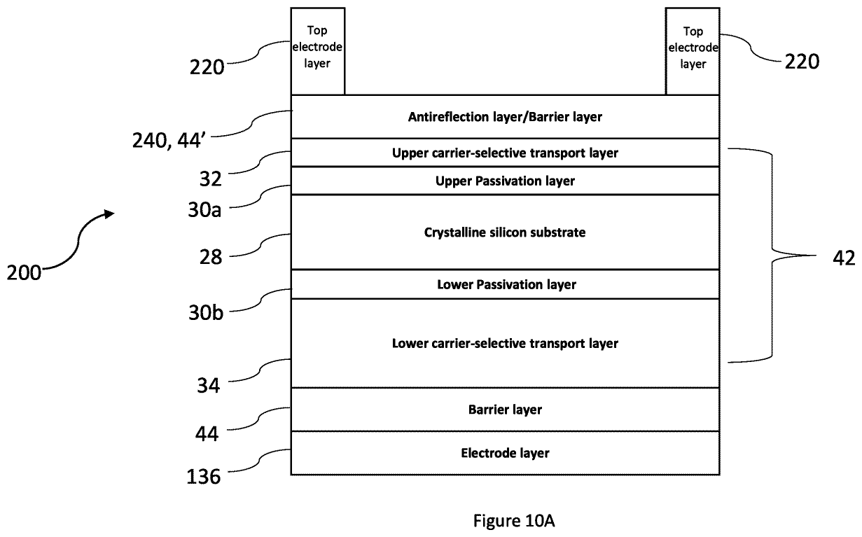

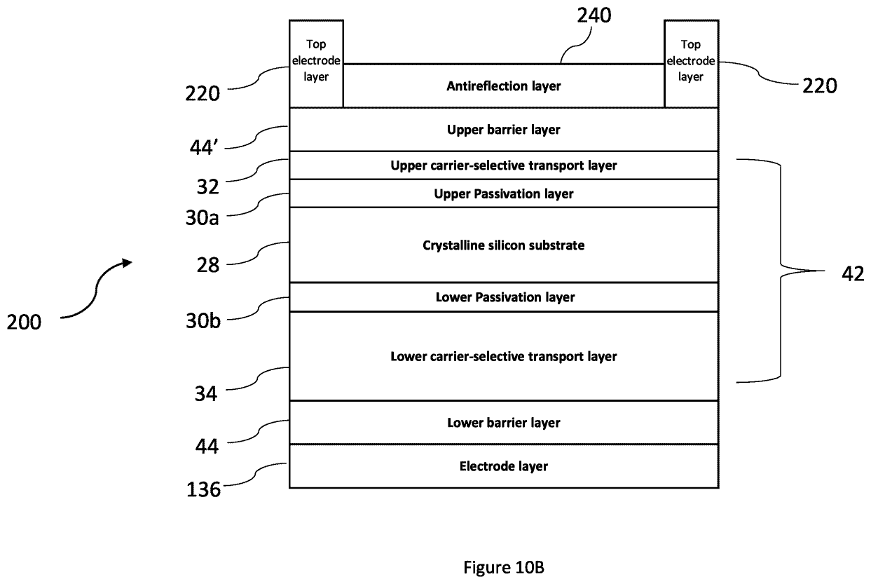

The cell 200 comprises an electrode 136. The electrode 136 performs a similar function as the bottom electrode 36 that is connected to the lower carrier-selective transport layer 34 in the third and fourth form specific embodiments described above. The electrode 136 provides a pathway for charge carriers to exit the cell 10 and flow through to an external circuit in order to recombine with oppositely charged carriers. In the illustrated embodiment, the electrode 136 is composed of Al (as shown in FIG. 10). In other embodiments, Ag, Cu or a stack of one or more of these metals may be used. The thickness of the electrode may range from 100 nm to 3000 nm.

The electrode 136 may be deposited by techniques such as thermal evaporation. Apart from the thermal evaporation, there are two main techniques which may be used to fabricate metal electrodes: screen-printing (utilising patterned screen, metal pastes, and firing); and electrode plating. Other techniques include e-beam evaporation, ink-jet printing methods, and sputtering. The electrode 136 may be deposited in accordance with methods known in the art.

### Barrier Layer 44

The cell 200 further comprises a barrier layer 44 that is configured to suppress diffusion of metal from the electrode 136 into the overlying layers 42. The barrier layer 44 is located between the electrode 136 and the lower carrier-selective charge transport layer 34. Alternatively or additionally, in some other embodiments, another barrier layer that is configured to suppress diffusion of metal from the top electrode 220 into the inner layers 42 is provided. The upper barrier layer is located between the top electrode 220 and the upper carrier-selective charge transport layer 32 and may be fabricated in the same manner as the barrier layer 44.

The use of a barrier layer 44 allows for the use of metals that are cheaper and more plentiful for the electrode 136. For example, as described above, Al can be employed. Al is available in plentiful supply and a cheaper metal compared to Ag. Similarly, Cu is another metal that is widely available and cheaper compared to Ag. However, the cheaper metals are more prone to reactions with the overlying layers (crystalline silicon substrate 28 and lower carrier-selective transport layer 34) when high temperature fabrication processes are employed.

The barrier layer 44 can be chosen from a group consisting of transition metal oxides, metal halides, and metal nitrides. In the illustrated embodiment, the barrier layer 44 is made of TiOₓ. In other embodiments, the barrier layer can be chosen from a group consisting of: TCOs, TaO, LiF, MgF₂, and TaN.

The cell 200 comprises an anti-reflection layer 240. The AR layer 240 functions to trap incident light as discussed above. In this embodiment, AR layer is fabricated from a dielectric material (e.g. SiNₓ or other dielectric antireflection coating materials known in the art). The AR layer 240 may be deposited on top of the upper CSL 32.

The cell 200 comprises a top electrode 220 that functions similar to electrode 136 in providing a pathway for the charge carriers to exit the cell 200 and flow through an external circuit to recombine with oppositely charged carriers. In general, the top electrode 220 may have a similar or the same structure as the bottom electrode 136. As explained above, in the past, Ag was typically used for electrodes. But, with the inclusion of a barrier layers between the electrode and the inner layer 42 it is possible to use other (cheaper) metals, such as Al and Cu.

The top electrode may be a grid or mesh of the selected metal.

### Sixth Illustrated Form

A sixth form of the invention according to the third aspect will now be described with reference to FIGS. 10A and 10B. Disclosed in FIGS. 10A and 10B is a schematic of a photovoltaic cell 200. The photovoltaic cell 200 is a single junction cell comprising, in order relative to incident light, layers 42 overlying the electrode 136. The inner layers 42 includes a crystalline silicon substrate 28 and a lower carrier-selective transport layer 34. The description of the like-numbered layers provided above in the fifth form specific embodiment (see FIG. 9) of the invention are equally applicable here.

The sixth form differs from the fifth form in that it includes an upper barrier layer 44′, as well as a (lower) barrier layer 44. The upper barrier layer is configured to suppress diffusion of metal from the top electrode 220 into the inner layers 42. The upper barrier layer is located between the top electrode 220 and the upper carrier-selective charge transport layer 32. The use of a barrier layer 44 allows for the use of metals that are cheaper and more plentiful for the top electrode 220. The top electrode may be as described above for the fifth form.

In a first option for the sixth form illustrated by FIG. 10A, the upper barrier layer 44′ also acts as an antireflection (AR) layer 240. Thus, the material selected for the barrier layer 44′ has AR properties. Such barrier layer materials may be TCOs, such as (but not limited to) indium tin oxide (ITO); tin-oxide (SnOₓ); GaInO; GaInSnO; ZnInO (IZO); ZnInSnO; Zinc Tin Oxide (ZTO); Ta or Nb-doped titanium oxide; F-doped tin oxide (FTO); aluminium doped zinc-oxide (ZnO:Al), and Ga doped zinc-oxide (ZnO:Ga).

In a second option shown in FIG. 10B, the upper barrier layer 44′ is a layer that is separate from the AR layer 240. In this embodiment, the AR layer may be formed using a dielectric material, such as silicon nitrides (SiNₓ) or silicon oxides (SiOₓ). When the AR layer 24 is formed of a material that is not conductive, it is deposited between the elements of the electrode 220 on top of the barrier layer 44′, as shown in FIG. 10B.

In this second option, a broader range of materials for the barrier layer 44′ can be used, as the barrier layer 44′ is not also acting as the AR layer (in contrast to the first option shown in FIG. 10A). The barrier layer 44′ may be chosen from a group comprising, but not limited to, transition metal oxides, metal halides, and metal nitrides. In the illustrated embodiment, the barrier layer 44′ is made of TiOₓ. In other embodiments, the barrier layer can be chosen from a group consisting of: TaO, LiF, MgF₂, and TaN.

### Seventh Illustrated Form

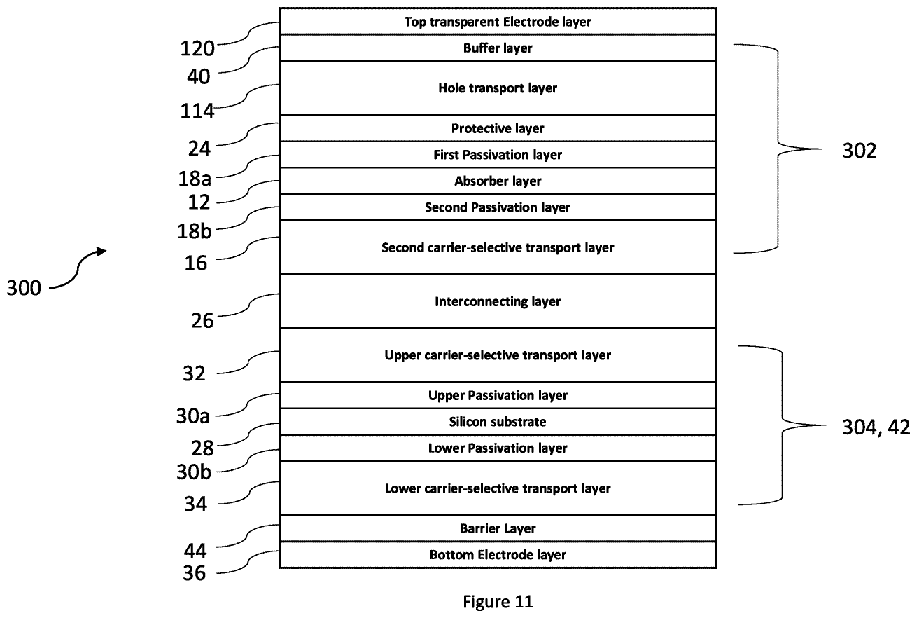

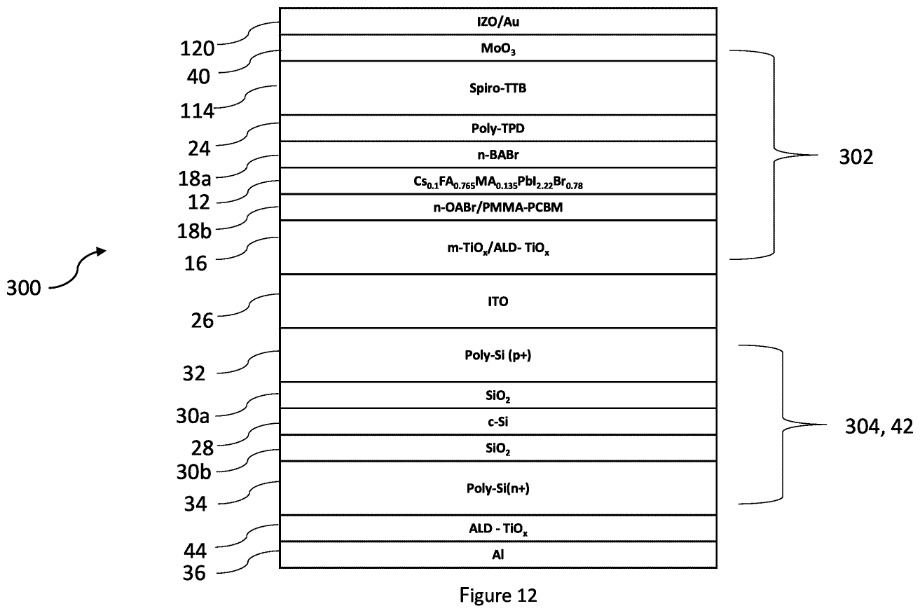

Disclosed in FIG. 11 is a schematic of a photovoltaic cell 300. FIG. 12 discloses a specific embodiment of the seventh form of the invention according to the second variant of the third aspect. The photovoltaic cell 300 is a tandem junction cell comprising a first sub-cell 302 and a second sub-cell 304.

The first sub-cell 302 is similar to the first sub-cell 102 described above for the first and second form specific embodiments. The description provided for the first sub-cell 102 is equally applicable for the first sub-cell 302.

The second sub-cell 304 comprises the inner layers 42 described above. The description of these layers provide above in the third form specific embodiment of the invention are equally applicable here. The use of a barrier layer 44 allows higher processing temperatures to be utilized in the fabrication of the various components of the cell 200.

In the illustrated embodiment of this seventh form, ICL 26 is provided. The ICL may be as described above for the third form.

Alternatively, some embodiments of the seventh form can be configured without an ICL 26, such that the ETL 16 directly contacts the second sub-cell 304.

### Eighth Illustrated Form

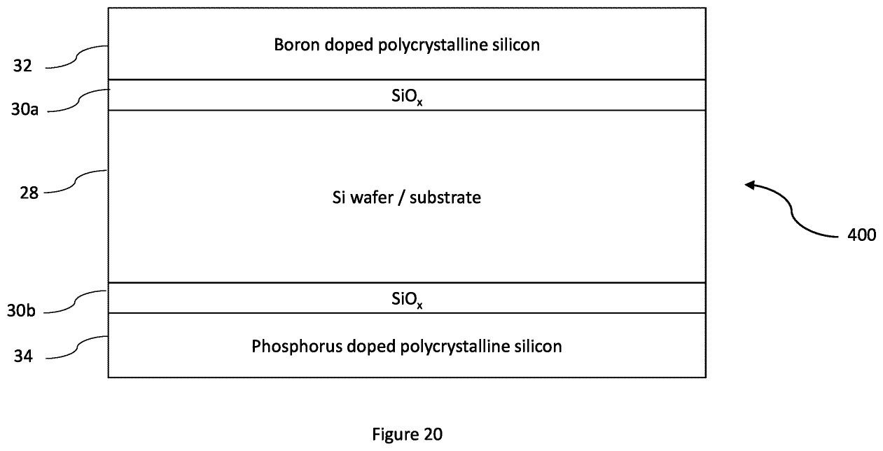

Disclosed in FIG. 20 is a schematic of a doped precursor 400 that can be utilized to fabricate a silicon photovoltaic cell. The precursor may be fabricated according to the fourth and/or fifth aspects. The precursor 400 comprises a crystalline silicon substrate 28, upper and lower passivation layers 30a and 30b, upper carrier-selective transport layer 32 and a lower carrier-selective transport layer 34. The precursor 400 together can be subjected to further fabrication steps to form a fully functioning single junction/tandem photovoltaic cell. For example, the doped precursor 400 can be utilised to fabricate photovoltaic cells in accordance with the first, second and/or third aspects to form photovoltaic cells comprising barrier layers and/or protective layers and/or an ultrathin HTL.

### Ninth Illustrated Form

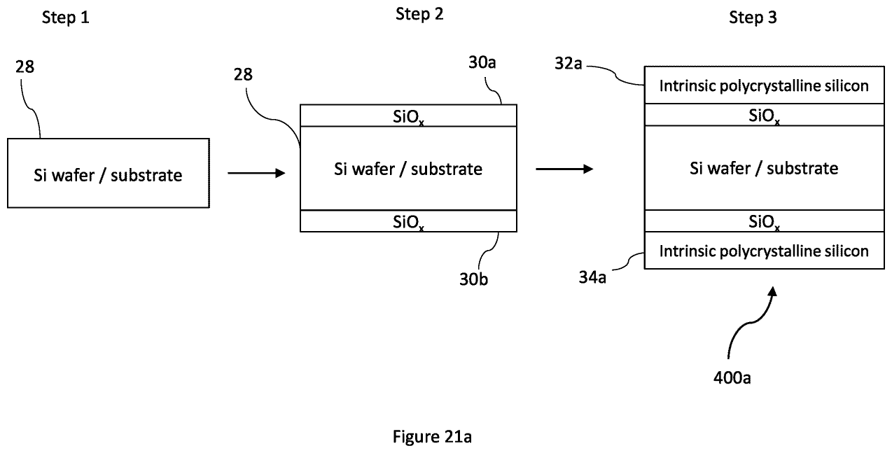

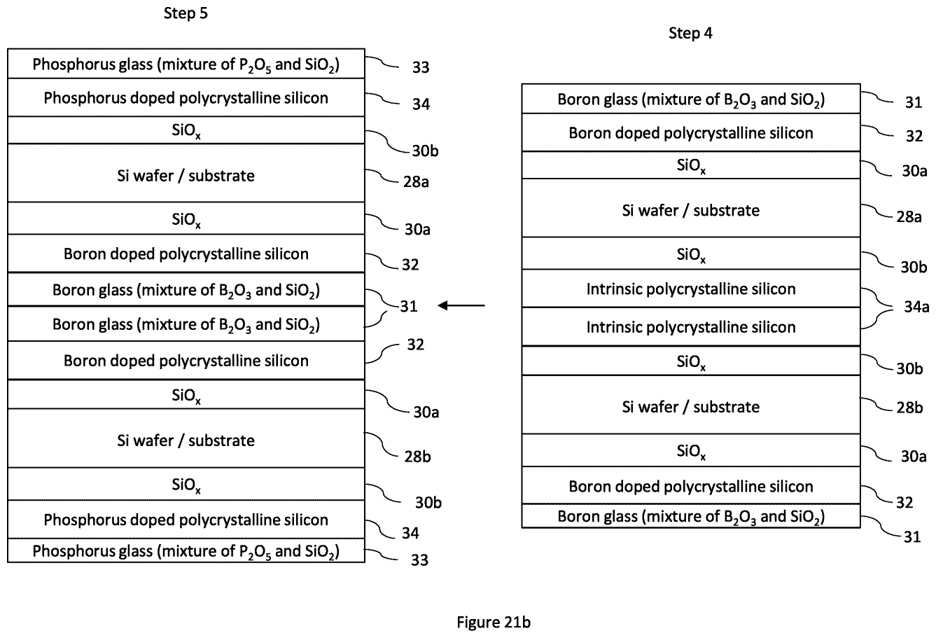

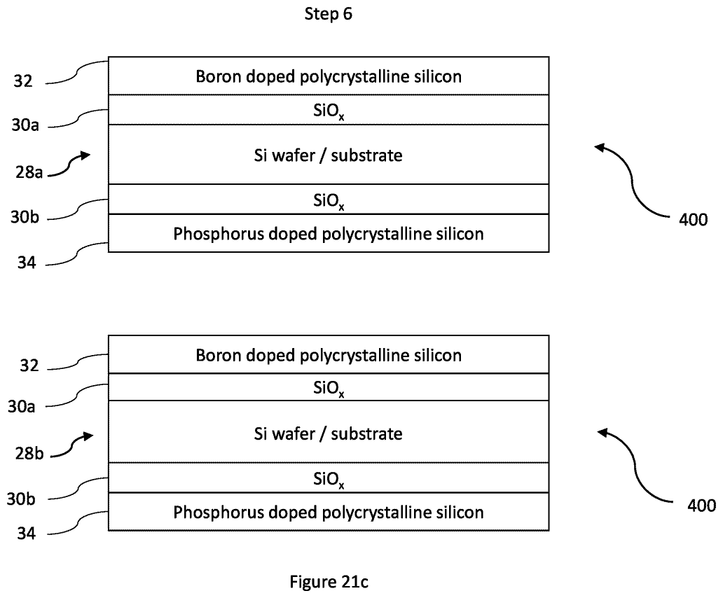

FIGS. 21a, 21b and 21c illustrate the steps for fabricating a doped precursor 400 using thermal diffusion.

Prior to the fabrication of the layers of the precursor, the substrate 28 is subjected to a series of cleaning and masking steps to prepare a defined and clean substrate surface for deposition of the doped layers.

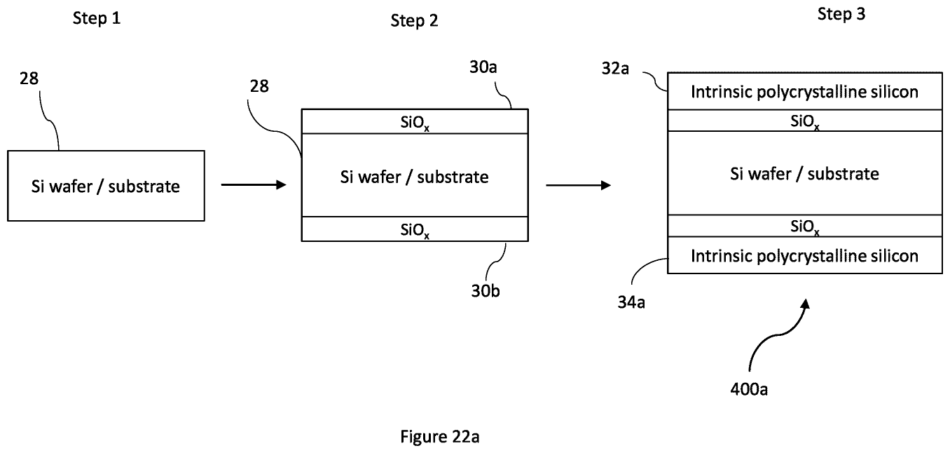

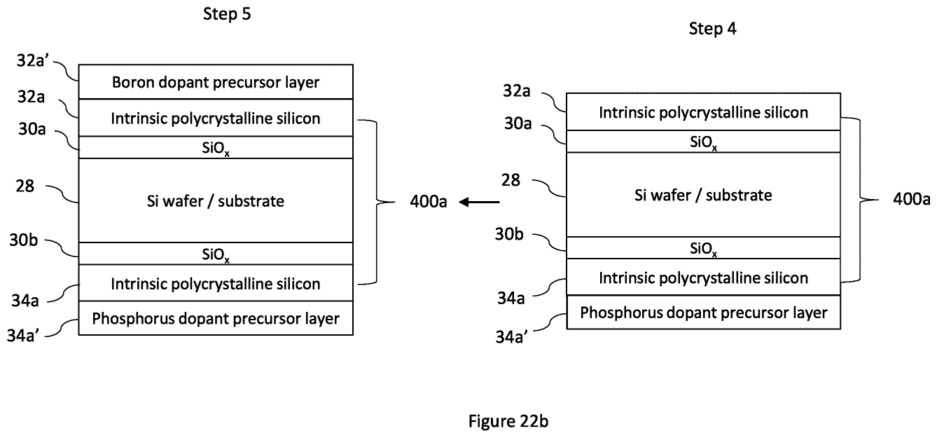

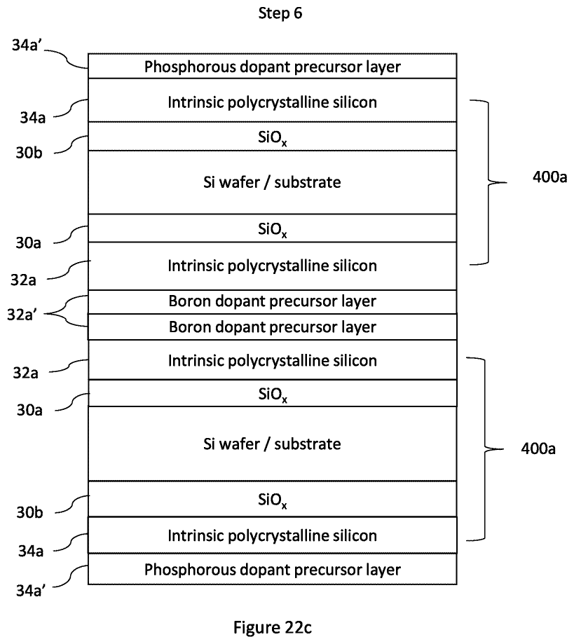

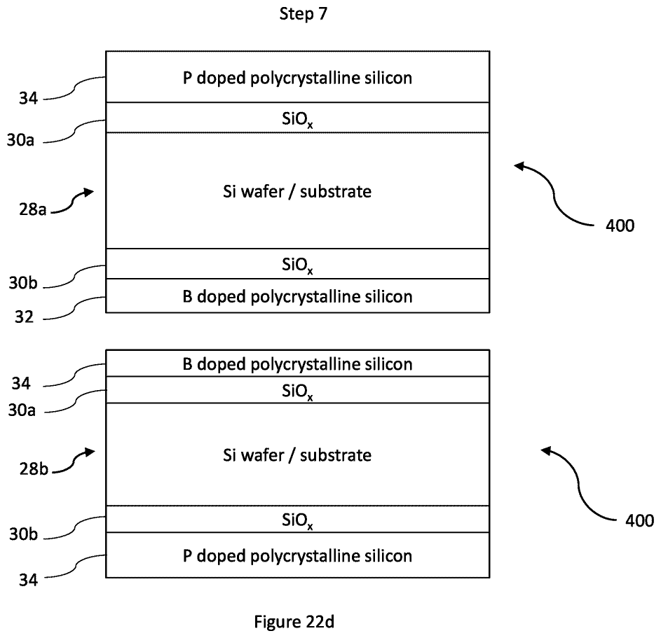

By way of example only, a fabrication method used for smaller area cells in e.g. a laboratory setting will be described with reference to FIGS. 21a, 22b and 22c. The skilled person will appreciate, in view of this description, how to adjust the fabrication method for use in an industrial setting. The crystalline silicon substrate 28 is subjected to an RCA chemical cleaning to eliminate impurities from the surface of the silicon. Subsequently, a masking oxide (not shown) is grown using the technique of wet thermal oxidation. Following the RCA cleaning, the silicon substrate 28 is loaded into a manual furnace at 700° C. and the temperature is ramped up to 1050° C. with 15 minutes of dry oxidation and 15 minutes of wet oxidation. This is followed again by 1 hour of dry oxidation. The substrates were unloaded from the furnace after cooling to 700° C. In wet oxidation water vapor is added to oxygen gas to oxidise the silicon surface, while dry oxidation only uses oxygen gas. Thus, in dry oxidation there is thermal annealing of the sample in a clean oxygen atmosphere, while in wet oxidation there may be thermal annealing of the sample in a clean oxygen atmosphere with the addition of H₂O in the form of steam.

Subsequently, photolithography definition of the front cell area is performed. Photoresist AZ 1518 was spin coated on front surface of the substrate 28 at a speed of 3000 rpm for 30 s. After soft baking at 90° C. for 20 minutes, the substrate 28 was exposed to UV light under a chrome mask for 15 seconds. The photoresist was then developed in AZ 326 for 1 minute to remove exposed photoresist. This was followed by buffered HF treatment of the substrate 28 for 3 minutes to etch underlying masking oxide. Finally, the substrate 28 was washed in an acetone bath to remove the photoresist.

As illustrated in step 1, the substrate 28 is now ready for deposition of passivation layers 30a and 30b and the doped polycrystalline silicon layers 32 and 34.

The prepared substrate 28 is subjected to a further RCA cleaning procedure following which thin oxide passivation layers (30a, 30b) were grown on the surface of the substrate 28 (step 2). These passivation layers (30a, 30b) function to avoid recombination of charge carriers at the surface of the substrate 28. In the illustrated embodiment, a chemical treatment procedure was utilized that allows for better control of the passivation layer thickness. The chemical treatment procedure involves treating the substrate 28 with hot concentrated nitric acid at 90° C. for 30 minutes.

Following this, the substrate 28 is transferred to a low-pressure chemical vapor deposition system (LPCVD) to deposit the initial precursors in the form of intrinsic polycrystalline silicon. The intrinsic polycrystalline silicon is grown on the passivation layers (step 3). The process is performed at a temperature of 530° C. using Silane gas as the precursor. Intrinsic polycrystalline silicon layers 32a and 34a are formed on the passivation layers 30a and 30b respectively. The intrinsic polycrystalline silicon layers 32a and 34a lack any conductivity and are subjected to a doping via thermal diffusion in later steps. The thickness of the layers formed is about 15 to 150 nm depending on the deposition conditions adopted. In this illustrated embodiment, the substrate 28, passivation layers 30a and 30b, and intrinsic polycrystalline silicon layers 32a and 34a together form the initial precursor 400a that is to be subjected to the doping process.

In the illustrated embodiment, layer 32a is subjected to doping with boron while the layer 34a is subjected to doping with phosphorous. In some other embodiments, the opposite may be performed.

In step 4, two substrates 28a and 28b, each comprising passivation layers 30a, 30b and intrinsic polycrystalline silicon layers 32a and 34a are arranged in a back-to-back configuration such that layers 34a of each precursor face each other. There is very little or no gap (e.g. no visible gap) between the layers 34a. Thus, the surface of the layers 34a are not exposed to the surrounding environment (including the dopant). On the other hand, the surfaces of the layers 32a are fully exposed to the ambient environment. This will allow intimate contact with any dopants in the atmosphere.

In this configuration, boron dopants are introduced into the doping chamber (step 4). In the illustrated embodiment, a boron doping mixture containing BBr₃, N₂ and O₂ gases were employed. The temperature during this process is maintained sufficiently high. In the illustrated embodiment, the temperature of the diffusion step is set at 980° C. for 25 minutes. Similarly, the temperature of the drive-in step was set at 980° C. for 25 minutes. As the surfaces 34a are facing each other, the gas mixture does not come into contact with these surfaces. On the other hand, the surface of the layers 32a are fully exposed to the gas mixture, they are doped with boron. After dopant deposition is completed, the O₂ is switched off to minimize oxidation.

During step 4, a boron glass 31 forms on top of each layer 32a. In step 5, the boron glass layer may act as a masking layer to protect the surface of the layers 32 from being contaminated during the second doping process.

Once step 4 is completed, the orientation of the substrates 28 is changed such that the surfaces of the doped layers 32 are now facing each other (step 5). Thus, the surfaces of the layers 34a which were earlier facing each other are now exposed to the ambient environment. Subsequently, phosphorous dopant mixture is introduced into the chamber. The phosphorous doping mixture containing POCl₃, N₂ and O₂ contacts the exposed surface of the layers 34a leading to a deposition of the phosphorous containing dopant. A temperature of 820° C. for 25 mins may be employed for the diffusion step while a temperature of 900° C. for 25 minutes may be employed for the thermal drive in step. The boron doped layers 32 are not contaminated by the phosphorous containing dopants. In this manner, the intrinsic polycrystalline silicon layers 34a are doped with phosphorous. Once doping is completed, the O₂ gas is switched off to minimize oxidation.

As shown in FIG. 21, at the conclusion of step 5, a phosphorus glass layer 33 has been deposited on layers 34.

It should be noted that the circumferential edges of the substrates 28 that are not facing each other either during phosphorous or boron doping will be contaminated with both phosphorous and boron. Accordingly, an etching procedure may be utilized to remove these contaminated portions from the substrate 28.

In some embodiments, the first and second polycrystalline layers 32a and 34a may be subjected to annealing prior to doping. In the illustrated embodiment, this annealing can be performed in an inert atmosphere of nitrogen at a temperature of 1000° C. for 60 minutes.

Following the completion of the diffusion and drive-in steps, the precursors 400a are subjected to annealing at a temperature of 425° C. for 30 minutes under forming gas (95% N₂₊₅% H₂). This annealing subjects the interfacial SiO₂ (i.e. the passivation layers 30a, 30b) to a hydrogen passivation step. In some other embodiments, alternative hydrogen passivation steps may be performed (e.g. using one or more hydrogen-containing dielectric layers).

Finally, the substrates can be subjected to an etching procedure with 1% HF solution for 5 minutes in order to chemically remove the boron and phosphorus glass layers 31, 33 from the doped polycrystalline silicon layers 32, 34. The resulting doped precursor 400 can then be utilised in the fabrication of a photovoltaic cell.

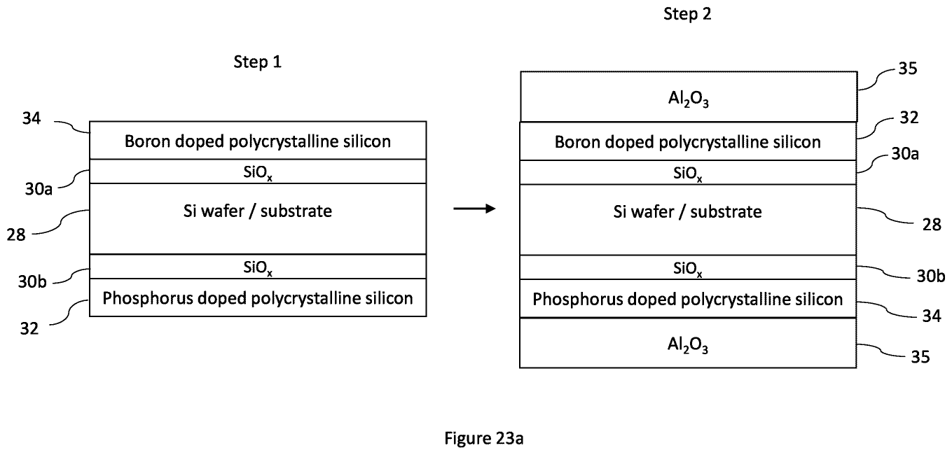

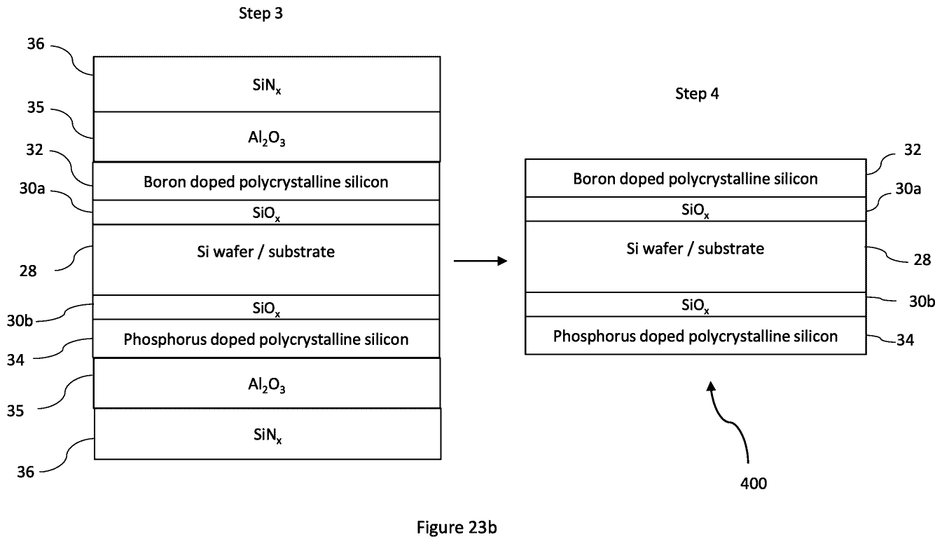

Alternatively, the precursor 400 may be subjected to a hydrogen passivation treatment as shown in FIGS. 23a and 23b and described further below.

### Tenth Illustrated Form

FIGS. 22a, 22b, 22c and 22d illustrate the steps for fabricating a doped precursor 400 using by contacting the initial precursor 400a with a liquid dopant source. Contact with the dopant source may be achieved using spin-on coating and/or spray-on coating. For convenience, in the method described below, reference may be made to contacting the precursor with the liquid dopant source using spin-on coating. However, it would be appreciated that the method may be applied to other forms of contacting, in particular spray-on coating.

As shown in FIG. 22a, the cleaned silicon substrate is subjected to deposition of the passivation layers of SiOₓ followed by deposition of an intrinsic polysilicon layer on both sides of the substrate 28 to produce the initial precursor 400a. The deposition method discussed for the illustrated embodiment of thermal diffusion is equally applicable here.

Following this, a liquid precursor containing the phosphorous dopant is deposited by spin coating on the surface of layer 34a at a speed of 2000 rpm for 30 seconds (see step 4). This layer is again subjected to a soft baking at 110° C. for 15 minutes and hard-baking at 200° C. for 8 minutes on hot-plate. This was followed by an intermediate annealing step at 450° C. for 20 minutes in a tube furnace. The series of annealing steps leads to the formation of a phosphorous dopant precursor layer 34a′ on the surface of the layer 34a.

Next, in step 5, the liquid precursor containing a boron dopant is deposited on the intrinsic polysilicon layer 32a. The boron-containing liquid precursor is spin-coated on surface of layer 32a at 2000 rpm for 30 seconds. The layer was then subjected to soft-baking at 110° C. for 15 minutes and hard-baking at 200° C. for 8 minutes on hot-plate. The annealing is performed in an oxygen-containing atmosphere (e.g. air). The annealing process forms the boron dopant precursor layer 32a′. The silicon substrate 28 now has dopant precursor layers 32a′ and 34a′ deposited respectively on the layers 32 and 34.

Once the precursor layers are formed, two precursors (each of which have the first and second dopant precursor layers 32a′ and 34a′) are now arranged such that the layers 32a′ of the substrates face each other as shown in Step 6 of FIG. 22c.

In this configuration, the substrates 28 are subjected to an activation anneal at 970° C. for 1 hour under ambient N₂ to drive the dopants from the layers 32a′ and 34a′ into the layers 32a and 34a respectively to form the doped layers 32 and 34 (shown in step 7 of FIG. 22d).

The precursors may then be subjected to an annealing at 425° C. for 30 minutes under forming gas atmosphere (95% N₂₊₅% H₂).

Finally, in step 7, the substrates can be subjected to an etching procedure with 1% HF solution for 5 minutes in order to chemically remove the boron and phosphorus dopant precursor layers 32a′, 34a′ from the doped polycrystalline silicon layers 32, 34. The resulting doped precursor 400 can then be utilised in the fabrication of a photovoltaic cell.

Alternatively, the precursor 400 may be subjected to a hydrogen passivation process as shown in FIGS. 23a and 23b and described further below.

### Eleventh Illustrated Form

FIGS. 23a and 23b illustrate a hydrogen passivation process. The illustrated process may be used for embodiments of the invention in accordance with the fourth and/or fifth aspects.

The hydrogen passivation process is performed on the doped precursor 400 (see step 1). In this embodiment, a first hydrogen-containing dielectric layer 35 and a second hydrogen-containing dielectric layer 36 are deposited on each doped polycrystalline silicon layers 32, 34.

In step 2, the first hydrogen-containing dielectric layer 35 is depositing on each doped polycrystalline silicon layer 32, 34. The first hydrogen-containing dielectric layer comprise Al₂O₃. For this embodiment, ALD is used to deposit the first hydrogen-containing dielectric layer comprising Al₂O₃ of 20 nm at 200° C. In some embodiments, the Al₂O₃ layer thickness is from about 5 to 25 nm. In some embodiments, PECVD is used instead of ALD.

In step 3, the second first hydrogen-containing dielectric layer 36 is deposited on each first hydrogen-containing dielectric layer 35. The second hydrogen-containing dielectric layer comprises SiNₓ. For this embodiment, PECVD is used to deposit the second hydrogen-containing dielectric layer comprising SiNₓ of 70 nm at 400° C. In some embodiments, the PECVD temperature used for SiNₓ deposition may be from about 300° C. to about 600° C.

After deposition, the hydrogen-containing dielectric layers 35, 36 are subjected to a thermal annealing or firing step that results in hydrogenation of the underlying layers 32, 34. For example, the hydrogen-containing dielectric layers 35, 36 may be subjected to annealing at a temperature of 425° C. for 30 minutes under forming gas (95% N₂+5% H₂).

Following the hydrogenation treatment, the dielectric layers may be removed by subjecting the layers to etching in HF (see step 4). The precursor 400 is now ready for fabrication of the photovoltaic cell.

### EXAMPLES

### Example 1—Single Junction Cell with Ultrathin Hole Transport Layer, Protective Layer, and Barrier Layer

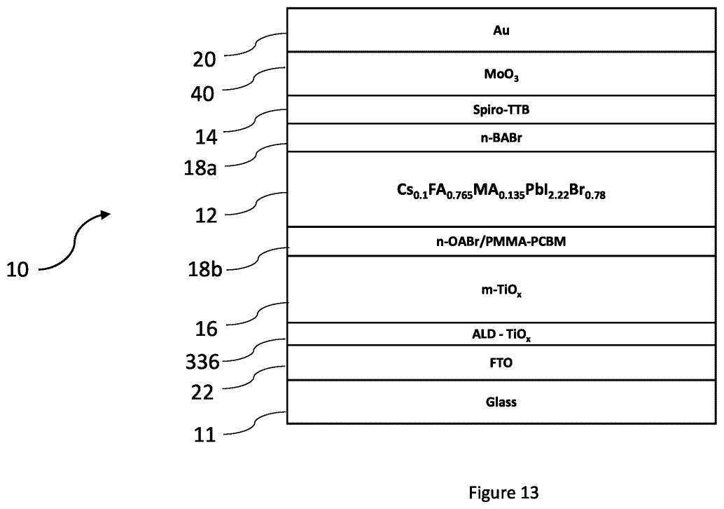

Single junction solar cells in accordance with the schematic shown in FIG. 13 can be prepared according to the example.

### Substrate and Bottom Electrode

A Fluorine-doped Tin Oxide (FTO)/glass substrate was provided. The substrate was cleaned sequentially with detergent, acetone, isopropanol, ethyl alcohol and deionized (DI) water. Each sequence was performed for 10 minutes in an ultrasonic bath. The substrate was then UV-ozone treated for 15 minutes.

### Compact ALD-TiO₂ Layer, 336

The cleaned substrate was transferred to a thermal ALD system for depositing a compact TiO₂ layer. A TiCl₄ precursor and N₂ purge gas were utilized for the process. The reactor temperature was set at 200° C. and H₂O was used as the oxidant. The chamber N₂ flow was set at 200 standard cubic centimeters per minute (sccm). Each ALD cycle consisted of a 0.75 s pulse of TiCl₄ followed by a 0.050 s pulse of H₂O. Between each precursor pulse, a 0.75 s purge under a constant flow (300 sccm) of research-grade N₂(g) was used.

The compact TiO₂ can block the direct contact of perovskite and substrate to prevent current loss, because mesoporous TiO₂ is not compact.

### Electron Transport Layer, 16

Next, an electron transport layer of mesoporous TiO₂ was deposited on top of the compact TiO₂ layer. The precursor employed was a diluted TiO₂ paste solution (TiO₂ paste (30NRD): Ethanol=1:12). The deposition was performed by spinning the precursor at 5000 rpm for 15 s. Subsequently, annealing was performed at 400° C. for 25 minutes.

### Passivation Layer, 18b

Passivation layers comprising a combination of PMMA-PCBM and n-OABr were deposited on top of the mesoporous TiO₂ layer. A PMMA-PCBM blend solution was used as a precursor. This solution was prepared by dissolving 1 mg PMMA (Mw˜120000, Sigma Aldrich) and 3 mg PC61BM (Sigma Aldrich) into 1 mL Chlorobenzene. The solution was spin coated at 4000 rpm for 30 seconds.

The n-OABr layer was deposited on the PMMA-PCBM layer. A solution of n-OABr (2 mg/ml in Isopropanol) was spin-coated at 5000 rpm for 15 s. This was followed by an annealing step at 100° C. for 10 minutes.

### Absorber Layer, 12

The substrate containing the passivation layers and the electron transport layer is now ready for deposition of the absorber layer. As discussed earlier, the absorber comprises a perovskite material. In this instance, the perovskite material had a stoichiometry of Cs_{0.1}FA_{0.765}MA_{0.135}PbI_{2.22}Br_{0.78}. This was prepared from a precursor solution containing 0.96 M PbI₂, 0.99 M FAI, 0.16 M PbBr₂, 0.18 M MABr, and 0.13 M CsI in 1 ml of anhydrous N,N′-dimethylformamide (DMF)/dimethyl sulfoxide (DMSO) (8:2, v/v). The multiple-cation precursor solution was deposited by spin coating at 1000 rpm with a ramp rate of 100 rpm s⁻¹ for 10 s and then at 4000 rpm with a ramp of 1000 rpm s⁻¹ for 25 s. Subsequently, ˜100 μl of chlorobenzene was poured on the spinning substrates 5 s before the end of the program. The resulting film was then heated on hot plate for 100° C. for 30 mins.

### Passivation Layer, 18a

A passivation layer comprising n-BABr was deposited on top of the absorber layer. A precursor solution of n-BABr (2 mg/ml in Isopropanol) was spin coated at 5000 rpm for 15 s. Following this, annealing was performed at 100° C. for 10 minutes.

### Protective Layer, 24

The protective layer comprises poly-TPD. A precursor solution of poly-TPD (0.5 mg/mL in chlorobenzene) was spin coated at 5000 rpm for 15 s on top of the n-BABr layer. Following this, annealing was performed at 100° C. for 10 minutes.

### Ultrathin Hole Transport Layer, 14

The ultrathin hole transport layer was deposited on top of the protective layer. The ultrathin hole-transport layer in this example comprises 2,2′,7,7′-Tetra(N,N-di-p-tolyl)amino-9,9-spirobifluorene (Spiro-TTB). A 5 nm layer of Spiro-TTB was deposited using thermal evaporation.

### Buffer Layer, 40

Following this, a buffer layer of MoO₃ was deposited by thermal evaporation at a rate of 0.05 nm/s. Both the deposition steps of the Spiro-TTB (see above) and the MoO₃ were performed under a high vacuum of 8×10⁻⁷ Torr.

### Electrode, 20

Finally, the top electrode layer was deposited on the MoO₃ layer to complete the device. The top electrode layer was fabricated from gold. Thermal evaporation technique was used to deposit 100 nm thick full-area Au contacts on top of the MoO₃ layer. Shadow masks were employed to protect areas.

### Example 2—Tandem Cell with Ultrathin Hole Transport Layer, Protective Layer and Barrier Layer

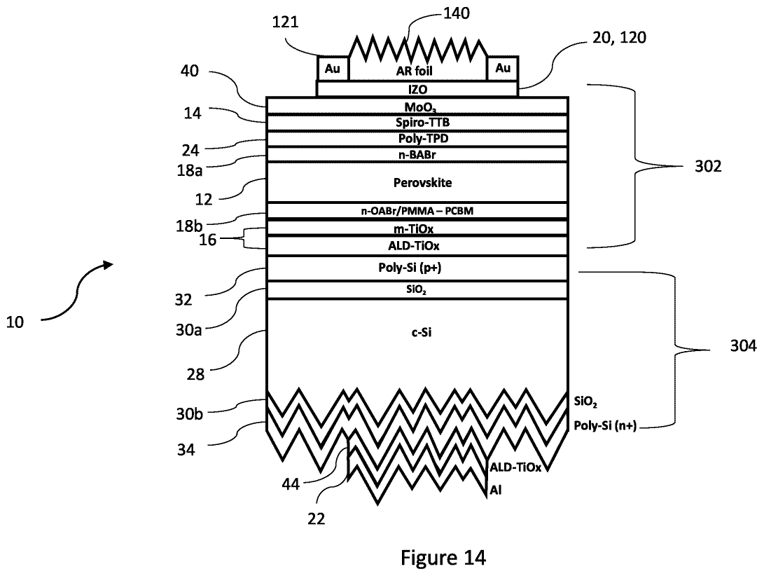

Tandem solar cells in accordance with the schematic shown in FIG. 14 can be prepared according to the following example.

### Silicon Sub-Cell, 304

The silicon sub-cell was prepared using high quality silicon wafers with polished front surface and textured rear surface, having a thickness of 270 m and a resistivity of 1-5 ohmcm. The silicon wafers received RCA cleaning before further processing (RCA1=10 minutes, 80° C. dip in 5:1:1 NH₄OH:H₂O₂:H₂O; 1% wt HF dip for 1 min; RCA2=10 minutes, 80° C. dip in 5:1:1 HCl:H₂O₂:H2O; 1% wt HF dip for 1 min.). After each step, the wafers were dipped in deionized water for thorough cleaning before the next step. The cleaned wafers are dried with nitrogen gas.

The cleaned silicon wafers were then covered by means of a masking oxide. The wafers were loaded into a manual furnace at 700° C., ramped up to 1050° C., with 15 minutes dry oxidation, 15 minutes wet oxidation, followed by 1 hour dry oxidation. Samples were unloaded after cooling down to 700° C. In wet oxidation water vapor is added to oxygen gas to oxidise the silicon surface, while dry oxidation only uses oxygen gas. Thus, in dry oxidation there is thermal annealing of the sample in a clean oxygen atmosphere, while in wet oxidation there may be thermal annealing of the sample in a clean oxygen atmosphere with the addition of H₂O in the form of steam

Next the front cell area was defined by photolithography. To accomplish this, a photoresist AZ 1518 was coated by spin coating on the front surface of the passivated wafer at 3000 rpm for 30 s. After soft baking at 90° C. for 20 minutes, the wafers were exposed to UV light under a chrome mask for 15 seconds. Photoresist was then developed in AZ 326 for 1 minute to remove exposed photoresist. This was followed by buffered HF treatment for 3 minutes to etch the underlying masking oxide. Finally, an acetone bath was used to remove the remaining photoresist.

A thin chemical oxide was grown by treating the wafers with hot concentrated nitric acid at 90° C. for 30 minutes, thus forming the passivation layers 30a, 30b.

Intrinsic polycrystalline silicon layers were deposited on both sides of the cleaned and passivated silicon wafer. Low Pressure Chemical Vapor Deposition (LPCVD) was used to grow intrinsic polycrystalline silicon at 530° C. using Silane as a reactant gas. The deposition time can be selected to achieve the desired thickness.

The intrinsic polycrystalline silicon layers were annealed at 1000° C. for 1 hour in an N₂ atmosphere.

Next, the wafers were arranged in a back-to-back configuration such that the rear sides of two wafers were facing each other. In this configuration, boron doping was performed on the front side. The reactant gas employed was BBr₃, N₂ and O₂. The oxidation is minimized by switching off O₂ gas after deposition.

The boron thermal diffusion is conducted with a 25 mins deposition step at 980° C., followed by a drive-in step at 980° C.

Subsequently, the wafers are arranged such that the B-doped front sides are now facing each other in a back-to-back configuration leaving the rear sides exposed to the ambient environment of the deposition chamber. In this configuration, phosphorous doping is performed on the rear side. The reactant gas employed is POCl₃, N₂, and O₂. Oxidation is minimised by switching off O₂ gas after dopant deposition.

The phosphorus thermal diffusion is conducted with a 25 mins deposition step at 820° C., followed by a drive-in step at 900° C.

After doping the phosphorous and boron into the respective polycrystalline silicon layers, the wafers were subjected to a forming gas anneal at 425° C. for 30 minutes.

Finally, the wafers are subjected to etching with a 1% HF solution to remove the boron and phosphorous glasses formed during thermal diffusion.

This fabricates the doped polycrystalline silicon CSLs 32 (p-type doped) and 34 (n-type doped).

### Barrier Layer, 44

The bottom (second) sub-cell is transferred to a thermal ALD system for depositing an ALD-TiO₂ barrier layer. The precursors used in the ALD process are titanium isopropoxide (TTIP) and water. The deposition temperature is at a range of from 90° C. to 230° C. The ALD process normally is as follows:
precursors and chamber are heated up to the required temperature (since it is thermal ALD, the reaction of the precursors is done thermally);
TTIP is pulsed until full coverage of the substrate surface;
the chamber is cleaned with a long step of N₂ to get rid of the leftover TTIP molecules;
water is pulsed and the reaction happens between TTIP and water at the surface of the sample; and
the chamber is cleaned again with a long N₂ purge step to get rid of leftover water;
the steps are repeated until the desired barrier layer has been deposited.

### Bottom Electrode, 22

The Al bottom electrode was deposited using thermal evaporation.

### Electron Transport Layer, 16

### First Sub-Layer

The bottom (second) sub-cell was transferred to a thermal ALD system for depositing a compact TiO₂ layer as a first sub-layer of the ETL 16. A TiCl₄ precursor and N₂ purge gas were utilized for the process. The reactor temperature was set at 200° C. and H₂O was used as the oxidant. The chamber N₂ flow was set at 200 standard cubic centimeters per minute (sccm). Each ALD cycle consisted of a 0.75 s pulse of TiCl₄ followed by a 0.050 s pulse of H₂O. Between each precursor pulse, a 0.75 s purge under a constant flow (300 sccm) of research-grade N₂(g) was used.

### Second Sub-Layer

Next, an electron transport layer of mesoporous TiO₂ was deposited on top of the compact TiO₂ layer. The precursor employed was a diluted TiO₂ paste solution (TiO₂ paste (30NRD): Ethanol=1:12). The deposition was performed by spinning the precursor at 5000 rpm for 15 s. Subsequently, annealing was performed at 400° C. for 25 minutes.

### Passivation Layer, 18b

Passivation layers comprising a combination of PMMA-PCBM and n-OABr were deposited on top of the mesoporous TiO₂ layer. A PMMA-PCBM blend solution was used as a precursor. This solution was prepared by dissolving 1 mg PMMA (Mw˜120000, Sigma Aldrich) and 3 mg PC61BM (Sigma Aldrich) into 1 mL Chlorobenzene. The solution was spin coated at 4000 rpm for 30 seconds.

The n-OABr layer was deposited on the PMMA-PCBM layer. A solution of n-OABr (2 mg/ml in Isopropanol) was spin-coated at 5000 rpm for 15 s. This was followed by an annealing step at 100° C. for 10 minutes.

### Absorber Layer, 12

The substrate containing the passivation layers and the electron transport layer is now ready for deposition of the absorber layer. As discussed earlier, the absorber comprises a perovskite material. In this instance, the perovskite material had a stoichiometry of Cs_{0.1}FA_{0.765}MA_{0.135}PbI_{2.22}Br_{0.78}. This was prepared from a precursor solution containing 0.96 M PbI₂, 0.99 M FAI, 0.16 M PbBr₂, 0.18 M MABr, and 0.13 M CsI in 1 ml of anhydrous N,N′-dimethylformamide (DMF)/dimethyl sulfoxide (DMSO) (8:2, v/v). The multiple-cation precursor solution was deposited by spin coating at 1000 rpm with a ramp rate of 100 rpm s⁻¹ for 10 s and then at 4000 rpm with a ramp of 1000 rpm s⁻¹ for 25 s. Subsequently, ˜100 μl of chlorobenzene was poured on the spinning substrates 5 s before the end of the program. The resulting film was then heated on hot plate for 100° C. for 30 mins.

Passivation Layer, 18a A passivation layer comprising n-BABr was deposited on top of the absorber layer.

A precursor solution of n-BABr (2 mg/ml in Isopropanol) was spin coated at 5000 rpm for 15 s. Following this, annealing was performed at 100° C. for 10 minutes.

### Protective Layer, 24

The protective layer comprises poly-TPD. A precursor solution of poly-TPD (0.5 mg/mL in chlorobenzene) was spin coated at 5000 rpm for 15 s on top of the n-BABr layer. Subsequently, annealing was performed at 100° C. for 10 minutes.

### Ultrathin Hole Transport Layer, 14

The ultrathin hole transport layer was deposited on top of the protective layer. The ultrathin hole-transport layer in this example comprises 2,2′,7,7′-Tetra(N,N-di-p-tolyl)amino-9,9-spirobifluorene (Spiro-TTB). A 5 nm layer of Spiro-TTB was deposited using thermal evaporation.

### Buffer Layer, 40

Following this, a buffer layer of MoO₃ was deposited by thermal evaporation at a rate of 0.05 nm/s. Both the deposition steps of the Spiro-TTB (see above) and the MoO₃ were performed under a high vacuum of 8×10⁻⁷ Torr.

### Top Electrode Layer, 20

Finally, the top electrode layer was deposited on the MoO₃ layer to complete the device. The front transparent contact 120 was fabricated by sputtering ˜40-nm indium zinc oxide (IZO) on the MoO₃. The sputtering was performed for 60 min with 30 W of RF power under an Ar plasma, with a chamber pressure of 1.5 mTorr.

To complete the device, Au fingers and busbars 121 were deposited on the sample using thermal evaporation through a shadow mask.

A silicone texture foil (anti-reflection layer) 140 is mechanically attached to the surface of the tandem solar cell to enhance light trapping.

### Example 3—Use of the Protective Layer

Samples with and without a protective layer were prepared as follows.

Device Fabrication (with a Protective Layer):

1. FTO/glass substrates were sequentially cleaned with detergent, acetone, isopropanol, ethyl alcohol, and deionized (DI) water for a duration of 10 minutes for each step using an ultrasonic bath. The substrates were then UV-ozone treated for 15 minutes.

2. Subsequently, a ˜70 nm layer of cp-TiO₂ and a ˜80 nm layer of mp-TiO₂ were deposited on the pre-cleaned substrates sequentially according to the processes described in Peng, J.; Khan, J. I.; Liu, W.; Ugur, E.; Duong, T.; Wu, Y.; Shen, H.; Wang, K.; Dang, H.; Aydin, E.; Yang, X.; Wan, Y.; Weber, K. J.; Catchpole, K. R.; Laquai, F.; De Wolf, S.; White, T. P., A Universal Double-Side Passivation for High Open-Circuit Voltage in Perovskite Solar Cells: Role of Carbonyl Groups in Poly(methyl methacrylate). Advanced Energy Materials 2018, 8 (30), 1801208. A thin PMMA:PCBM passivation layer was deposited on the substrate at a spin rate of 4000 rpm for 15 s with a ramp rate of 4000 rpm/s. Details regarding the preparation of PMMA:PCBM passivation solution can be found in Peng, J.; Wu, Y.; Ye, W.; Jacobs, D. A.; Shen, H.; Fu, X.; Wan, Y.; Duong, T.; Wu, N.; Barugkin, C.; Nguyen, H. T.; Zhong, D.; Li, J.; Lu, T.; Liu, Y.; Lockrey, M. N.; Weber, K. J.; Catchpole, K. R.; White, T. P., Interface passivation using ultrathin polymer-fullerene films for high-efficiency perovskite solar cells with negligible hysteresis. Energy & Environmental Science 2017, 10 (8), 1792-1800.

3. Then, n-OACl passivation was applied, by spin-coating the n-OACl precursor (2 mg/mL in IPA) at a spin rate of 5000 rpm for 15 s with a ramp rate of 5000 rpm/s. This was followed by 10 minutes of annealing on a hotplate at 100° C.

4. Cs_{0.1}FA_{0.765}MA_{0.135}PbI_{2.22}Br_{0.78} contained 0.96 M PbI₂, 0.99 M FAI, 0.16 M PbBr₂, 0.18 M MABr, and 0.13 M CsI in 1 ml of anhydrous N,N′-dimethylformamide (DMF)/dimethyl sulfoxide (DMSO) (8:2, v/v). The multiple-cation perovskite precursor solution was deposited by spin coating at 1000 rpm with a ramp rate of 100 rpm s⁻¹ for 10 s and then at 4000 rpm with a ramp of 1000 rpm s⁻¹ for 25 s. During the second step, ˜150 μl of chlorobenzene was poured on the spinning substrates 5 s before the end of the program. The film was then heated on hot plate for 100° C. for 30 mins.

5. Then passivation layers were based n-BABr solution applied (2 mg/mL in Isopropanol). A layer of n-BABr was deposited on the perovskite layer by spinning the solution at 5000 rpm for 15 s, followed by another annealing step at 100° C. for 10 minutes.

6. Depositing a poly-TPD protective layer was performed by dissolving 0.5 mg Poly-TPD powder in 1 mL Chlorobenzene solution to make the precursor (0.5 mg/mL). Spin-coating the precursor by using the “Laurell Spinner” in the “Vigor glove box” at 5000 rpm for 15 s to deposit the film. This was followed by annealing at 100° C. for 10 minutes.

7. Depositing a 5 nm of Spiro-TTB layer was performed using the “KJ Lesker Cosmo Thermal Evaporation System (TES)” in the “Vigor glove box” to evaporate a 5-10 nm film with a rate of 0.1 Å/s. The thickness and depositing rate of the layer was monitored by a crystal sensor in the evaporation system.

8. Depositing a 5 nm of MoO₃ layer was performed using the “Angstrom Evaporation system” in the “Vigor glove box” to evaporate a 5-10 nm film with a rate of 0.1 Å/s. The thickness and depositing rate of the layer was monitored by a crystal sensor in the evaporation system.

9. The device was completed by depositing Au electrode: Using the “KJ Lesker Cosmo Thermal Evaporation System (TES)” in the “Vigor glove box” to evaporate a 100 nm film with a rate of 1 Å/s.

Device Fabrication (without a Protective Layer):

The same methodology as outlined above, except step 6 was omitted.

### J-V Measurements:

J-V measurements for the sample devices with and without protective layers were conducted using a solar simulator system (Weblab Inc.) under 1 sun condition (AM 1.5 G, 1000 W/m², 25° C.). A certified Fraunhofer CalLab reference cell was used to calibrate the light intensity prior to the J-V measurements. No preconditioning protocol was applied before the cell measurement. The cells were tested in a custom-built measurement jig under a flow of N₂ gas. For the forward and reverse scans, the voltage range was maintained at −0.1 V→1.25 V, and 1.25 V→0.1 V, respectively. Unless otherwise stated, all the measurements were done at a scan rate of 50 mV/s with a voltage step of 0.01 V.

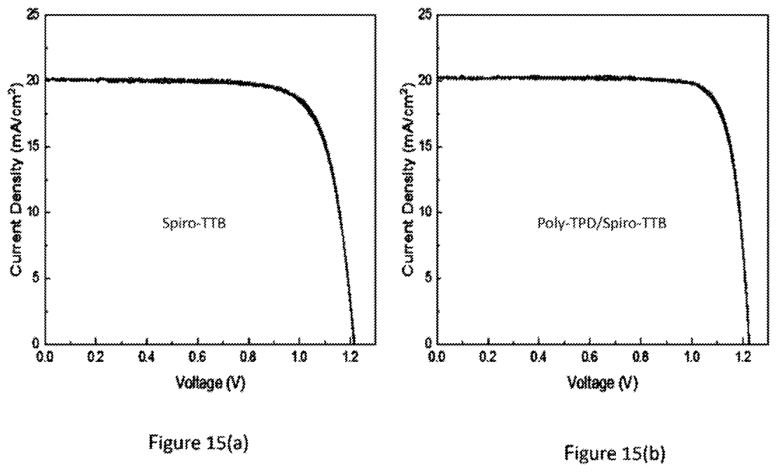

The J-V measurements are shown in FIG. 15(a) and Table 1 (without a protective layer) and FIG. 15(b) and Table 2 (with a protective layer).

TABLE 1
without a protective layer (see FIG. 15(a) also)

| | V_{oc} | J_{sc} | | PCE | Hysteresis |
|---|---|---|---|---|---|
| Device | (V) | (mA/cm²) | FF | (%) | (%) |
| Forward Scan | 1.22 | 20.02 | 0.76 | 18.51 | 1.6 |
| Reverse Scan | 1.22 | 20.16 | 0.77 | 18.82 | |

TABLE 2
with a protective layer (see FIG. 15(b) also)

| | V_{oc} | J_{sc} | | PCE | Hysteresis |
|---|---|---|---|---|---|
| Device | (V) | (mA/cm²) | FF | (%) | (%) |
| Forward Scan | 1.23 | 20.22 | 0.82 | 20.23 | 1.1 |
| Reverse Scan | 1.23 | 20.27 | 0.82 | 20.47 | |

These results indicate that adding a Poly-TPD protective layer to the device can significantly improve the device's performance.

### Example 4—Molecular Weight of the Protective Layer

Sample devices with poly-TPD layers were prepared in accordance with the fabrication method set out in Example 3. However, in Step 6, when making Poly-TPD precursors, different poly-TPD powders were used for each sample:
1. a first sample was prepared using poly-TPD with a weight average molecular weight of 6 kDa; and
2. a second sample was prepared using poly-TPD with a weight average molecular weight of 200 kDa.

### J-V Measurements:

J-V measurements for the sample devices were conducted using a solar simulator system (Weblab Inc.) under 1 sun condition (AM 1.5 G, 1000 W/m², 25° C.). A certified Fraunhofer CalLab reference cell was used to calibrate the light intensity prior to the J-V measurements. No preconditioning protocol was applied before the cell measurement. The cells were tested in a custom-built measurement jig under a flow of N₂ gas. For the forward and reverse scans, the voltage range was maintained at −0.1 V→1.25 V, and 1.25 V→0.1 V, respectively. Unless otherwise stated, all the measurements were done at a scan rate of 50 mV/s with a voltage step of 0.01 V.

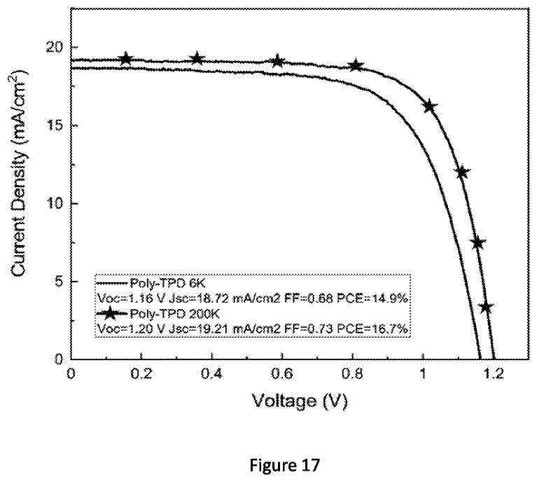

The J-V measurements are shown in FIG. 17, with the red line for the first sample and the blue line for the second sample. These results indicate the Poly-TPD with higher molecular weight is preferred for be use in the protective layer in device, since it can result in better device performance.

### Example 5—the Passivation Layer

Sample devices were prepared in accordance with the fabrication method set out in Example 3, except:
1. a first sample was prepared without the poly-TPD protective layer (Step 6 omitted) and without n-BABr passivation (Step 5 omitted); and
2. a second sample was prepared was prepared without the poly-TPD protective layer (Step 6 omitted) but including n-BABr passivation (Step 5 performed).

### J-V Measurements:

J-V measurements for the sample devices were conducted using a solar simulator system (Weblab Inc.) under 1 sun condition (AM 1.5 G, 1000 W/m2, 25° C.). A certified Fraunhofer CalLab reference cell was used to calibrate the light intensity prior to the J-V measurements. No preconditioning protocol was applied before the cell measurement. The cells were tested in a custom-built measurement jig under a flow of N₂ gas. For the forward and reverse scans, the voltage range was maintained at −0.1 V→1.25 V, and 1.25 V→−0.1 V, respectively. Unless otherwise stated, all the measurements were done at a scan rate of 50 mV/s with a voltage step of 0.01 V.

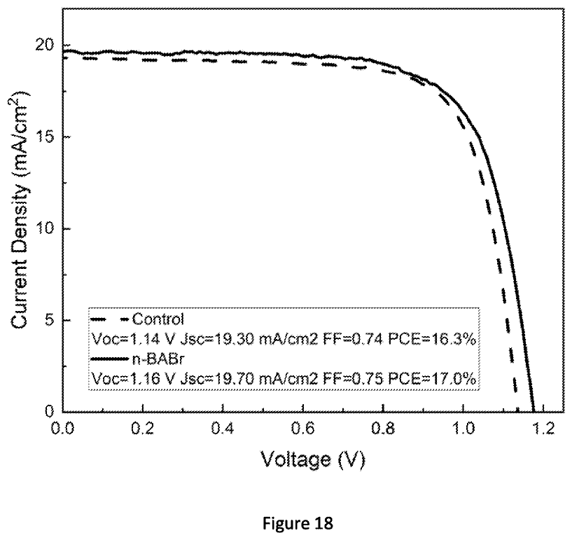

The J-V measurements are shown in FIG. 18, with the red line for the first sample and the yellow line for the second sample. These results indicate that the adding a n-BABr passivation layer can improve the device performance.

### Example 6—Tandem Cell with Protective Layer

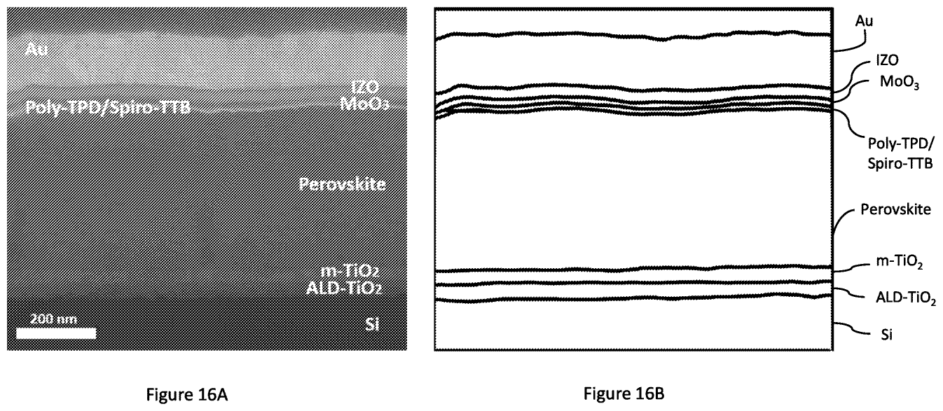

FIG. 16 shows an exemplary embodiment of a tandem cell in accordance with the first and second aspects of the invention. The device was fabricated as follows:

### 1. Compact TiO₂ Layer on Silicon Bottom Cells

A thermal ALD system is used for depositing TiO₂ films using the TiCl₄ precursor, with N₂(g) as the purge gas. For the TiCl₄ precursor, the reactor temperature was set to be 200° C., and H₂O was used as the oxidant. The chamber N₂(g)flow was set to be 200 standard cubic centimetres per minute (sccm). Each ALD cycle consisted of a 0.75-s pulse of TiCl4followed by a 0.050-s pulse of H₂O. Between each precursor pulse, a 0.75-s purge under a constant flow (300 sccm) of research-grade N₂(g) was used.

### 2. Mesoporous TiO₂ Layer

The electron transporting layer was based on diluted TiO₂ paste solution (TiO₂ paste (30NRD): Ethanol=1:12). A layer of mesoporous TiO₂ (100 nm) was deposited on the Si cell by spinning a solution of TiO₂ paste (30NRD) at 5000 rpm for 15 s, followed by another annealing step at 400° C. for 25 minutes.

### 3. PMMA:PCBM Passivation Layer Deposition

The PMMA:PCBM passivation layer was spin coated at 4000 rpm for 30 s, where the PMMA:PCBM blend solution was prepared by dissolving 1 mg PMMA (Mw˜120000, Sigma Aldrich) and 3 mg PC61BM (Sigma Aldrich) into 1 mL Chlorobenzene.

4. n-OABr Passivation Layer Deposition

The passivation layers were based on n-OABr solution (2 mg/mL in Isopropanol). A layer of n-OABr was deposited on the substrate by spinning the solution at 5000 rpm for 15 s, followed by another annealing step at 100° C. for 10 minutes.

### 5. Perovskite Film Deposition

Cs_{0.1}FA_{0.765}MA_{0.135}PbI_{2.22}Br_{0.78} contained 0.96 M PbI₂, 0.99 M FAI, 0.16 M PbBr₂, 0.18 M MABr, and 0.13 M CsI in 1 ml of anhydrous N,N′-dimethylformamide (DMF)/dimethyl sulfoxide (DMSO) (8:2, v/v). The multiple-cation perovskite precursor solution was deposited by spin coating at 1000 rpm with a ramp rate of 100 rpm s⁻¹ for 10 s and then at 4000 rpm with a ramp of 1000 rpm s⁻¹ for 25 s. During the second step, ˜100 μl of chlorobenzene was poured on the spinning substrates 5 s before the end of the program. The film was then heated on hot plate for 100° C. for 30 mins.

6. n-BABr Passivation Layer Deposition

The passivation layer was based on n-BABr solution (2 mg/mL in Isopropanol). A layer of n-BABr was deposited on the perovskite layer by spinning the solution at 5000 rpm for 15 s, followed by another annealing step at 100° C. for 10 minutes.

### 7. Poly-TPD/Spiro-TTB/MoO₃ Perovskite Hole Transport Layer Stack Deposition

The hole transport layer were based on spin coating a solution of poly-TPD (0.5 mg/mL in chlorobenzene) at 5000 rpm for 15 s, followed by another annealing step at 100° C. for 10 minutes. Then, approximately 5 nm of Spiro-TTB and 5 nm of MoOₓ was deposited on the samples by thermal evaporation at a rate of 0.05 nm s⁻¹ under a high vacuum of 8×10⁻⁷ Torr.

### 8. Tandem Front Contact

The front transparent contact was then fabricated by sputtering ˜40-nm IZO on the MoOₓ. The sputtering was performed for 60 min with 30 W of RF power under an Ar plasma, with a chamber pressure of 1.5 mTorr.

To complete the device, Au fingers and busbars were deposited on the sample using thermal evaporation through a shadow mask.

### Example 7—Absorbance of Exemplary Perovskite Compositions

Samples Using the Exemplary Perovskite Compositions Shown in Table 3 Suitable for use in the absorber layer of at least the first and second aspects of the present invention were prepared according to the following method.

TABLE 3

| Sample | | |
|---|---|---|
| Code | Perovskite Composition | Bandgap |
| PVK1 | Cs_{0.05}Rb_{0.05}FA_{0.765}MA_{0.135}PbI_{2.55}Br_{0.45} | 1.62 eV |
| PVK2 | Cs_{0.1}FA_{0.765}MA_{0.135}PbI_{2.4}Br_{0.6} | 1.65 eV |
| PVK3 | Cs_{0.1}FA_{0.765}MA_{0.135}PbI_{2.22}Br_{0.78} | 1.69 eV |
| PVK4 | Cs_{0.1}FA_{0.765}MA_{0.135}PbIBr | 1.72 eV |

### Sample Fabrication: (Glass/Perovskite)

1. Glass substrates were sequentially cleaned with detergent, acetone, isopropanol, ethyl alcohol, and deionized (DI) water for a duration of 10 minutes for each step using an ultrasonic bath. The substrates were then UV-ozone treated for 15 minutes.

2. The multiple-cation perovskite precursor solution was deposited by spin coating at 1000 rpm with a ramp rate of 100 rpm s⁻¹ for 10 s and then at 4000 rpm with a ramp of 1000 rpm s⁻¹ for 25 s. During the second step, ˜150 μl of chlorobenzene was poured on the spinning substrates 5 s before the end of the program. The film was then heated on the hot plate at 100° C. for 30 mins.

The precursor solutions for each sample were as follows:
A. Cs_{0.05}Rb_{0.05}FA_{0.765}MA_{0.135}PbI_{2.55}Br_{0.45} precursor contained 1.1 M PbI₂, 0.99 M FAI, 0.19 M PbBr₂, 0.18 M MABr, 0.065 M RbI and 0.065 M CsI in 1 ml of anhydrous N,N′-dimethylformamide (DMF)/dimethyl sulfoxide (DMSO) (8:2, v/v).
B. Cs_{0.1}FA_{0.765}MA_{0.135}PbI_{2.4}Br_{0.6} precursor contained 1.04 M PbI₂, 0.99 M FAI, 0.26 M PbBr₂, 0.18 M MABr, 0.13 M CsI in 1 ml of anhydrous N,N′-dimethylformamide (DMF)/dimethyl sulfoxide (DMSO) (8:2, v/v).
C. Cs_{0.1}FA_{0.765}MA_{0.135}PbI_{2.22}Br_{0.78} contained 0.96 M PbI₂, 0.99 M FAI, 0.34 M PbBr₂, 0.18 M MABr, and 0.13 M CsI in 1 ml of anhydrous N,N′-dimethylformamide (DMF)/dimethyl sulfoxide (DMSO) (8:2, v/v).
D. Cs_{0.1}FA_{0.765}MA_{0.135}PbIBr contained 0.87 M PbI₂, 0.99 M FAI, 0.43 M PbBr₂, 0.18 M MABr, and 0.13 M CsI in 1 ml of anhydrous N,N′-dimethylformamide (DMF)/dimethyl sulfoxide (DMSO) (8:2, v/v).

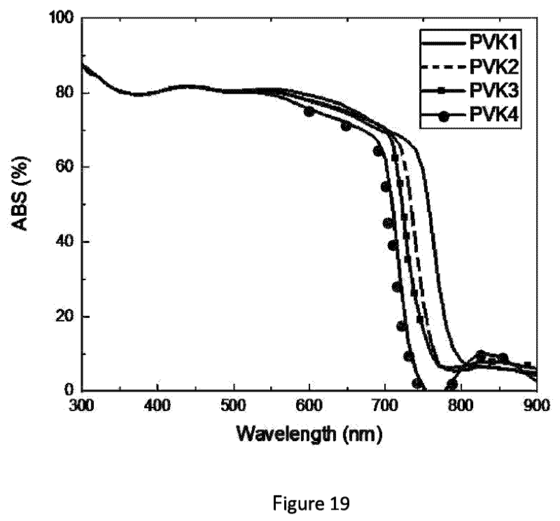

Optical characterization (transmittance, absorbance) of the samples was conducted using a Perkin Elmer Lambda 1050 UV-vis-NIR spectrophotometer. FIG. 19 shows the absorbance measurements for the samples. These results show that the four types of perovskites developed have different absorption edge and thus different bandgap. The perovskite of Cs_{0.1}FA_{0.765}MA_{0.135}PbI_{2.22}Br_{0.78} showed a bandgap of 1.69 eV, which can be optimum for tandem fabrications.

### Example 8—Thermal Deposition Conditions

The conditions employed for the diffusing and drive-in steps used in thermal deposition may be optimized by varying the doping temperatures, polycrystalline silicon layer thickness, growth method for the SiO₂ (thermal and chemical), and diffusion temperatures. The effects on passivation behaviour and the contact resistance may be analysed to establish the best conditions for both good passivation (high V_{oc}) and low resistivity (high FF).

For a cell in accordance with FIG. 14, the contact resistivity between the p-type poly-Si layer and the TiO₂ layer (the electron transport layer of the top perovskite cell) was measured.

The results in Tables 4a-4d below illustrate the surface passivation of the polycrystalline silicon before and after forming gas annealing. The results in Table 5 illustrate the quality of contact of the polycrystalline silicon before and after forming gas annealing.

In the optimisation process, for the p-type doped polycrystalline silicon layer, the boron diffusion temperature was adjusted from 880° C. to 980° C. for the diffusing (deposition) step and from 880° C. to 980° C. for the drive-in step. The sheet resistance was in the range of 35 to 750 ohms/square (ohm/□), and the implied V_{oc} value was in the range of 610 mV to 717 mV. See further details in Tables 4c and 4d below.

In the optimisation process, for the n-type doped polycrystalline silicon layer, the the phosphorus diffusion temperature was varied from 780° C. to 795° C. for the deposition step and from 830° C. to 900° C. for the drive-in step. The sheet resistance was in the range of 35 to 180 ohm/□, and the implied V_{oc} value was in the range of 695 mV to 730 mV. See further details in Tables 4a and 4b below.

TABLE 4a
Phosphorus diffusion, 2 ohm nCz

| | Diffusion | Sheet | iVoc | iVoc after |
|---|---|---|---|---|
| | conditions | resistance | before | 425° C. 30 |
| Initial precursor | (Deposition, | (ohm/ | FGA | min FGA |
| fabrication conditions | Drive in) | cm²) | (mV) | (mV) |
| 510° C. 50 min LPCVD | 790° C. 35 min, | 80 | 725 | 728 |
| (~25 nm polycrystalline | 830° C. 40 min | | | |
| layer thickness), chemical | 780° C. 35 min, | 85 | 727 | 730 |
| SiOx, pre-annealed | 830° C. 40 min | | | |
| 530° C. 50 min LPCVD | 790° C. 35 min, | 55 | 722 | 723 |
| (~50 nm polycrystalline | 830° C. 40 min | | | |
| layer thickness), chemical | 780° C. 35 min, | 60 | 719 | 723 |
| SiOx, pre-annealed | 830° C. 40 min | | | |
| 550° C. 50 min LPCVD | 790° C. 35 min, | 40 | 705 | 710 |
| (~100 nm polycrystalline | 830° C. 40 min | | | |
| layer thickness), chemical | | | | |
| SiOx, pre-annealed | | | | |
| 570° C. 50 min | 790° C. 35 min, | 35 | 695 | 700 |
| LPCVD (125-150 nm | 830° C. 40 min | | | |
| polycrystalline layer | | | | |
| thickness), chemical SiOx, | | | | |
| pre-annealed | | | | |
| 550° C. 25 min LPCVD | 780° C. 35 min, | 50 | 713 | 723 |
| (~50 nm polycrystalline | 830° C. 30 min | | | |
| layer thickness), chemical | | | | |
| SiOx, pre-annealed | | | | |

TABLE 4b
Phosphorus diffusion, 100ohm nFZ

| | Diffusion | | Single-side | iVoc | | iVoc after |
|---|---|---|---|---|---|---|
| Initial precursor | conditions | Sheet | J₀ before | before | Single-side | 425° C. |
| fabrication | (Deposition, | resistance | FGA | FGA | J₀ aft FGA | 30 min |
| conditions | Drive in) | (ohm/cm²) | (fA/cm²) | (mV) | (fA/cm²) | FGA (mV) |
| 520° C. 80 min | 795° C. 25 min, | 180 | 9 | 709 | 6 | 712 |
| LPCVD (~80 nm | 900° C. 25 min | | | | | |
| polycrystalline | | | | | | |
| layer thickness), | | | | | | |
| thermal SiOx, | | | | | | |
| not pre-annealed | | | | | | |

TABLE 4c
Boron diffusion, ramp down in N₂, 100ohm nFZ

| | Diffusion | | | iVoc | | iVoc after |
|---|---|---|---|---|---|---|
| Initial precursor | conditions | Sheet | | before | | 425° C. |
| fabrication | (Deposition, | resistance | Single-side | FGA | Single-side | 30 min |
| conditions | Drive in) | (ohm/cm²) | J₀ (fA/cm²) | (mV) | J₀ (fA/cm²) | FGA (mV) |
| 520° C. 80 min | 980° C. 25 min, | 55 | 13 | 699 | 13 | 699 |
| LPCVD (~80 nm | 980° C. 30 min | | | | | |
| polycrystalline | | | | | | |
| layer thickness), | | | | | | |
| thermal SiOx, | | | | | | |
| not pre-annealed | | | | | | |
| 520° C. 80 min | 980° C. 25 min, | 60 | 12 | 700 | 12 | 700 |
| LPCVD (~80 nm | 980° C. 30 min | | | | | |
| polycrystalline | | | | | | |
| layer thickness), | | | | | | |
| chemical SiOx, | | | | | | |
| not pre-annealed | | | | | | |
| 520° C. 50 min | 980° C. 25 min, | 45 | 24 | 693 | 24 | 693 |
| LPCVD (~50 nm | 980° C. 30 min | | | | | |
| polycrystalline | | | | | | |
| layer thickness), | | | | | | |
| chemical SiOx, | | | | | | |
| not pre-annealed | | | | | | |
| 520° C. 30 min | 980° C. 25 min, | 35 | 430 | 610 | 410 | 624 |
| LPCVD (~30 nm | 980° C. 30 min | | | | | |
| polycrystalline | | | | | | |
| layer thickness), | | | | | | |
| chemical SiOx, | | | | | | |
| not pre-annealed | | | | | | |
| 520° C. 50 min | 900° C. 25 min, | 115 | 23 | 695 | 23 | 695 |
| LPCVD (~50 nm | 900° C. 30 min | | | | | |
| polycrystalline | | | | | | |
| layer thickness), | | | | | | |
| chemical SiOx, | | | | | | |
| not pre-annealed | | | | | | |
| 520° C. 50 min | 880° C. 25 min, | 260 | 27 | 693 | 26 | 693 |
| LPCVD (~50 nm | 930° C. 30 min | | | | | |
| polycrystalline | 920° C., 25 min | 175 | 120 | 657 | 108 | 660 |
| layer thickness), | 950° C., 30 min | | | | | |
| thermal SiOx, | | | | | | |
| not pre-annealed | | | | | | |

TABLE 4d
Boron diffusion, 2 ohm nCz

| | Diffusion | Sheet | iVoc | iVoc after |
|---|---|---|---|---|
| Initial precursor | conditions | resistance | before | 425° C. 30 |
| fabrication | (Deposition, | (ohm/ | FGA | min FGA |
| conditions | Drive in) | cm²) | (mV) | (mV) |
| 510° C. 50 min LPCVD | 900° C. 40 min, | 400 | 617 | 617 |
| (~25 nm | 930° C. 30 min | | | |
| polycrystalline layer | 880° C. 50 min, | 750 | 613 | 615 |
| thickness), chemical | 880° C. 20 min | | | |
| SiOx, pre-annealed | 920° C. 40 min, | 260 | 624 | 633 |
| | 930° C. 30 min | | | |
| | 900° C. 50 min, | 760 | 613 | 614 |
| | 900° C. 10 min | | | |
| 530° C. 50 min LPCVD | 900° C. 40 min, | 220 | 695 | 697 |
| (~50 nm | 930° C. 30 min | | | |
| polycrystalline layer | 880° C. 50 min, | 410 | 709 | 711 |
| thickness), chemical | 880° C. 20 min | | | |
| SiOx, pre-annealed | 920° C. 40 min, | 654 | 660 | 660 |
| | 930° C. 30 min | | | |
| | 900° C. 50 min, | 440 | 660 | 670 |
| | 900° C. 10 min | | | |
| 550° C. 50 min LPCVD | 900° C. 40 min, | 130 | 665 | 666 |
| (~100 nm | 930° C. 30 min | | | |
| polycrystalline layer | 880° C. 50 min, | 250 | 690 | 691 |
| thickness), chemical | 880° C. 20 min | | | |
| SiOx, pre-annealed | 920° C. 40 min, | 100 | 647 | 647 |
| | 930° C. 30 min | | | |
| | 900° C. 50 min, | 230 | 700 | 700 |
| | 900° C. 10 min | | | |
| | 880° C. 50 min, | 260 | 688 | 688 |
| | 880° C. 50 min | | | |
| 570° C. 50 min LPCVD | 900° C. 40 min, | 80 | 650 | 650 |
| (125-150 nm | 930° C. 30 min | | | |
| polycrystalline layer | 880° C. 50 min, | 110 | 690 | 690 |
| thickness), chemical | 880° C. 20 min | | | |
| SiOx, pre-annealed | 920° C. 40 min, | 80 | 650 | 650 |
| | 930° C. 30 min | | | |
| | 900° C. 50 min, | 100 | 693 | 693 |
| | 900° C. 10 min | | | |
| | 880° C. 50 min, | 120 | 694 | 695 |
| | 880° C. 50 min | | | |
| 550° C. 25 min LPCVD | 880° C. 50 min, | 440 | 717 | 718 |
| (~50 nm | 880° C. 20 min | | | |
| polycrystalline layer | 880° C. 50 min, | 240 | 696 | 700 |
| thickness), chemical | 880° C. 50 min | | | |
| SiOx, pre-annealed | 900° C. 40 min, | 410 | 708 | 708 |
| | 900° C. 10 min | | | |
| | 900° C. 30 min, | 530 | 697 | 698 |
| | 900° C. 10 min | | | |
| | 900° C. 50 min, | 230 | 708 | 708 |
| | 900° C. 10 min | | | |
| | 950° C. 30 min, | 160 | 698 | 698 |
| | 900° C. 10 min | | | |
| | 930° C. 50 min, | 140 | 697 | 698 |
| | 930° C. 10 min | | | |
| | 930° C. 50 min, | 240 | 688 | 688 |
| | No Drive in | | | |
| 530° C. 80 min LPCVD | 950° C. 40 min, | 100 | 705 | 705 |
| (~80 nm | 950° C. 25 min | | | |
| polycrystalline layer | 930° C. 40 min, | 115 | 713 | 713 |
| thickness), thermal | 930° C. 25 min | | | |
| SiOx, pre-annealed | | | | |
| 530° C. 80 min LPCVD | 950° C. 40 min, | 100 | 709 | 709 |
| (~80 nm | 950° C. 25 min | | | |
| polycrystalline layer | 930° C. 40 min, | 120 | 701 | 703 |
| thickness), thermal | 930° C. 25 min | | | |
| SiOx, NOT pre- | | | | |
| annealed | | | | |
| 530° C. 80 min LPCVD | 950° C. 40 min, | 85 | 693 | 694 |
| (~80 nm | 950° C. 25 min | | | |
| polycrystalline layer | 930° C. 40 min, | 105 | 700 | 700 |
| thickness), chemical | 930° C. 25 min | | | |
| SiOx, pre-annealed | | | | |
| 530° C. 80 min LPCVD | 950° C. 40 min, | 70 | 680 | 680 |
| (~80 nm | 950° C. 25 min | | | |
| polycrystalline layer | 930° C. 40 min, | 85 | 697 | 698 |
| thickness), chemical | 930° C. 25 min | | | |
| SiOx, NOT pre- | | | | |
| annealed | | | | |

TABLE 5

| | Poly: all 80 nm LPCVD | | |
|---|---|---|---|
| | Boron Diffusion: 25/dep, 30/O₂, | | |
| | ramp up & down in N1 | | |
| | | Contact | Contact |
| | | resistivity | resistivity |
| p-type poly-Si | | (mΩ · cm²) | (mΩ · cm²) |
| optimisation | Boron diffusion | (Before for ming | (After for ming |
| for tandems | temperature | gas annealing) | gas annealing) |
| Thermal oxide | 880° C. | 40.7 | 17.3 |
| for the oxide | 900° C. | 36.6 | 14.9 |
| layer | 950° C. | 60.9 | 24.1 |
| | 900° C. deposition | 105 | 13.9 |
| | (980° C. drive in) | | |
| Chemical oxide | 880° C. | 38.2 | 26.1 |
| for the oxide | 900° C. | 36.6 | 31.9 |
| layer | 950° C. | 161 | 34.2 |
| | 900° C. deposition | 171 | 13 |
| | (980° C. drive in) | | |

According to these results, it is considered that an optimised doping temperature range for the double-sided polycrystalline silicon CSL tandem cell is 980° C. deposition for 25 mins, 980° C. drive in for 25 mins for boron diffusion, and 820° C. deposition for 25 mins, 900° C. drive in for 25 mins for phosphorus diffusion. Both chemical oxide and thermal oxide can lead to good contact at suitable temperature range in the tandem device. Chemical oxide may be advantageous for better control of the interfacial oxide thickness.

### Example 9—Tandem Cell with Ultrathin Hole Transport Layer, Protective Layer and Barrier Layer

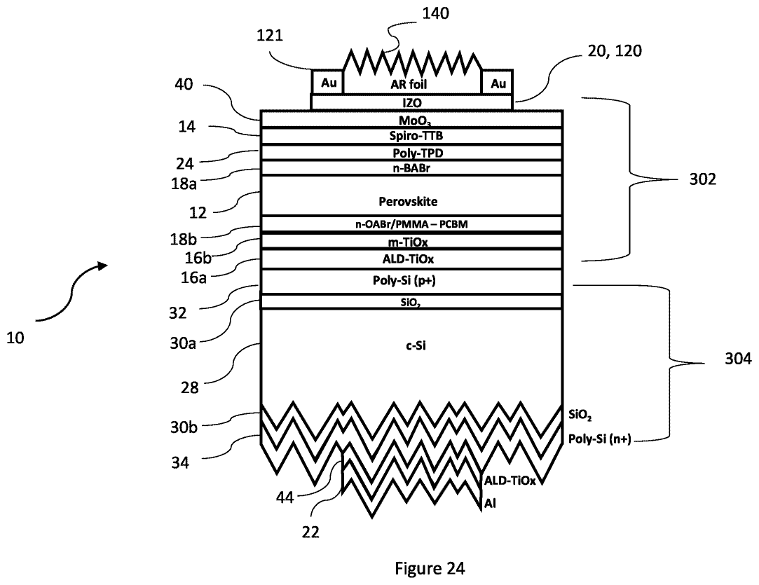

Tandem solar cells in accordance with the schematic shown in FIG. 24 were prepared according to the following example.

### Silicon Sub-Cell 304

The silicon sub-cell was prepared using a silicon wafer with polished front and rear surfaces, having a thickness of 270 μm and a resistivity of between 1 to 5 ohm·cm. The silicon wafers were subjected to RCA cleaning before further processing (RCA1=10 minutes, 60° C. dip in 1:1:7 NH₃:H₂O₂:H₂O; 1% wt HF dip for 1 min; RCA2=10 minutes, 60° C. dip in 1:1:7 HCl:H₂O₂:H₂O; 1% wt HF dip for 1 min.).

The cleaned silicon wafer was then covered with a masking oxide. The wafer was oxidised in a tube furnace under O₂ atmosphere at 1050° C. to grow a thin layer of SiOₓ as insulation for the non-active cell areas.

Next the front cell area was defined by photolithography. The SiOₓ layer in the defined front cell area along with all of the rear surface was etched using buffered HF solutions.

Thin SiOₓ layers were grown on the etched surfaces by treating the wafers with hot concentrated nitric acid at 90° C. for 30 minutes, thus forming the passivation' layers 30a, 30b.

Intrinsic polycrystalline silicon layers were deposited on both sides of the cleaned and passivated silicon wafer. Low Pressure Chemical Vapor Deposition (LPCVD) was used to grow intrinsic polycrystalline silicon using Silane as a reactant gas.

Doping was performed in a back-to-back configuration as detailed in Example 2.

Boron doping was performed on the front side, with the wafers placed in a back-to-back configuration during the diffusion process, with the rear sides of the two wafers facing each other. The reactant gas employed was BBr₃, N₂ and O₂. The oxidation is minimized by switching off O₂ gas after deposition.

The boron thermal diffusion is conducted with a 40 mins deposition step at 880° C., followed by a 10 mins drive-in step at 880° C.

Phosphorous doping is performed on the rear side, with the boron doped front sides of the wafers now facing each other and the rear sides are exposed to the ambient environment of the deposition chamber. The reactant gas employed is POCl₃, N₂, and 02. Oxidation is minimised by switching off O₂ gas after dopant deposition.

The phosphorus thermal diffusion is conducted with a 25 mins deposition step at 800° C., followed by a 25 mins drive-in step at 870° C.

After doping the phosphorous and boron into the respective polycrystalline silicon layers, the wafers were subjected to a forming gas anneal, using 95% N₂ and 5% H₂, at 425° C. for 30 minutes.

Finally, the wafers are subjected to etching with a 1% HF solution to remove the boron and phosphorous glasses formed during thermal diffusion.

This fabricates the doped polycrystalline silicon CSLs 32 (p-type doped) and 34 (n-type doped).

### Barrier Layer 44 and Electron Transport Layer—First Sub-Layer 16a

The bottom (second) sub-cell 304 was transferred to a thermal ALD system for depositing compact TiO₂ layers on both surfaces of the sub-cell 304 as a first sub-layer 16a of the ETL and a barrier layer 44. A TiCl₄ precursor and N₂ purge gas were utilized for the process. The reactor temperature was set at 200° C. and H₂O was used as the oxidant. The chamber N₂ flow was set at 200 standard cubic centimeters per minute (sccm). Each ALD cycle consisted of a 0.75 s pulse of TiCl₄ followed by a 0.050 s pulse of H₂O. Between each precursor pulse, a 0.75 s purge under a constant flow (300 sccm) of research-grade N₂(g) was used.

The silicon sub-cell 304 is then subjected to a 30-minute thermal annealing in ambient air before the remaining layers are deposited.

### Bottom Electrode 22

After deposition of the TiO₂ layers 16a, 44, 500 nm of Al was deposited on the rear surface as the bottom electrode 22 using thermal evaporation.

### Electron Transport Layer —Second Sub-Layer 16b

Next, an electron transport layer 16b of mesoporous TiO₂ was deposited on top of the compact TiO₂ layer 16a. The precursor employed was a diluted TiO₂ paste solution (TiO₂ paste (30NRD): Ethanol=1:12). A layer of mesoporous TiO₂ (100 nm) was deposited on the Si cell by spinning a solution of TiO₂ paste (30NRD) at 5000 rpm for 15 s, followed by another annealing step at 400° C. for 25 minutes.

### Passivation Layer, 18b

Passivation layers comprising a combination of PMMA-PCBM and n-OABr were deposited on top of the mesoporous TiO₂ layer 16b. A PMMA-PCBM blend solution was used as a precursor. This solution was prepared by dissolving 1 mg PMMA (Mw˜120000, Sigma Aldrich) and 3 mg PC61BM (Sigma Aldrich) into 1 mL Chlorobenzene. The solution was spin coated at 4000 rpm for 30 seconds.

The n-OABr layer was deposited on the PMMA-PCBM layer. A solution of n-OABr (2 mg/ml in Isopropanol) was spin-coated at 5000 rpm for 15 s. This was followed by an annealing step at 100° C. for 10 minutes.

### Absorber Layer 12

The absorber comprises a perovskite material. In this instance, the perovskite material had the following composition: Cs_{0.1} Rb_{0.05}FA_{0.765}MA_{0.135}PbI_{2.22}Br_{0.78}Cl_{0.015}. This was prepared from a precursor solution containing 0.96 M PbI₂, 0.99 M FAI, 0.16 M PbBr₂, 0.18 M MABr, 0.13 M CsI, 0.065 M RbI, and 1.5 mol % PbCl₂ in 0.875 ml of anhydrous N,N′-dimethylformamide (DMF)/dimethyl sulfoxide (DMSO) (8:2, v/v). The multiple-cation perovskite precursor solution was deposited by spin coating at 2000 rpm with a ramp rate of 1000 rpm s⁻¹ for 12 s. Then the sample was transferred to a vacuum jig and underwent a vacuum flashing process at a pressure of 120 mTorr for 15 s and 1.5 Torr for 15 s. The film was then heated on hot plate for 120° C. for 20 mins or 120° C. for 10 mins and 100° C. for 10 mins.

### Passivation Layer 18a

A passivation layer comprising n-BABr was deposited on top of the absorber layer. A precursor solution of n-BABr (2 mg/ml in Isopropanol) was spin coated at 5000 rpm for 15 s. Following this, annealing was performed at 100° C. for 10 minutes.

### Protective Layer 24

The protective layer comprises poly-TPD. A precursor solution of poly-TPD was spin coated at 5000 rpm for 15 s on top of the n-BABr layer. Versions of this example with the concentration of poly-TPD precursor varying from 0.1 mg/mL to 1 mg/mL, including a concentration of 0.5 mg/mL, were prepared to provide different embodiments of the protective layer.

### Ultrathin Hole Transport Layer 14

The ultrathin hole transport layer 14 was deposited on top of the protective layer 24. The ultrathin hole-transport layer 14 in this example comprises 2,2′,7,7′-Tetra(N,N-di-p-tolyl)amino-9,9-spirobifluorene (Spiro-TTB). A ˜10 nm layer of Spiro-TTB was deposited using thermal evaporation. The deposition was performed under a high vacuum of 8×10⁻⁷ Torr.

### Buffer Layer 40

Following this, a buffer layer of MoO₃ was deposited by thermal evaporation at a rate of 0.05 nm/s. The deposition was performed under a high vacuum of 8×10⁻⁷ Torr.

### Top Electrode Layer 20

Finally, the top electrode layer was deposited on the MoO₃ layer to complete the device. The front transparent contact 120 was fabricated by sputtering ˜40-nm indium zinc oxide (IZO) on the MoO₃ (Buffer Layer 40). The sputtering was performed for 60 min with 30 W of RF power under an Ar plasma, with a chamber pressure of 1.5 mTorr.

To complete the device, Au fingers and busbars 121 were deposited on the sample using thermal evaporation through a shadow mask. An anti-reflection coating 140 in the form of a silicon texture foil was attached mechanically to the top of the tandem cell to allow light trapping in the cell.

### Example 10—Contact Resistivity

A sample was prepared in accordance with Example 9, using a 0.5 mg/mL poly-TPD precursor to form the protective layer 24.

The ALD-TiO₂ barrier layer 44 between the n-type poly-Si layer 34 on the back and the metal contact 22 may improve the thermal stability of the tandem cell 10, allowing the use of aluminium (Al) instead of the commonly used Ag as a contact. The contact resistivity of the Al/TiO₂/n-type poly-Si/SiO₂ structure 22, 44, 34, 30b was measured to be 57 mΩ·cm². As described in Example 9, the Al contact (electrode 22) is deposited after a 30-minute thermal annealing in air ambient (i.e. after deposition of the electron transport layer first sub-layer_16a of ALD-TiO₂). The annealing is performed prior to the deposition of layer 16b (i.e. after the lower sub-cell is fabricated and prior to deposition of the upper sub-cell).

The TiO₂ barrier layer 16a may also form a low-resistivity ohmic contact with the p-type poly-Si/SiO₂ contact on the front of the poly-Si cell, enabling interconnect-free tandem structure.

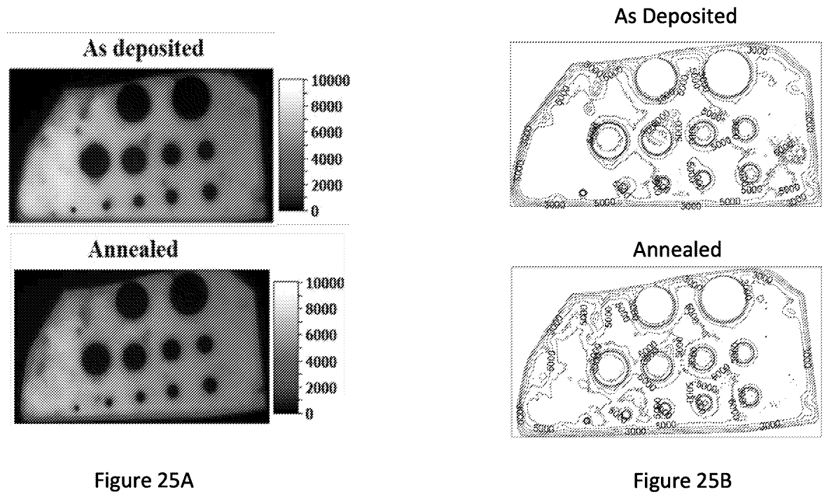

The surface passivation of the rear-side poly-Si contact with the metal electrode (the Al/TiO₂/n-type poly-Si/SiO₂ structure 22, 44 34, 30b) was maintained after annealing, as demonstrated by photoluminescence (PL) images showing the surface passivation characteristics in FIGS. 25A and 25B. According to the quasi-steady state shortcut (QSSSC) measurement, the implied V_{oc} of the n-type poly-Si/SiO₂ contact reaches over 740 mV, with the implied V_{oc} of the p-type reaching 730 mV.

The as-prepared champion Si sub-cell 304 exhibits an implied V_{oc} up to 720 mV under 1-sun illumination.

### Example 11—Effect of the Ultrathin Hole Transport Layer and Protective Layer

Samples were fabricated as described below to evaluate the effect of the hole transport layer and the protective layer in a perovskite single junction solar cell or a perovskite sub-cell utilized in a tandem cell. Three samples were fabricated:
1. a perovskite cell with a standard doped Spiro-OMeTAD layer;
2. a perovskite cell with a Spiro-TTB HTL layer, but without a protective Poly-TPD layer; and
3. a perovskite solar cell cell with a Spiro-TTB HTL layer and a protective Poly-TPD layer.

The sample preparation procedure for all the above samples involved the following steps:
FTO/glass substrates for single-junction perovskite cells were sequentially cleaned with detergent for 90 min, followed by deionized (DI) water, acetone, isopropanol, ethyl alcohol and DI water for 15 minutes per step in an ultrasonic bath.
Following this, the FTO glass or Si bottom cells were UV-ozone treated for 15 mins.
Next, mesoporous TiO₂ layer was fabricated by spin-coating diluted TiO₂ paste solution (30NRD: Ethanol=1:12 wt.) at 5000 rpm/5000 acc for 15 s, followed by annealing at 400° C. for 25 minutes.
Subsequently, PMMA: PCBM passivation layer was spin-coated at 4000 rpm/4000 ace for 15 s, then annealed at 100° C. for 10 mins. The PMMA:PCBM blend solution was prepared by dissolving 1 mg PMMA (Mw˜120000) and 3 mg PCBM into 1 mL Chlorobenzene. The passivation layers were based on Isopropanol).
A layer of n-OACl was deposited on the substrate by spinning the n-OACl solution (2 mg/mL) at 5000 rpm/5000 acc for 15 s, followed by annealing step at 100° C. for 10 mins.
Next, the absorber layer was deposited. In this regard, the perovskite solution contained 0.96 M PbI₂, 0.99 M FAI, 0.16 M PbBr₂, 0.18 M MABr, 0.13 M CsI, 0.065 M RbI, and 1.5 mol % PbCl₂ in 0.875 ml of anhydrous N,N′-dimethylformamide (DMF)/dimethyl sulfoxide (DMSO) (8:2, v/v). The multiple-cation perovskite precursor solution was deposited by spin coating at 2000 rpm with a ramp rate of 1000 rpm s⁻¹ for 12 s. Then the sample was transferred to a vacuum jig and undergoes a vacuum flashing process at a pressure of 120 mTorr for 15 s and 1.5 Torr for 15 s. The film was then heated on hot plate for 120° C. for 20 mins or 120° C. for 10 mins and 100° C. for 10 mins.
A passivation layer was deposited on the perovskite layer by dynamic spinning the n-BABr solution (1.15 mg/mL in Isopropanol) at 5000 rpm/1000 acc for 30 s, followed by another annealing step at 100° C. for 10 mins.

Following the above common steps, Samples 1 to 3 with different hole transport layers were deposited as detailed below:

For Sample 1, a Spiro-OMeTAD precursor solution was prepared by dissolving 72.5 mg of Spiro-OMeTAD, 28.5 ml of 4-tert-butylpyridine (TBP), and 17.5 ml of lithium bis(trifluoromethanesulfonyl)imide (LiTFSI)solution (520 mg ml-1 in acetonitrile) in 1 ml of chlorobenzene. The Spiro-OMeTAD thin film was deposited by spin-coating the precursor solution at 3500 rpm with a ramp of 3500 rpm s−1for 30 s.

For Sample 3, the hole transport layer comprising poly-TPD (EMNI, 200,000 K) was deposited by spin coating a solution of Poly-TPD (0.5 mg/mL in chlorobenzene) at 5000 rpm/5000 ace for 15 s, followed by another annealing step at 100° C. for 5 mins. Then, approximately 5-10 nm of Spiro-TTB (Lumtec.) was deposited on the samples by thermal evaporation at a rate of 0.1 Å/s under a high vacuum of 8×10⁻⁷ torr.

For fabrication of Sample 2, all the process steps described above for Sample 3 were followed except for the deposition of the poly-TPD layer.

Following the deposition of the hole transport layers, the remaining layers were deposited as detailed below:
A 6.2 nm MoOₓ layer was then deposited on the samples by thermal evaporation (Angstrom) at a rate of 0.1 Å/s.
100 nm full-area Au contacts were deposited on the sample using thermal evaporation through a shadow mask.
For monolithic tandem device, the front transparent contact was then fabricated by sputtering ˜40 nm IZO on the buffer layer with 30 W of radio-frequency (RF) power under Ar plasma, with a chamber pressure of 1.5 mtorr for 60 min. To complete the device, Au fingers and busbars were deposited on the sample using thermal evaporation through a shadow mask.

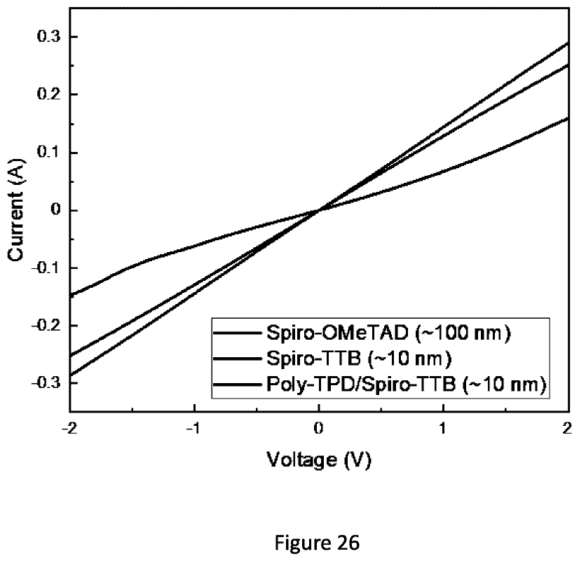

Sample 2, which has an ultra-thin (˜10 nm), dopant-free Spiro-TTB layer showed a lower resistivity (1.15 Ωcm²) compared to Sample 1, which uses the standard doped Spiro-OMeTAD layer (100 nm) and which has a resistivity of 2.35 Ωcm² (see FIG. 26)

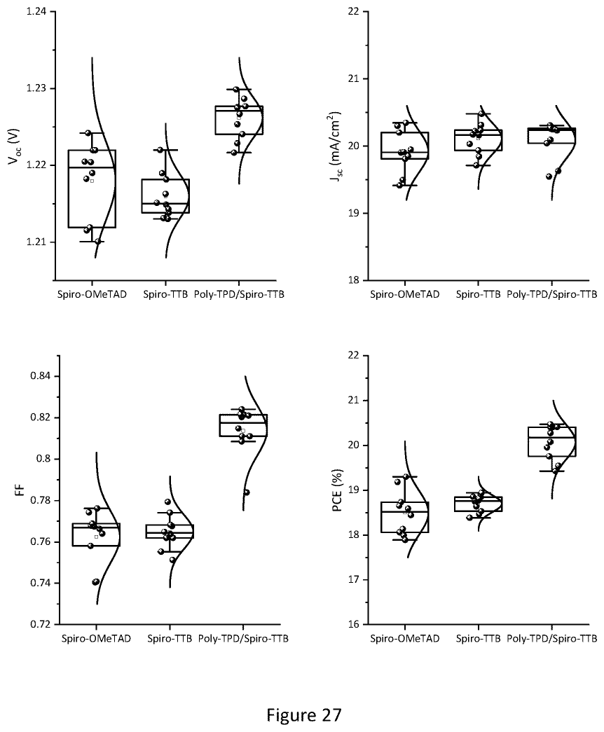

As noted above, Sample 1 is the control sample with a standard doped Spiro-OMeTAD layer, leading to a V_{oc}=1.22 V, a J_{sc}=20.20 mA/cm², an FF=0.76, and a PCE=18.66%, with negligible hysteresis (See FIG. 27). These results are comparable with the other reported wide bandgap perovskite solar cells (PSCs) with similar bandgap ranging from 1.65 to 1.72 eV (see e.g. Y. Tong et al., Wide-Bandgap Organic-Inorganic Lead Halide Perovskite Solar Cells. Advanced Science 9, 2105085 (2022)). The Sample 2 (with a Spiro-TTB HTL) exhibits slightly improved photovoltaic performance, with a V_{oc} '₂ 1.22 V, a J_{sc}=20.16 mA/cm², an FF=0.77, and a PCE=18.82% (See FIG. 27).

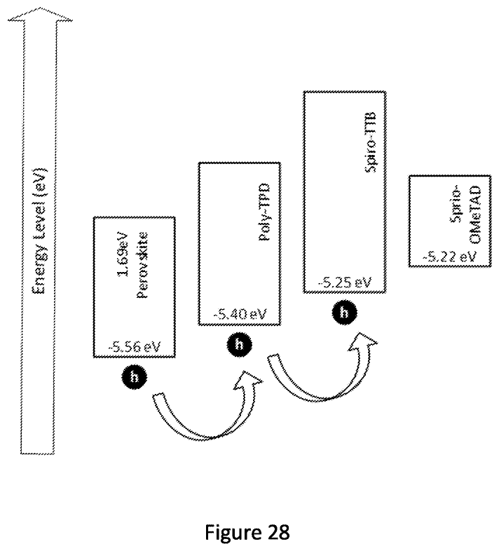

Sample 3 which includes an ultra-thin, dopant-free poly(N,N′-bis-4-butylphenyl-N,N′-bisphenyl)benzidine (Poly-TPD) layer between Spiro-TTB and perovskite made by spin-coating a diluted poly-TPD solution, which has a lower HOMO level (−5.40 eV) than those of Spiro-OMeTAD or Spiro-TTB, allowing a cascade energy level alignment in the device shown in FIG. 28.

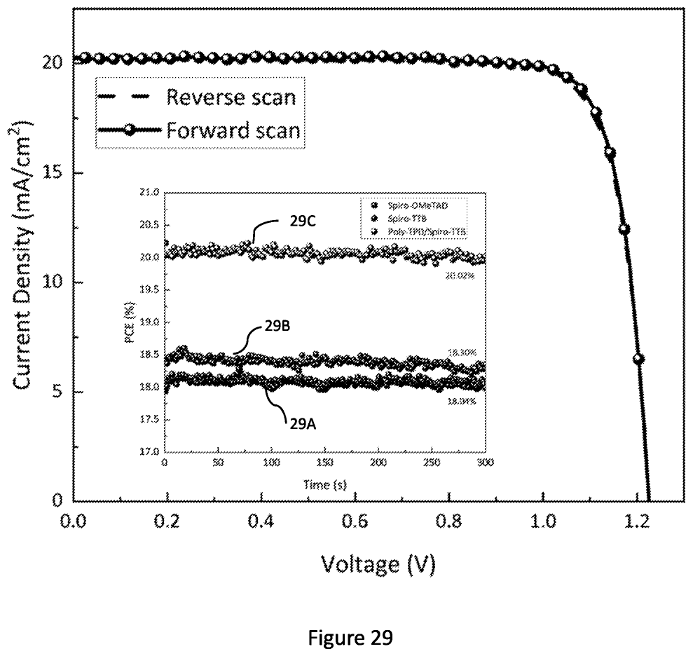

FIG. 29 shows the J-V curve for additional samples in accordance with Sample 3. In addition, the inset of FIG. 29 shows the stabilized PCE at maximum power point (MPP) under one-sun illumination for over 300 s for Samples 1, 2 and 3 (see data points 29A, 29B and 29C, respectively). A stabilized PCE of 20.02% at maximum power point (MPP) under one-sun illumination for over 300 s was achieved for Sample 3, 18.30% for Sample 2, and 18.04% for Sample 1.

### Example 12—Varying the Protective Layer

Samples were fabricated to identify the effect of varying the concentration for the precursor solution used for forming a poly-TPD protective layer. The following process steps were involved in the fabrication of the samples with varying concentrations of poly-TPD in the precursor.

FTO/glass substrates for single-junction perovskite cells were sequentially cleaned with detergent for 90 min, followed by deionized (DI) water, acetone, isopropanol, ethyl alcohol and DI water for 15 minutes per step in an ultrasonic bath.

Following this, FTO glass or Si bottom cells were then UV-ozone treated for 15 mins. The mesoporous

TiO₂ layer was fabricated by spin-coating diluted TiO₂ paste solution (30NRD:Ethanol=1:12 wt.) at 5000 rpm/5000 acc for 15 s, followed by annealing at 400° C. for 25 minutes.

The PMMA: PCBM passivation layer was spin-coated at 4000 rpm/4000 acc for 15 s, then annealed at 100° C. for 10 mins. The PMMA: PCBM blend solution was prepared by dissolving 1 mg PMMA (Mw˜120000) and 3 mg PCBM into 1 mL Chlorobenzene. The passivation layers were based on Isopropanol).

A layer of n-OACl was deposited on the substrate by spinning the n-OACl solution (2 mg/mL) at 5000 rpm/5000 acc for 15 s, followed by annealing step at 100° C. for 10 mins.

To deposit the absorber layer, the multiple-cation perovskite precursor solution was prepared and deposited by spin coating at 2000 rpm with a ramp rate of 1000 rpm s⁻¹ for 12 s. The perovskite solution contained 0.96 M PbI₂, 0.99 M FAI, 0.16 M PbBr₂, 0.18 M MABr, 0.13 M CsI, 0.065 M RbI, and 1.5 mol % PbCl₂ in 0.875 ml of anhydrous N,N′-dimethylformamide (DMF)/dimethyl sulfoxide (DMSO) (8:2, v/v). Then the sample was transferred to a vacuum jig and underwent a vacuum flashing process at a pressure of 120 mTorr for 15 s and 1.5 Torr for 15 s. The resulting film was then heated on hot plate for 120° C. for 20 mins or 120° C. for 10 mins and 100° C. for 10 mins.

A passivation layer was deposited on the perovskite layer by dynamic spinning the n-BABr solution (1.15 mg/mL in Isopropanol) at 5000 rpm/1000 acc for 30 s, followed by another annealing step at 100° C. for 10 mins.

The protective layer of poly-TPD (EMNI, 200,000 K) was formed by spin coating solution in chlorobenzene at 5000 rpm/5000 acc for 15 s, followed by another annealing step at 100° C. for 5 mins. The poly-TPD concentrations are varied from 0.1 mg/mL, 0.5 mg/mL and 1 mg/mL, to make three different solar cells respectively.

Then, approximately 10 nm of Spiro-TTB (Lumtec) (as the hole transport layer) was deposited on the samples by thermal evaporation at a rate of 0.1 Å/s under a high vacuum of 8×10⁻⁷ torr. A 6.2 nm MoOₓ layer (buffer layer) was then deposited on the samples by thermal evaporation (Angstrom) at a rate of 0.1 Å/s. 100 nm full-area Au contacts were deposited on the sample using thermal evaporation through a shadow mask. For monolithic tandem device, the front transparent contact was then fabricated by sputtering ˜40 nm IZO on the buffer layer with 30 W of radio-frequency (RF) power under Ar plasma, with a chamber pressure of 1.5 mtorr for 60 min.

To complete the device, Au fingers and busbars were deposited on the sample using thermal evaporation through a shadow mask.

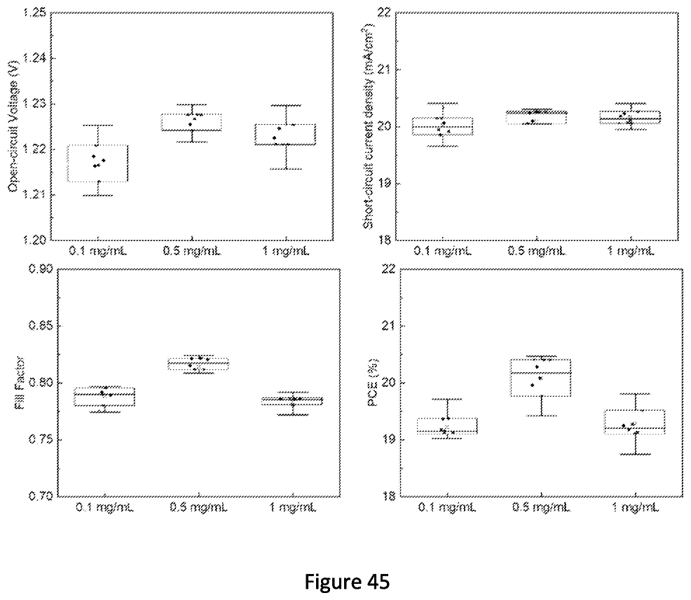

The effect of the concentration of poly-TPD precursor (varying from 0.1 mg/mL to 1 mg/mL) on the device performance was studied (See FIG. 45). It is believed that increasing the concentration of the precursor used can lead to an increase in layer thickness, compactness, and/or layer regularity.

It was found that 0.5 mg/mL is optimal condition. Without being bound by theory is it believed that this precursor may allow formation of a poly-TPD layer with good coverage and moderate thickness to allow efficient hole extraction, indicated by low resistivity of the layer (see FIG. 26).

Sample 3 of Example 11 (described above) had improved FF (0.82) and a slightly increased V_{oc} (1.23 V) thus a PCE of 20.47% (see FIG. 27) with negligible hysteresis. A stabilized PCE of 20.02% at maximum power point (MPP) under one-sun illumination for over 300 s was achieved (see inset of FIG. 29).

### Example 13—Stability Assessment

Samples were prepared in accordance with Example 9 and tested for their stability. Prior to testing, the samples were subjected to further processing to simulate real time conditions. In this regard, the sample was encapsulated using the glass-to-glass edge-sealing method. The perovskite solar cells were sandwiched between two pieces of glass and sealed at the edges with polyisobutene (PIB). In particular, the perovskite solar cell sample used for testing was placed in a glove box. Electrodes based on conductive copper tape are attached via copper-tin cable. The perovskite solar cell is then sandwiched between two pieces of glass and the edges were sealed using PIB by heating and pressing using a custom-made pressure tool. The solar cell was heated to 95° C. and continuously pressed to ensure the PIB to be sealed effectively.

It was observed that the sample maintained 99.6% of its initial PCE after 1500 hours when stored in ambient at 25° C./40-60% RH.

Without being bound by theory, it is believed that the cross-linkable property of Poly-TPD with hydrophobic butylene functional groups can protect the perovskite film from moisture permeation and the passivation effect for the interfacial defects, such as uncoordinated species existing between perovskite and HTL, in addition to the non-doping featuring of Spiro-TTB are the main contributors for enhanced stability.

### Example 14—Photoluminescence (PL) Measurements

Samples with different configurations detailed below were prepared to evaluate the photoluminescence properties:
1. pristine perovskite film
2. a perovskite layer with a standard doped Spiro-OMeTAD layer;
3. a perovskite layer with a Spiro-TTB HTL layer, but without a protective Poly-TPD layer; and
4. a perovskite layer with a Spiro-TTB HTL layer and a protective Poly-TPD layer.

In general, these samples were prepared according to processes described for Example 11 which adjustments as described below:

### Sample 1—Pristine Perovskite Film

This sample was fabricated by following the steps up to the deposition of the perovskite film layer. Subsequent steps involving deposition of the passivating layers and contacts were not performed.

Sample 2—Perovskite Layer with a Standard Doped Spiro-OMeTAD Layer:

This sample was fabricated by following the steps for Sample 1 of Example 11 up to the deposition of the hole transport layer as described in Example 11. Subsequent steps were not performed.

Sample 3—Perovskite Layer with a Spiro-TTB HTL Layer, but without a Protective Poly-TPD Layer

This sample was prepared following the steps for Sample 2 of Example 11 up to and including the deposition of the hole transport layer comprising Spiro-TTB.

Sample 4—Perovskite Layer with a Spiro-TTB HTL Layer and a Protective Poly-TPD Layer

This sample was prepared following the steps for Sample 3 of Example 11 up to and including the deposition of the hole transport layer comprising both Spiro-TTB and poly-TPD layers.

To investigate the dynamics of charge carriers, steady-state and time-resolved photoluminescence (PL) measurements were carried out on the samples with the sample described above. For PL imaging, a custom-built PL imaging system, equipped with 430 nm royal-blue LEDs and 451/106 nm bandpass filters was used. The cells were held in a N₂-filled and temperature-controlled custom-built jig and illuminated with a 1-sun equivalent intensity. A Peltier-cooled (−70° C.) Si CCD camera (Princeton Instruments Pixis 1024) along with a 750 nm long-pass filter was used to obtain a PL image of the cells with an exposure time of 0.01 s. The PL images were taken under both open⁺-circuit and reverse bias (−1 V) conditions. Fiji software was used to subtract the open-circuit images from the reverse bias ones to ensure the PL emission was solely from the active area of the device.

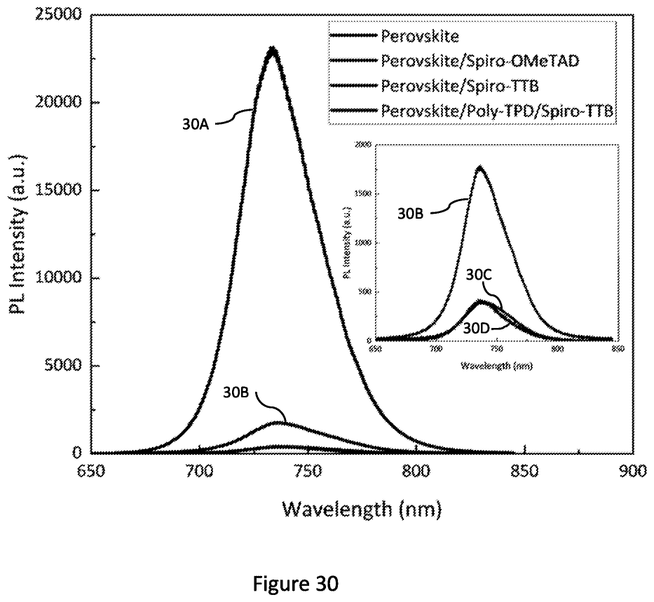

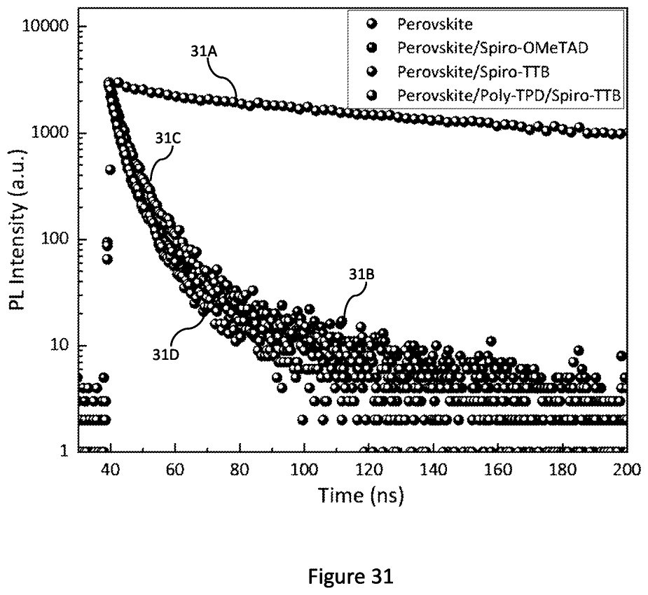

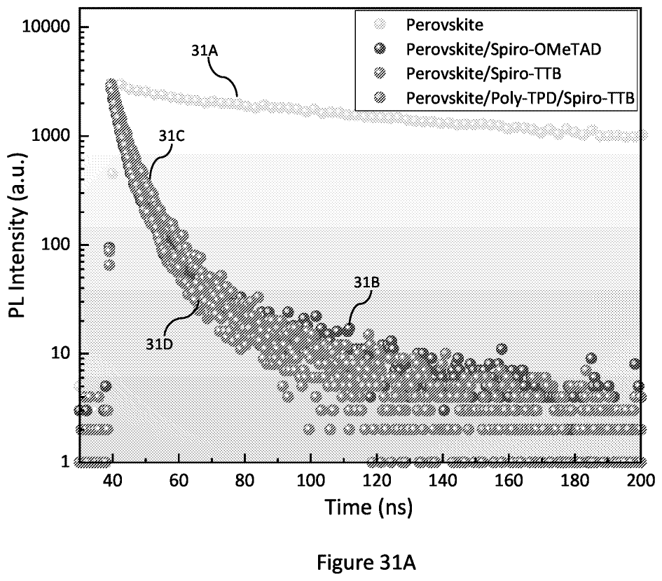

The PL peak for all samples was found to be around 730 nm (see FIG. 30: line 30A —Sample 1; line 30B—Sample 2; line 30C—Sample 3; line 30D—Sample 4). The perovskite film samples incorporating HTLs exhibited strong PL quenching (see FIG. 31A and FIG. 31: data points 31A—Sample 1; data points 31B—Sample 2; data points 31C—Sample 3; data points 31D—Sample 4), indicating effective extraction of charge carriers across the perovskite/charge transport layer (CTL) interface. Stronger PL quenching in Spiro-TTB and Poly-TPD/Spiro-TTB based perovskite films indicates that the light-excited electron-hole pairs in the perovskite film are quickly separated at both perovskite/HTL interfaces, indicating a higher hole extraction efficiency. The latter of which exhibits slightly stronger quenching than the Spiro-TTB based film at the wavelength range from 750 to 800 nm, indicating superior hole extraction ability of the bilayer HTL.

In agreement with the PL quenching in steady-state PL, the lifetime of the charged carriers in perovskite film with different HTLs (see FIGS. 31 and 31A) decreased dramatically, dropping from 379 ns for the pristine perovskite film to 14.4 ns, 12.6 ns, and 10.2 ns for perovskite films based on Spiro-OMeTAD, Spiro-TTB, and Poly-TPD/Spiro-TTB HTLs, respectively.

### X-Ray Diffraction (XRD)

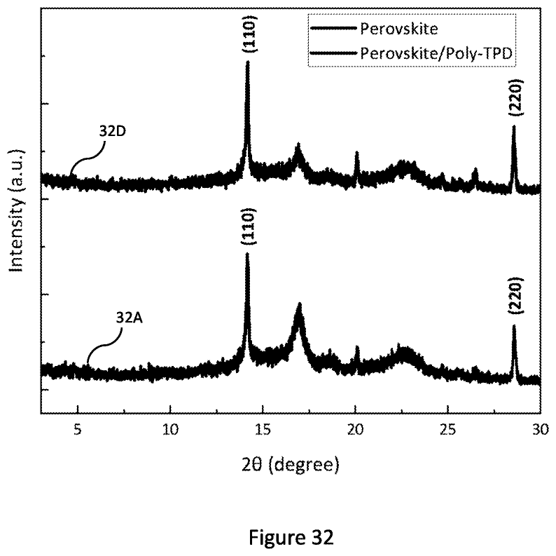

The poly-TPD protective layer was also found to enhance the crystallinity and film quality of the perovskite film, as revealed by stronger peak intensity at 14.1° and 28.2°, corresponding to (110) and (220) planes from XRD patterns (see FIG. 32: line 32A —Sample 1; line 32D —Sample 4). In addition, the characteristic peak of uncoordinated organic species, such as methylammonium, at 17.0° was smaller in poly-TPD coated perovskite film, indicating the passivation effect, which is considered mainly to come from the Lewis acid-base interaction between the central nitrogen atom of the triphenylamine group in poly-TPD and uncoordinated carbon and nitrogen bonds from organic species in perovskite film. This contributes to the improvement of the V_{oc} of the as-prepared device (see FIG. 27).

### X-Ray Photoelectron Spectroscopy (XPS)

The passivation effect of the poly-TPD layer was further confirmed by XPS analysis. For X-ray photoelectron spectroscopy (XPS) characterization, a SPECS (Berlin) machine was used. For XPS measurement, X-ray emission was conducted with Mg K α line (12 kV-200 W) anode from an UHV non-monochromatic source. High-resolution scans at a pass energy of 10 eV were recorded after a survey scan for characterizing the chemical states. The excitation energy was 1253.6 eV.

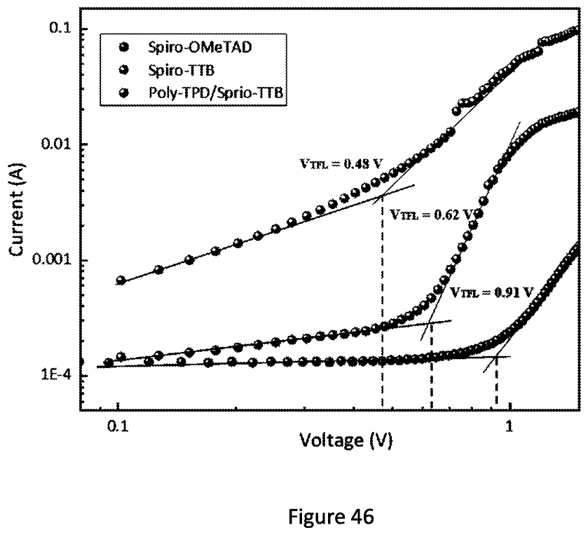

The poly-TPD coated perovskite film exhibited a reduced intensity over the C(OH₃) peak at 289 eV and NOx peak at 403 eV (see FIGS. 33A and 33B). In addition, from the space charge limited current (SCLC) measurement, poly-TPD/Spiro-TTB contributed to the lowest trap-filled limited voltage (V_{TFL}) of 0.48 V (See FIG. 46) as compared to the 0.62 V for Spiro-TTB based device and 0.91V for Spiro-OMeTAD based device, which indicates the lowest trap-state density.

To investigate causes of the experimentally observed improvement in FF and V_{oc}, simulations of the impact of changing HTL ionization potential (IP) on a wide-bandgap perovskite solar cell were performed using COMSOL Multiphysics v6.1.

Details of the model can be found in the following publications:
1. A. Jacobs et al., Journal of Applied Physics. 124, 225702 (2018).
2. D. Walter et al., J. Phys. Chem. C. 122, 11270-11281 (2018).

Simulation parameters are provided in Table 6 below:

TABLE 6
Models for simulation of impact of changing HTL
Ionization potential

| Parameter | Value [unit] | |
|---|---|---|
| Hole Transport Layer | | |
| Relative Permittivity | 3 | |
| Band Gap | 3 | V |
| Electron Affinity | Variable, see text | |
| Effective density of states, valence band | 10²⁰ | cm⁻³ |
| Effective density of states, conduction band | 10²⁰ | cm⁻³ |
| Electron mobility | 0.01 | cm²/Vs |
| Hole mobility | 0.01 | cm²/Vs |
| Dopant defect concentration (p-type) | 1017 | cm⁻³ |
| Thickness | 50 | nm |
| Electron Transport Layer | | |
| Relative Permittivity | 24 | |
| Band Gap | 3.2 | |
| Electron Affinity | 3.9 | V |
| Effective density of states, valence band | 10²⁰ | cm⁻³ |
| Effective density of states, conduction band | 10²⁰ | cm⁻³ |
| Electron mobility | 0.1 | cm²/Vs |
| Hole mobility | 0.01 | cm²/Vs |
| Dopant defect concentration (n-type) | 10¹⁵ | cm⁻³ |
| Thickness | 50 | nm |
| Perovskite Layer | | |
| Relative Permittivity | 64 | |
| Band Gap | 1.68 | V |
| Electron affinity | 4 | V |
| Effective density of states, valence band | 10¹⁹ | cm⁻³ |
| Effective density of states, conduction band | 10¹⁹ | cm⁻³ |
| Electron mobility | 10 | cm²/Vs |
| Hole mobility | 10 | cm²/Vs |
| Direct recombination coefficient | 5.3 × 10⁻¹¹ | cm³/s |
| Photocurrent density, when illu minated | 20.2 | mA/cm² |
| Thickness | 400 | nm |
| Cation Concentration | 10¹⁶ | cm⁻³ |
| Anion Concentration | 10¹⁶ | cm⁻³ |
| Cation Diffusivity | 10⁻⁸ | cm²/s |
| Anion Diffusivity | 10⁻¹¹ | cm²/s |
| Bulk midgap defect density | 0.5 × 10¹⁵ | cm⁻³ |
| HTL Interface defect density | 0.10⁷ | cm⁻² |
| TCO Layer | | |
| Relative Permittivity | 4 | |
| Band Gap | 4 | V |
| Electron affinity | 4.3 | V |
| Effective density of states, valence band | 10¹⁹ | cm⁻³ |
| Effective density of states, conduction band | 10¹⁹ | cm⁻³ |
| Electron mobility | 5 | cm²/Vs |
| Hole mobility | 1 | cm²/Vs |
| Thickness | 130 | nm |
| Dopant defect concentration (n-type) | 10²⁰ | cm⁻³ |

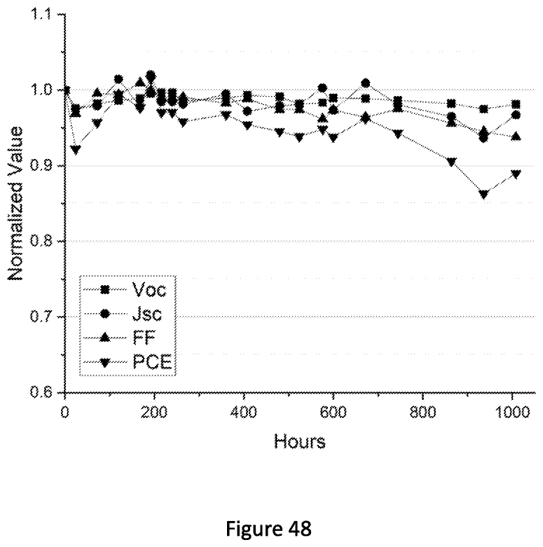

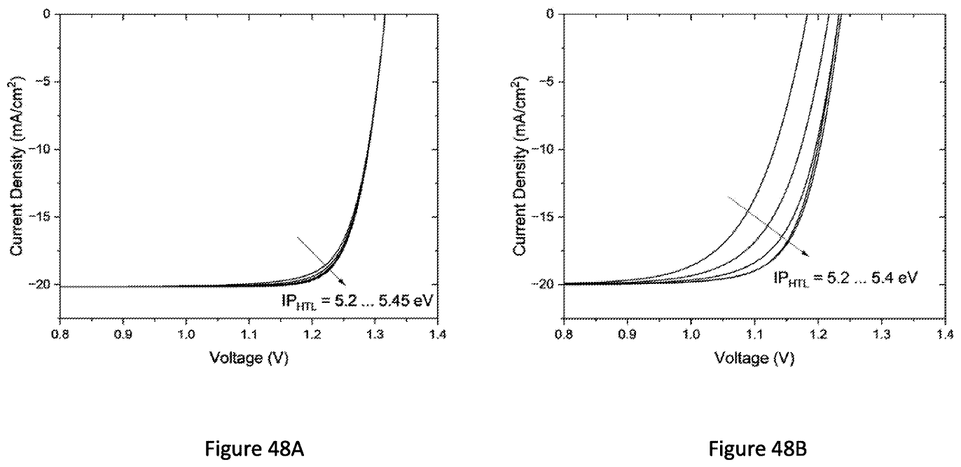

The impact of ionization energy (or, deeper LUMO) was considered in isolation. It was observed that an increasing magnitude of IP can improve both V_{oc} and FF by reducing non-radiative interface recombination and improving hole conductivity on the perovskite side of the interface, all other factors being equal. Using device parameters listed in Table 6 an increase in V_{oc} of ˜15 mV and in FF of ˜4 percentage points was simulated as the HTL IP increases in magnitude from −5.25 to −5.40 eV (see FIG. 48B). This accords with the experimental improvement (see FIG. 27). By comparison, simulations with zero recombination-active defects predict zero voltage and only ˜1% FF gain from this magnitude of change in the HTL LUMO (see FIG. 48A).

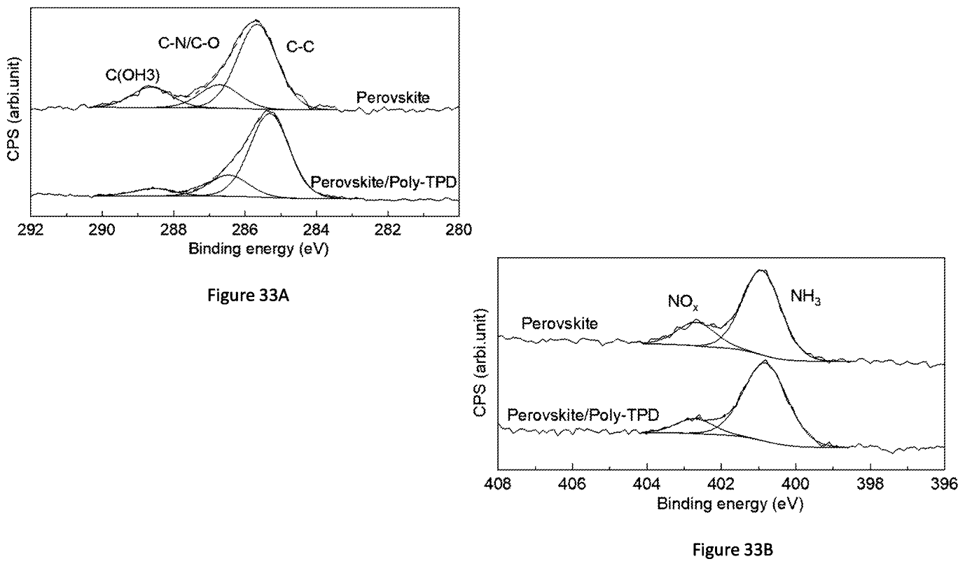

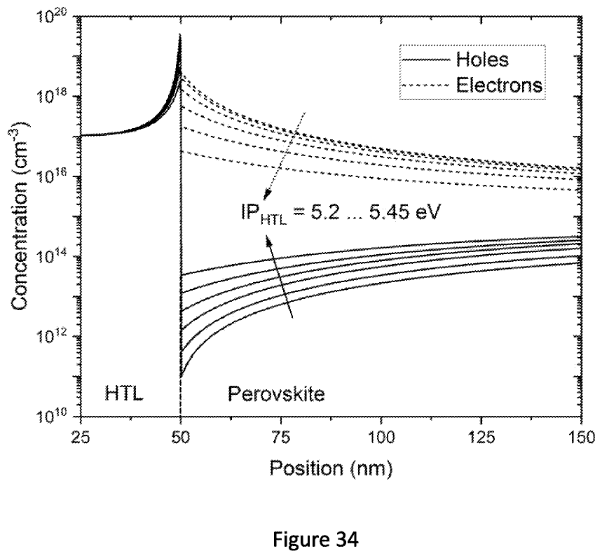

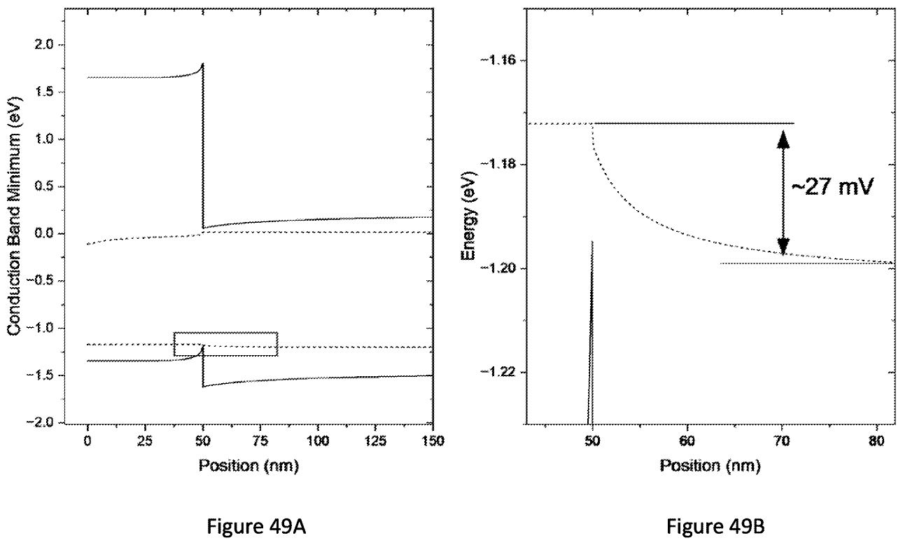

Both the improvement in near interface perovskite hole conductivity and reduction in non-radiative HTL interface recombination are considered consequences of the equilibrium electrostatic conditions at the perovskite-HTL interface. A smaller IP results in a shallower HTL work function (other factors being equal). In turn, this increases the equilibrium electron concentration and decreases the hole concentration at the perovskite side of the HTL interface (see FIG. 34). From the perspective of interface recombination, holes are supplied from both from the HTL and the perovskite bulk, with the former dominating. Thus, it is availability of electrons that determines the interface recombination rate (see FIGS. 49A and 49B) At open circuit, increased interface recombination at IP=5.25 eV reduces the quasi-Fermi level separation in the perovskite bulk, which can account for roughly half of the simulated voltage difference (-7 mV). A roughly equal contribution may come from bending of the quasi-Fermi level for holes due to transport resistance to the hole recombination current. This mechanism may explain the disconnect between transient changes open-circuit voltage and luminescence intensity in perovskite solar cells.

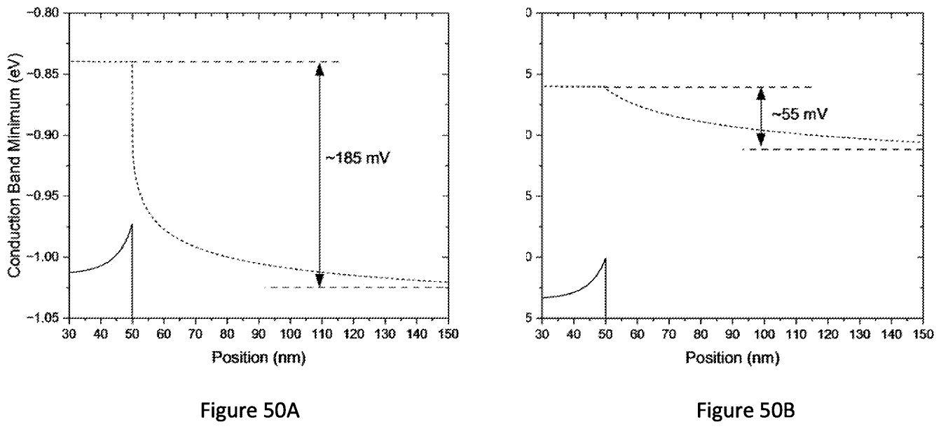

Fill factor improvements may likewise be explained by reduced interface recombination and improved perovskite hole conductivity at the HTL interface. In a device with zero recombination-active defects, hole depletion at the HTL interface introduces a hole transport resistance, which explains the simulated cell voltage difference of ˜27 mV (˜1% FF) at a ˜19 mA/cm² current density that approximates the MPP of both cells (see FIG. 48A) When recombination is introduced to the simulated device, interface recombination further depletes the hole concentration at the HTL interface, increasing transport resistance. A ˜130 mV difference in transport loss at the HTL interface at between IP=5.25 and 5.40 eV at ˜19 mA/cm²) results (see FIGS. 50A and 50B). To summarise, the equilibrium electrostatics of the perovskite/Poly-TPD interface, for which the work function difference between the two layers is lower, may favour an accumulation of electron and hole charge that reduces interface-recombination losses and improves hole conductivity at the near HTL-interface region of the perovskite absorber. The magnitude of the improvements appears to depend primarily on suppressing non-radiative recombination but is still present, to a lesser extent, in a defect-free PSC.

### Example 15—Tandem Cell Performance

Sample were prepared in accordance with Example 9, using a 0.5 mg/mL poly-TPD precursor to form the protective layer 24.

This sample was encapsulated using the glass-to-glass edge-sealing method. The perovskite solar cells were sandwiched between two pieces of glass and sealed at the edges with polyisobutene (PIB). In particular, the testing perovskite solar cell was placed in a glove box. Electrodes based on conductive copper tape are attached via copper-tin cable. The perovskite solar cell is then sandwiched between two pieces of glass and the edges were sealed using PIB by heating and pressing using a custom-made pressure tool. The solar cell was heated to 95° C. and continuously pressed to ensure the PIB to be sealed effectively.

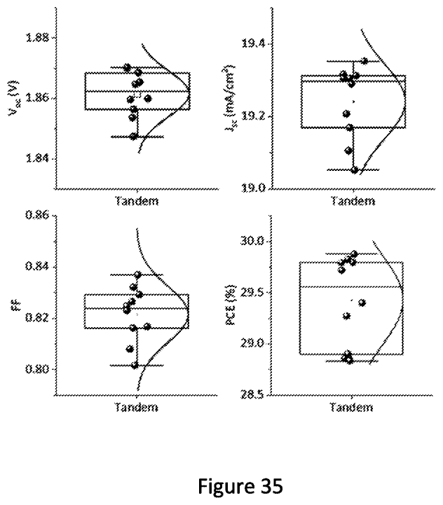

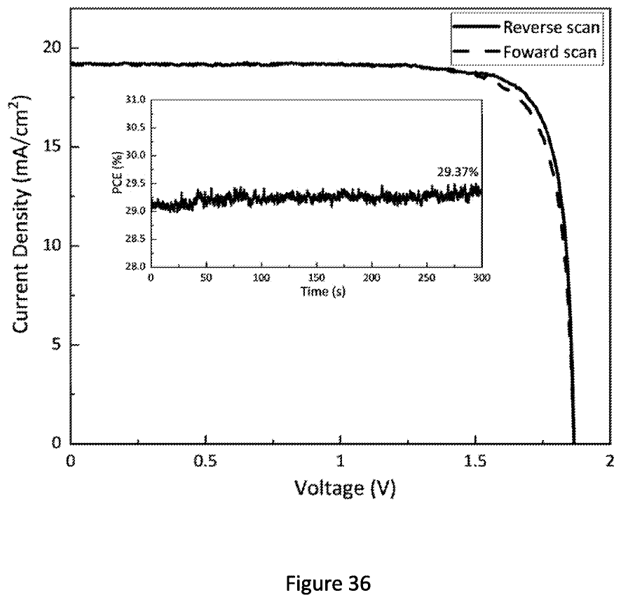

Statistical analysis of PV parameters indicated that the average V_{oc}, J_{sc}, FF, and PCE values for the tandem devices are 1.86±0.01 V, 19.24±0.10 mA/cm², 0.82±0.01, and 29.43±0.43%, respectively. The narrow statistical distribution suggests good reproducibility in the device performance (see FIG. 35). The PV parameters extracted from J-V curves (see FIG. 36) of the sample tandem cell yielded V_{c}=1.87 V, a J_{sc}=19.31 mA/cm², FF=0.83, and a PCE=29.88%, and a steady-state efficiency of 29.37% (inset of FIG. 36).

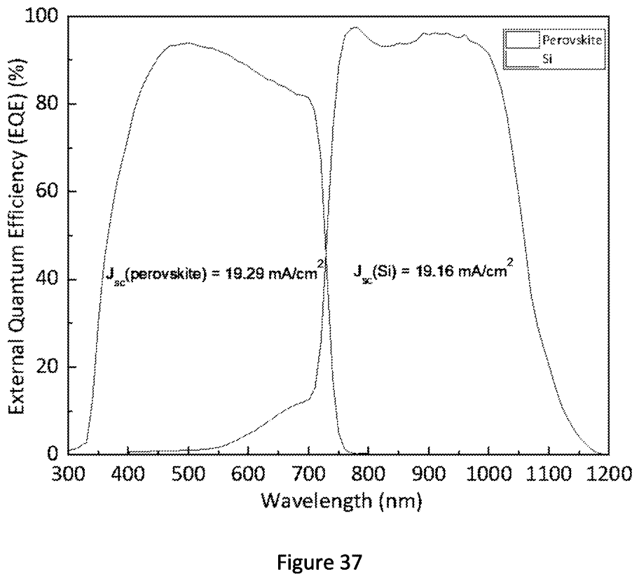

The integrated J_{sc} extracted from External Quantum Efficiency (EQE) for the perovskite top cell and Si bottom cell are 19.29 mA/cm² and 19.16 mA/cm², respectively (see FIG. 37), which agree with the tandem J_{sc} of 19.2 mA/cm² extracted from the J-V curve with a reasonable error, and also indicates a close to current-matching condition in the tandem cell. The high current yield of the n-i-p perovskite/Si TSCs tandem device may be largely attributed to the largely reduced parasitic absorption loss by replacing standard Spiro-OMeTAD layer with ultra-thin Spiro-TTB layer.

### Stability Assessment

Encapsulated tandem solar cell samples (prepared as described above) were subjected to various accelerating conditions for stability measurement. Three different tests conducted on samples:
1. Light-dark cycle test: The modules underwent one cycle, which involved exposing them to a standard sun simulator (AM1.5 G) for 12 hours at 25° C., followed by 12 hours of darkness. This cycle was repeated continuously for over 1000 hours.
2. Damp-heat test: The modules were placed in a humidity/temperature controlling testing chamber, at 85(±2°) C and 85%(±2%) relative humidity. The tandem cells are stored in dark condition.
3. Maximum power point tracking test: The encapsulated cells are exposed to AM1.5 G with 1-Sun illumination at 55(±5° C.) The tandem solar cells are biased at 1V, which is close to its maximum power point.

In order to subject the samples to the conditions above, the samples are placed on a hot plate at controlled temperature using a custom-made controller, fan cooler, and k-type thermocouple. The equipment used for illuminating the solar cells is a sun simulator (Model SS150) from PHOTO EMISSION TECH INC. The temperature and humidity test chamber is C340-40 Wvc Climate test chambers from Weisstechnik®.

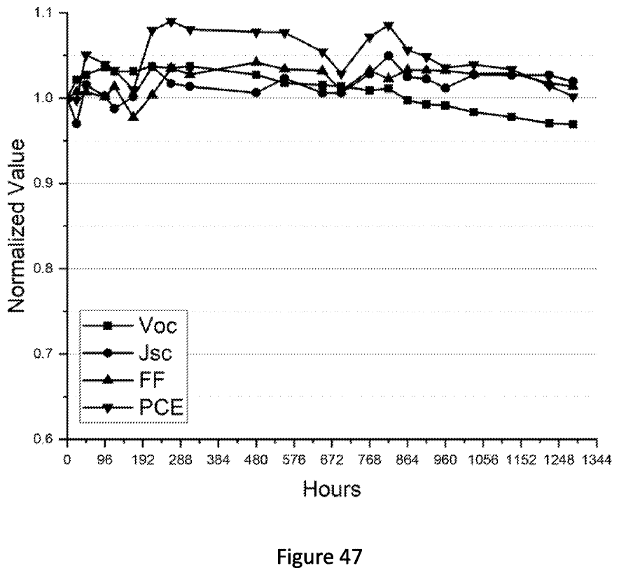

After subjecting samples to light-dark cycle testing (in total over 1000 hours, each cycle consisting of 12 hours of 1-sun illumination followed by 12 hours of storage in the dark), no drop in efficiency was observed (See FIG. 47)

Under damp-heat testing at 85° C. with a relative humidity of 85%, the samples maintained over 95% efficiency for 600 hours and approximately 89% after 1000 hours (See FIG. 48)

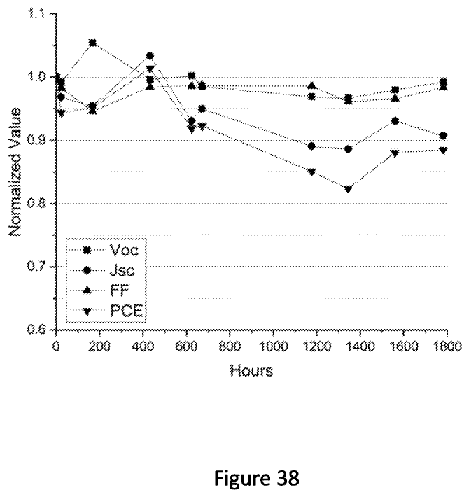

When samples were illuminated under one-sun and biased at a voltage near the maximum power point at 55±5° C. (maximum power point tracking testing), they retained 93% and 89% of their initial PCE after 500 hours and 1782 hours, respectively (as shown in FIG. 38).

### Example 16—Barrier Layer Performance

Barrier layers of various compositions and thicknesses were prepared, in order to assess the effects of these variables on the performance of the barrier layer. Materials including transition metal oxides, TCOs and metal halides were employed, with the barrier layers deposited onto silicon wafers having phosphorus-doped passivating contacts on both surfaces. Contact measurements and steady state photoluminescence (PL) imaging measurements were employed to assess, respectively, the contact properties and the reactivity between the layers adjacent the barrier layer, thereby indicating an aspect of barrier layer performance.

To prepare the silicon wafers, thin SiOₓ layers were grown in etched surfaces in a thermal oxidation step at a temperature of approximately 600° C., thus forming passivation layers 30a, 30b (e.g. as illustrated in FIG. 5 for example). Phosphorus in situ doped polycrystalline silicon layers were deposited on both sides of the cleaned and passivated silicon wafer. Low Pressure Chemical Vapor Deposition (LPCVD) was used to deposit phosphorus in-situ doped polycrystalline silicon, using silane and phosphine as a reactant gas.

The samples were then subjected to an annealing process at a temperature of 900° C. for 30 mins, to active the phosphorus dopants in the polycrystalline silicon layers.

Finally, the wafers were subjected to etching with a 1% HF solution to remove the silicon oxide layer formed during annealing.

To assess the stability of surface passivation with different barrier layers, a series of test structures were fabricated. A sample without any barrier layers (reference sample) was also prepared.

Thin films of TiO₂, LiF, MgF₂ and ZnO:Al were prepared as barrier layers, with each barrier layer partially coated with a ˜200 nm thick Al layer, to create adjacent regions of barrier layer with/without Al metallization. The reference sample (without barrier layers) was also partially coated with ˜200 nm thick Al layer, to create adjacent regions of the sample with/without Al metallization. The impact of the Al layer on the passivation quality of the underlying poly-Si junctions/contacts, with and without either the TiO₂, LiF, MgF₂ or ZnO:Al barrier layers, was examined through PL imaging using a PL imaging tool, such as a BT imaging LIS-R1 tool. PL images were taken before and after cumulative high temperature annealing steps at 400° C. for 20 mins followed by 500° C. for 20 mins in air.

For the reference samples (without any barrier layers), PL images were taken before and after cumulative high temperature annealing steps at 400° C. and 500° C. for 20 mins in air, as illustrated in FIGS. 60A and B, where the areas coated with ˜200 nm thick Al layer are indicated by dashed outline. Based on their PL images, it has been shown that there was no significant passivation degradation in the as deposited state. At the 400° C. step, the Al covered regions showed some passivation degradation, based on the different PL counts between Al covered region (low counts) and non-Al covered region (high counts). After the cumulative 500° C. annealing step, the PL count in the Al covered region dropped significantly. These results suggest that the Al began degrading the passivation quality of polysilicon at 400° C., while the passivation quality displayed significant degradation at 500° C.

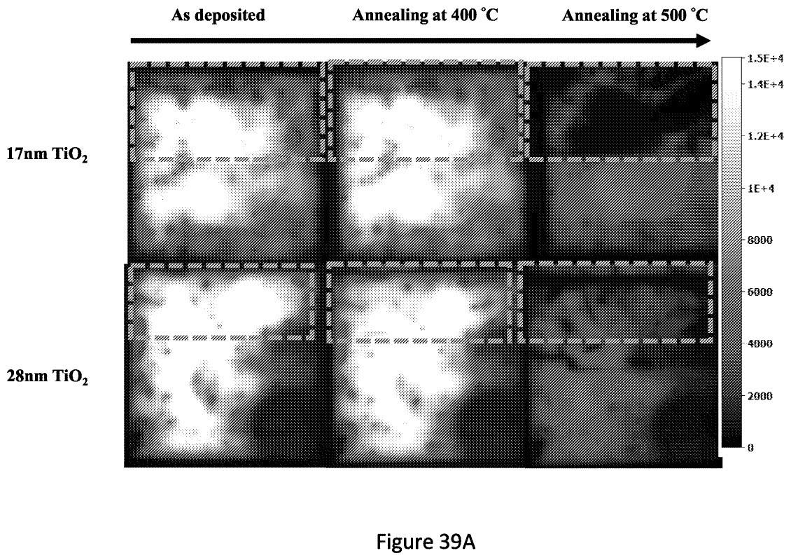

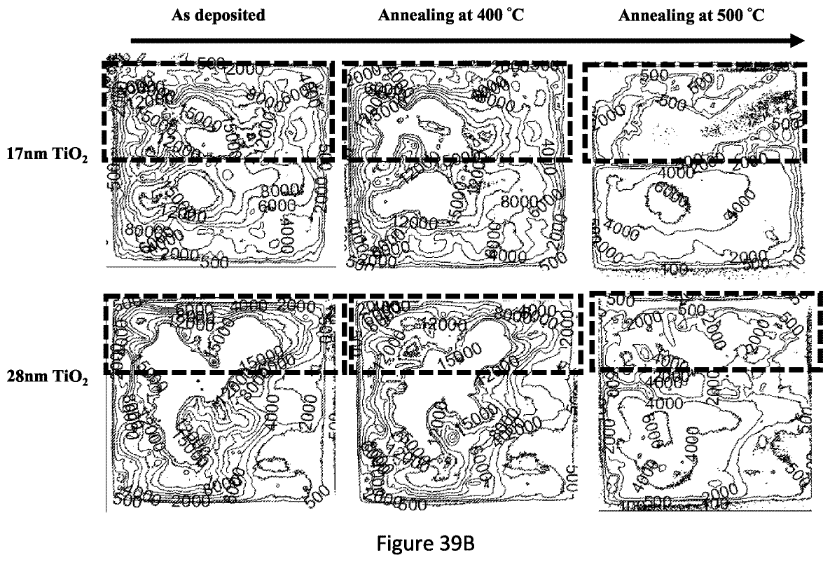

Similarity between PL counts for the Al coated and non-Al coated regions of the barrier layers, indicated limited or no passivation degradation (i.e. no significant interaction between the Al and the Si substrate). This indicates that the introduced layer works effectively as a barrier layer. A difference of PL intensity within 20%, is within the uncertainty range caused by non-uniformity of the samples and can be considered as not significant. Some degradation in passivation of the polysilicon layer is to be expected, with increasing annealing temperature. This degradation occurs independent of the presence of the metal layer, as demonstrated in the regions of FIGS. 39A and B without the Al layer, where the PL intensity drops as annealing temperature is increased from 400° C. to 500° C. Additional degradation can also occur when metal contacted regions are annealed, such as shown in the Al covered region in the 17 nm TiO₂ case in FIGS. 39A and B, where the PL count drops much more significantly in the Al covered area compared to the non-metal covered area, at 500° C.

### Transition Metal Oxides: (TiO₂)

TiO₂ barrier layers were deposited by thermal ALD using titanium tetrakis isopropoxide (TTIP) and H₂O precursors, at temperatures ranging from 90° C. to 250° C. The general process for ALD deposition is set out in Example 2 above. Two TiO₂ thicknesses, 17 nm and 28 nm, were deposited over the full area of one side of the samples. PL images were then taken before and after cumulative high temperature annealing steps at 400° C. and 500° C. in air (i.e. a 400° C. annealing step, followed by PL imaging, then subsequent annealing of the sample at 500° C.).

FIGS. 39A and 39B illustrate, respectively, PL images and corresponding contour plots, for n-type polycrystalline silicon samples with 17 nm (top row) and 28 nm (bottom row) TiO₂ barrier layers, before and after cumulative annealing steps. Areas coated with ˜200 nm thick Al layer is indicated by dashed outline.

The results indicate that both 17 nm and 28 nm thick TiO₂ are effective barrier layers for annealing temperatures up to 400° C. 17 nm TiO₂ is not sufficient to prevent degradation in passivation at 500° C., while 28 nm TiO₂ is partially effective at 500° C.

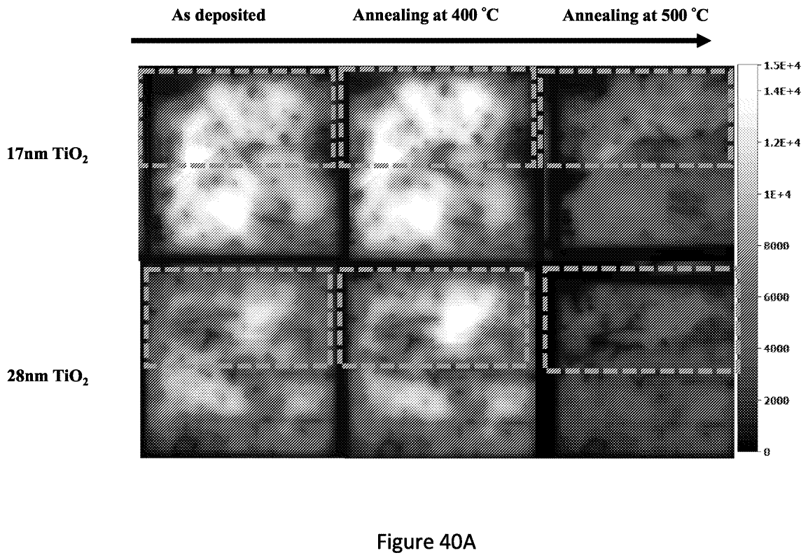

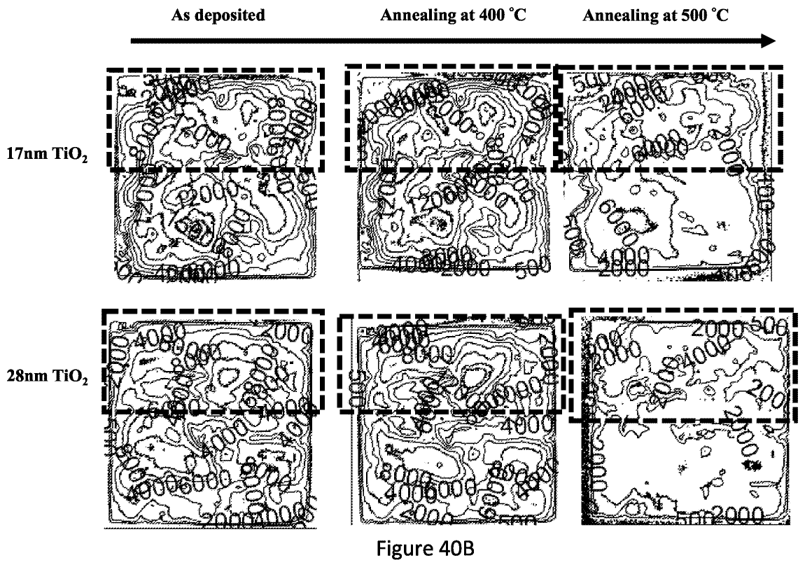

Additional samples were prepared and pre-annealed at 450° C. for 20 mins, before Al deposition. Following Al deposition, PL images were then taken before and after cumulative high temperature annealing steps at 400° C. and 500° C. in air. FIGS. 40A and 40B illustrate, respectively, PL images and corresponding contour plots, for n-type polycrystalline silicon samples with 17 nm (top row) and 28 nm (bottom row) TiO₂ barrier layers, before and after cumulative annealing steps. Areas coated with ˜200 nm thick Al layer are indicated by dashed line.

The results indicate that both 17 nm and 28 nm TiO₂ with pre-annealing, are effective barrier layers against Al for annealing up to 500° C.

### Transparent Conductive Oxides (TCOs): (ZnO:Al)

Aluminium doped zinc oxide (ZnO:Al or AZO) barrier layers were deposited by the ALD process, using trimethylaluminium (TMA), diethyl zinc (DEZ), and deionized water.

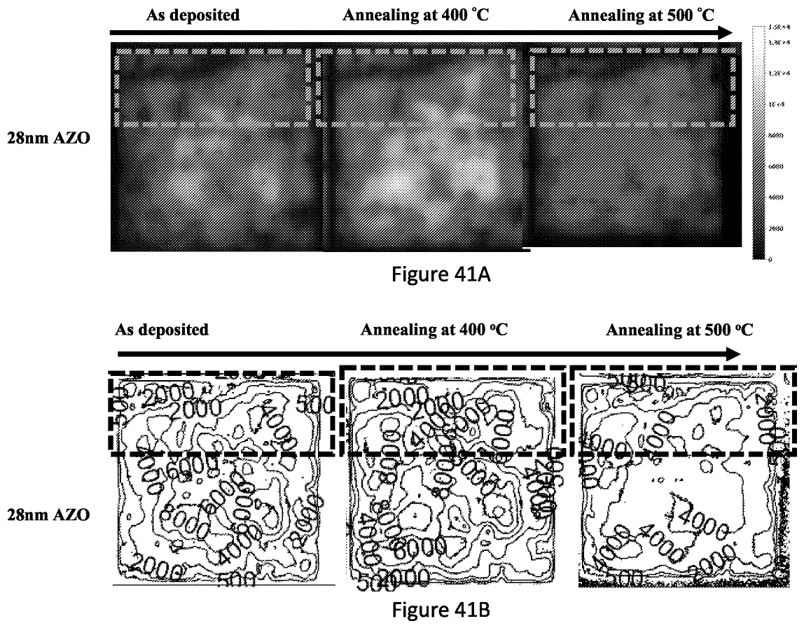

FIGS. 41A and 41B illustrate, respectively, PL images and corresponding contour plots, for n-type polycrystalline silicon samples with 28 nm ZnO:Al barrier layers, before and after cumulative annealing steps. Areas coated with ˜200 nm thick Al layer are indicated by dashed line.

The results indicate that aluminium doped zinc-oxide is an effective barrier layer against Al for annealing up to 500° C.

### Metal Halides: (LiF and MgF₂)

LiF and MgF₂ barrier layers were deposited using thermal evaporation of commercially available LiF (Alfa Aesar, product number 10736) and MgF₂ (Sigma-Aldrich, product number 378836) powders, at base pressure of below 1×10⁻⁶ Torr.

For MgF₂ barrier layers, substrate preparation differed to that outlined above for the other samples. To prepare the silicon wafers for MgF₂ barrier layers, thin SiOₓ layers were grown in etched surfaces by treating the silicon wafers with hot concentrated nitric acid at 90° C. for 30 minutes, thus forming passivation layers 30a, 30b (e.g. as illustrated in FIG. 5 for example). Intrinsic polycrystalline silicon layers were deposited on both sides of the cleaned and passivated silicon wafer. Low Pressure Chemical Vapor Deposition (LPCVD) was used to grow intrinsic polycrystalline silicon using silane as a reactant gas.

Phosphorous doping was performed on both sides of the wafer. The reactant gas employed was a mixture of POCl₃, N₂, and O₂. Oxidation was minimised by switching off O₂ gas after dopant deposition was completed.

Phosphorus thermal diffusion was conducted with a 25 min deposition step at 800° C., followed by a 25 min drive-in step at 870° C.

After doping the phosphorous into the respective polycrystalline silicon layers, the wafers were subjected to a forming gas anneal, using 95% N₂ and 5% H₂, at 425° C. for 30 minutes.

Finally, the wafers were subjected to etching with a 1% HF solution to remove the phosphorous glasses formed during thermal diffusion.

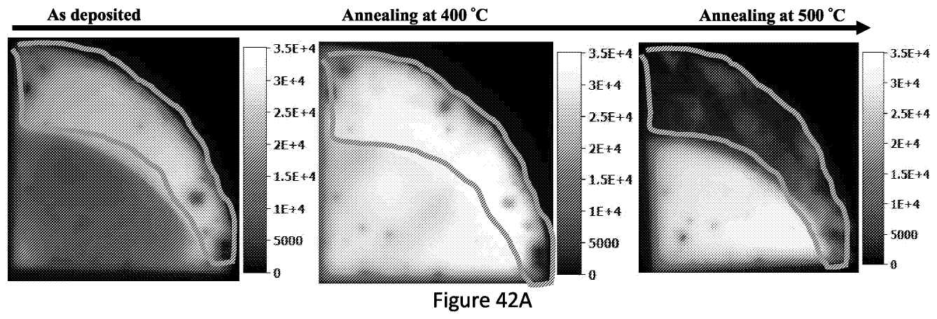

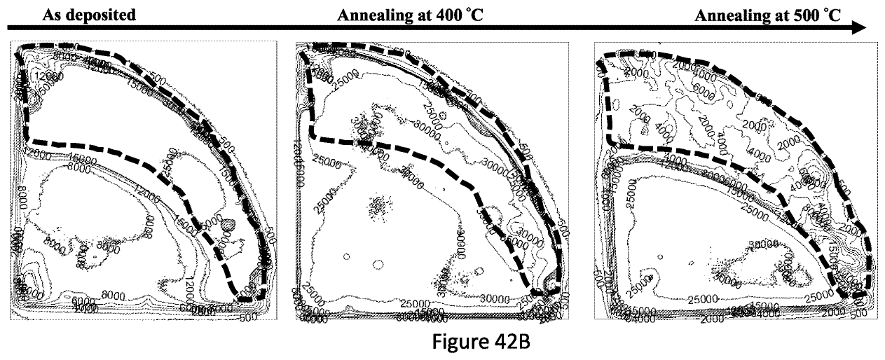

FIGS. 42A and 42B illustrate, respectively, PL images and corresponding contour plots, for n-type polycrystalline silicon samples with 45 nm MgF₂ barrier layers, before and after cumulative annealing steps. Areas coated with ˜200 nm thick Al layer are indicated by dashed outline.

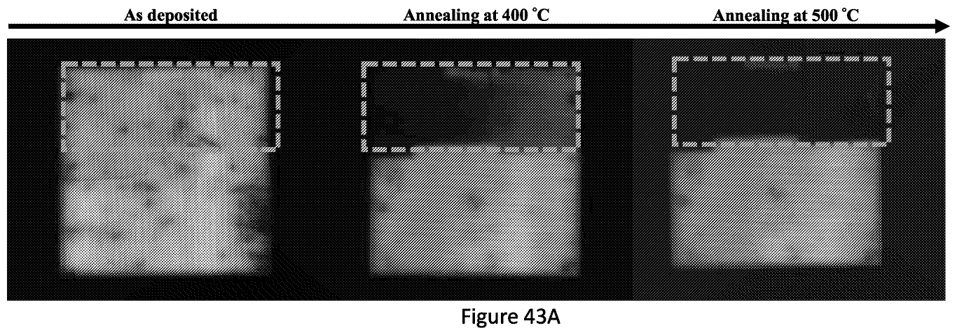

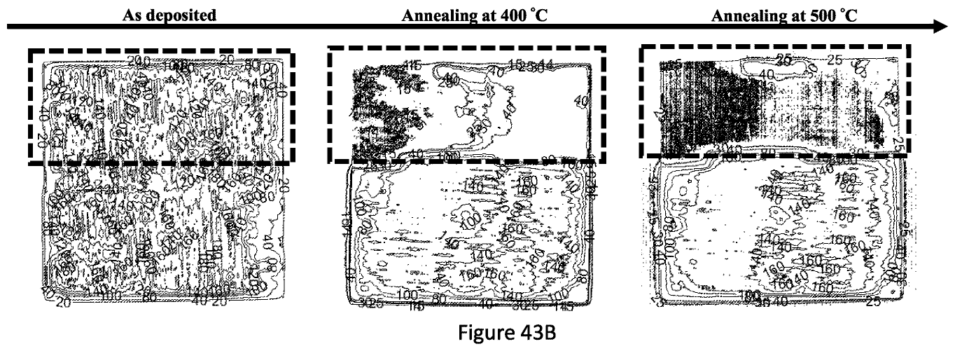

FIGS. 43A and 43B illustrate, respectively, PL images and corresponding contour plots, for n-type polycrystalline silicon samples with 30 nm LiF barrier layers, before and after cumulative annealing steps. Areas coated with ˜200 nm thick Al layer are indicated by dashed outline.

The results indicate 45 nm MgF₂ is an effective barrier layers against Al for annealing up to 400° C., but not for 500° C. The results indicate that for this configuration of cell a 30 nm LiF layer is a less effective barrier layer against Al diffusion after annealing at either 400° C. or 500° C.

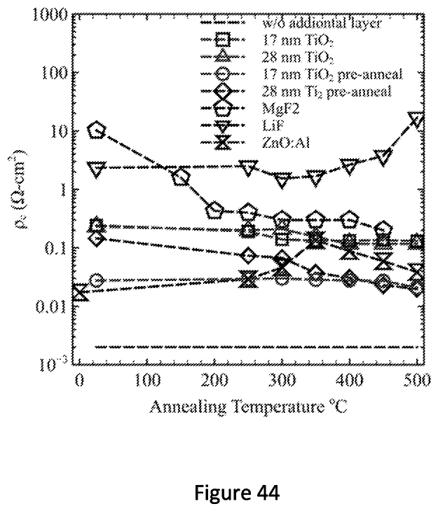

FIG. 44 illustrates contact resistivity p_{c} values of n-type polycrystalline silicon contacts, with and without the various barrier layers, shown as a function of cumulative annealing steps in air.

Effective barrier layers need to protect the poly-silicon layer from degradation when annealed with metal layers (such as Al), but also should contribute as little contact resistivity between the poly-silicon and metal layers as possible. As can be seen from FIG. 44, in the case without a barrier layer contact resistivity is very low, while addition of various barrier layers increases contact resistivity.

The contact resistivity results indicate that each of the barrier layer materials, with the exception of the 30 nm LiF layer, is able to alone provide acceptable electrical contact between the metal and the doped polysilicon layer for this cell configuration. The contact resistivity results of the 30 nm LiF layer are less desirable. However, without being bound by theory, it is believed that LiF may be combined with one or more barrier layer materials (as stacked sublayers) to provide a barrier layer with desirable diffusion barrier properties, resistivity and optical properties. For example, LiF may provide improved characteristics at the interface between the barrier layer and the carrier-selective transport layer when used as combination of LiF and TiO₂ sublayers, with the TiO₂ sublayer disposed between the LiF sublayer and the electrode.

### Example 17—Barrier Layer and Optical Performance

Barrier layers of MgF₂ and TiO₂ at different thicknesses were prepared, in order to assess the effects of these variables on the performance of the barrier layer and the optical performance of the sub-cell.

To prepare the silicon wafers, thin SiOₓ layers were grown in etched surfaces by treating the silicon wafers with hot concentrated nitric acid at 90° C. for 30 minutes, thus forming the passivation layers 30a, 30b as illustrated in FIG. 5 for example. Intrinsic polycrystalline silicon layers were deposited on both sides of the cleaned and passivated silicon wafer. Low Pressure Chemical Vapor Deposition (LPCVD) was used to grow intrinsic polycrystalline silicon using silane as a reactant gas.

Phosphorous doping was performed on both sides of the wafer. The reactant gas employed was a mixture of POCl₃, N₂, and O₂. Oxidation was minimised by switching off O₂ gas after dopant deposition was completed.

Phosphorus thermal diffusion was conducted with a 25 min deposition step at 800° C., followed by a 25 min drive-in step at 870° C.

After doping the phosphorous into the respective polycrystalline silicon layers, the wafers were subjected to a forming gas anneal, using 95% N₂ and 5% H₂, at 425° C. for 30 minutes.

Finally, the wafers were subjected to etching with a 1% HF solution to remove the phosphorous glasses formed during thermal diffusion.

To assess the different barrier layers, a series of test structures were fabricated.

### TiO₂ Barrier Layers

TiO₂ layers were deposited by thermal ALD using titanium tetrachloride and H₂O precursors, at temperatures of 200° C. The general process for ALD deposition is set out in Example 2 above. Multiple TiO₂ thicknesses, at 30 nm, 60 nm, 90 nm, and 120 nm, were deposited over the full area of both sides of the samples. PL images were taken after each step of processing. FIG. 52 shows the average photoluminescence intensity after each process. In FIG. 52, “initial” refers to before HF dip; “HF dipping” refers to after HF dip at 1% for 1 min; “deposition” refers to after deposition of the TiO₂ film, “Al deposition” refers to after deposition of 100 nm of Al using thermal evaporation; and “annealing” refers to after a 400° C. anneal in air for 20 mins.

The average photoluminescence intensity shown in FIG. 52 after each process indicates that TiO₂ of these thicknesses are suitable as barrier layers, with minimal degradation in photoluminescence intensity between Al deposition and after annealing. FIG. 54 shows the contact resistivity ρc values of n-type polycrystalline silicon contacts, with the range of TiO₂ thicknesses, demonstrating that good electrical contact can be achieved for the range of TiO₂ thicknesses used.

In FIG. 54 “before annealing” refers to after deposition of 100 nm of Al using thermal evaporation; and “After annealing” refers to after a 400° C. anneal in air for 20 mins.

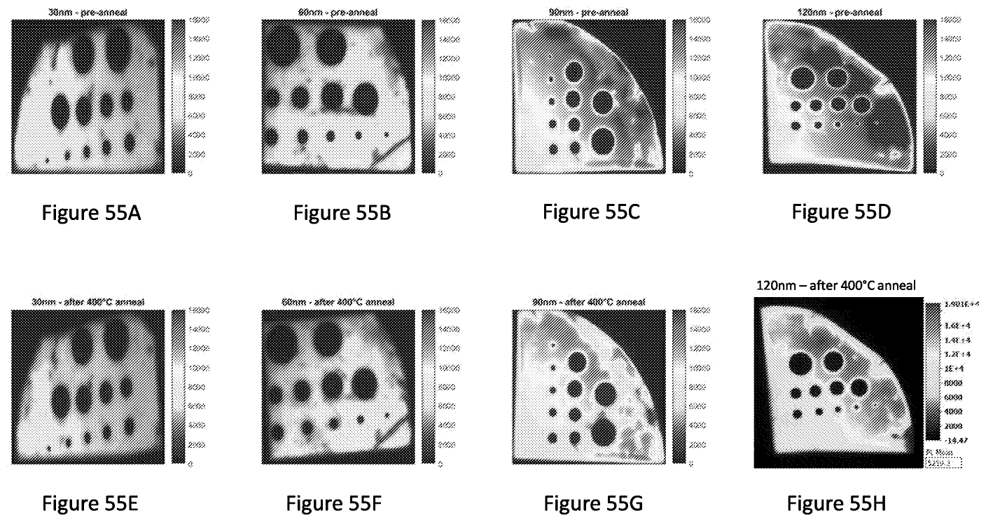

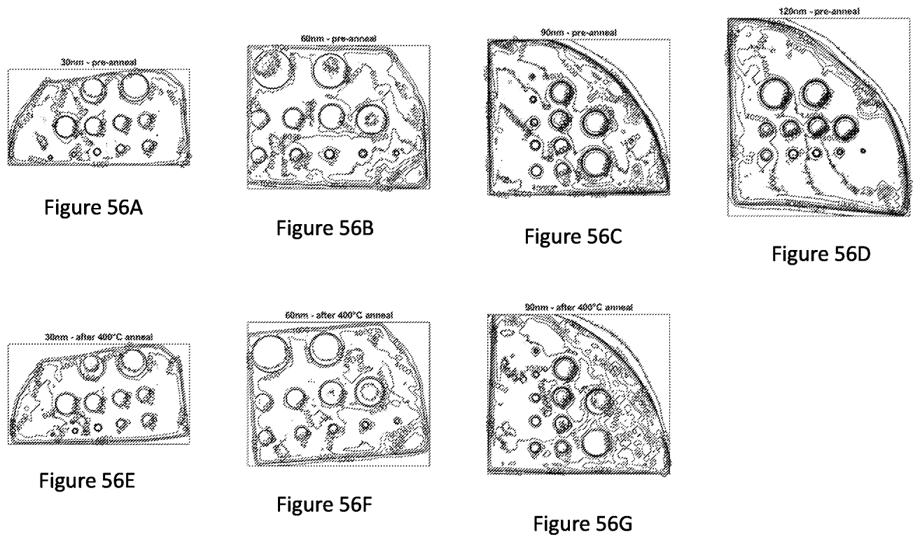

FIGS. 55A, 55B, 55C and 55D show gradient PL images of 30 nm TiO₂ layer, 60 nm TiO₂ layer, 90 nm TiO₂ layer and 120 nm TiO₂ layer samples, respectively, after deposition of 100 nm of Al using thermal evaporation, but before the 400° C. anneal in air for 20 mins, while FIGS. 55E, 55F, 55G, 55H show gradient PL images of 30 nm TiO₂ layer, 60 nm TiO₂ layer, 90 nm TiO₂ layer; and 120 nm TiO₂ layer samples, respectively, after the 400° C. anneal in air for 20 mins. The circular dots are Al covered on the front, while the whole rear surface is Al covered. FIGS. 56A to 56G are contour plots corresponding to FIGS. 55A to 55G, respectively. No corresponding contour plot is provided for FIG. 55H. These results, together this those shown in FIG. 52, indicate that TiO₂ layers of the thicknesses considered are suitable for use as barrier layers, with minimal degradation in photoluminescence intensity between Al deposition and after annealing. In addition, the results shown in FIG. 54 demonstrate that good electrical contact can be achieved for the range of TiO₂ thicknesses used.

### MgF₂ Barrier Layers

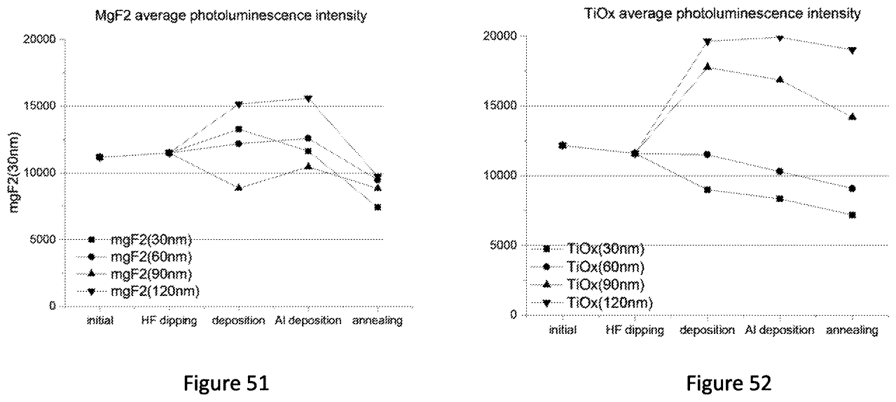

MgF₂ layers were also deposited using the same method as describe above for Example 16. Multiple MgF₂ thicknesses, at 30 nm, 60 nm, 90 nm, and 120 nm, were deposited over the full area of both sides of the samples. PL images were taken after each step of processing. FIG. 51 shows the average photoluminescence intensity after each process. In FIG. 51, “initial” refers to before HF dip; “HF dipping” refers to after HF dip at 1% for 1 min; “deposition” refers to after deposition of the MgF₂ film, “Al deposition” refers to after deposition of 100 nm of Al using thermal evaporation; and “annealing” refers to after a 400° C. anneal in air for 20 mins.

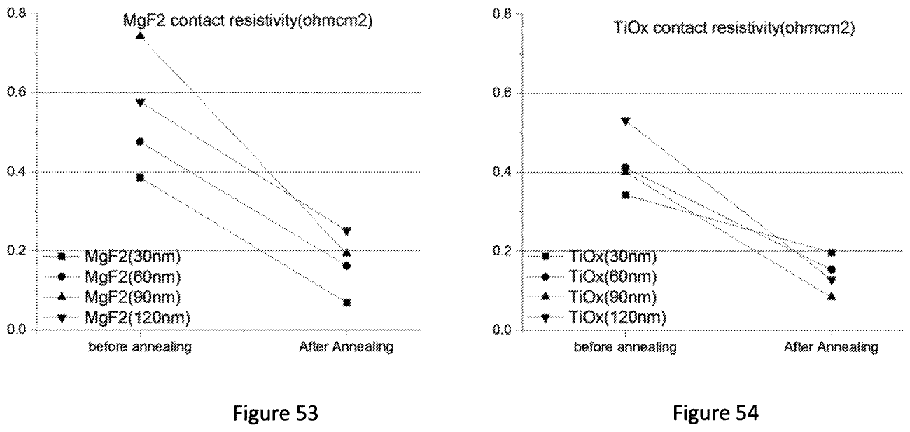

The average photoluminescence intensity shown in FIG. 51 after each process indicates that MgF₂ of these thicknesses are suitable as barrier layers, with some degradation in photoluminescence intensity between Al deposition and after annealing. FIG. 53 shows the contact resistivity ρc values of n-type polycrystalline silicon contacts, with the range of MgF₂ thicknesses, demonstrating that good electrical contact can be achieved for the range of MgF₂ thicknesses used. In FIG. 53 “before annealing” refers to after deposition of 100 nm of Al using thermal evaporation; and “After annealing” refers to after a 400° C. anneal in air for 20 mins.

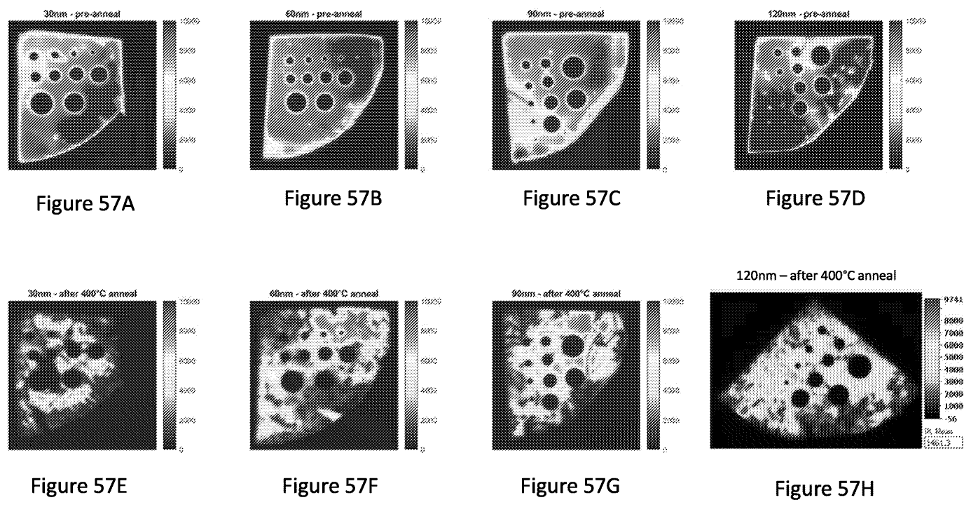

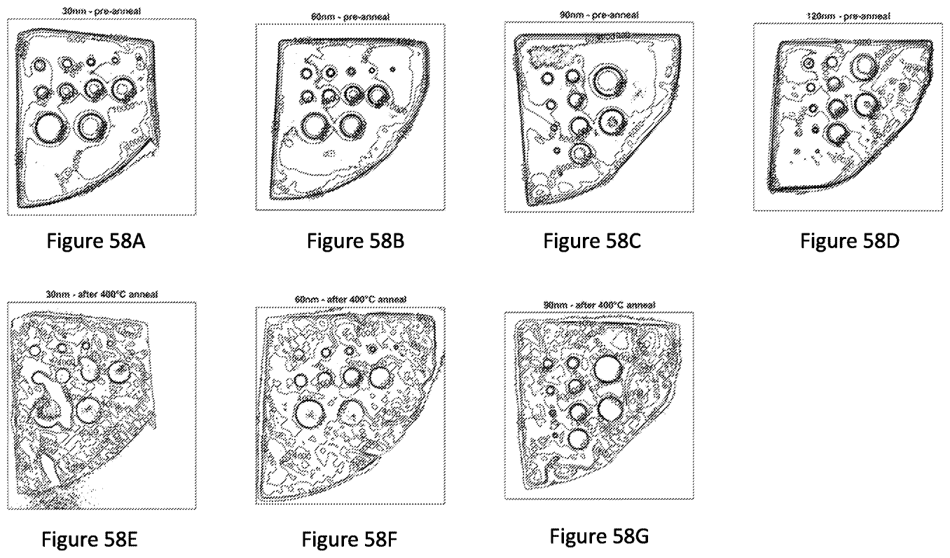

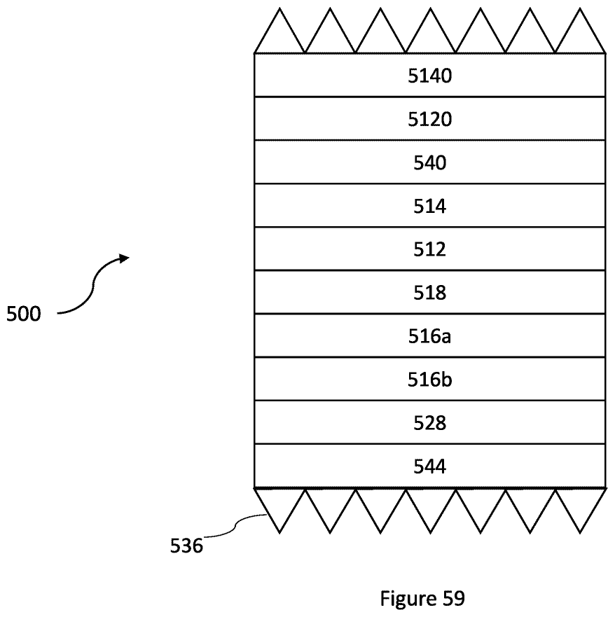

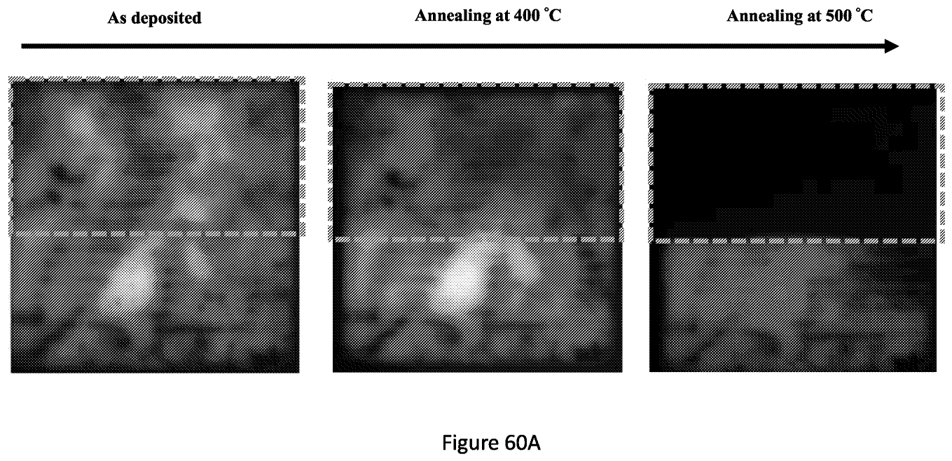

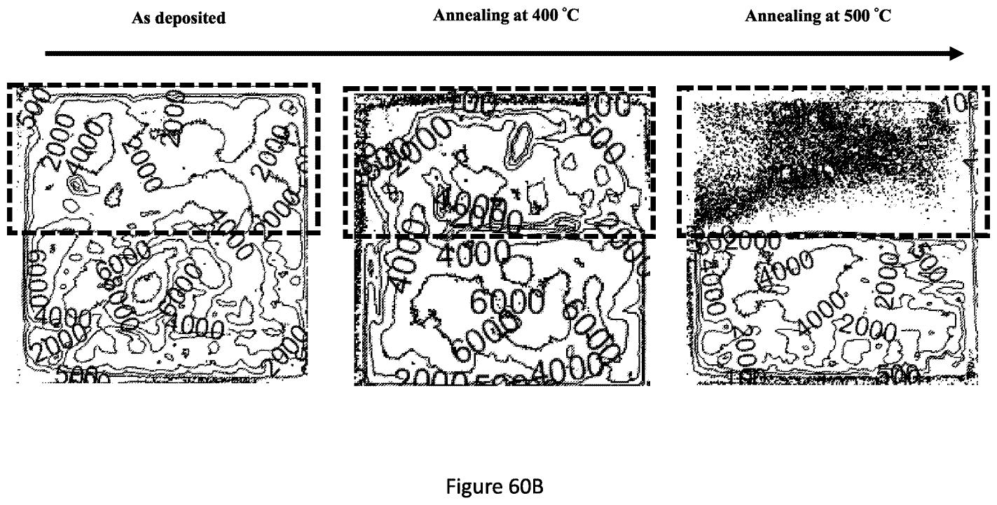

FIGS. 57A, 57B, 57C and 57D show gradient PL images of 30 nm MgF₂ layer, 60 nm MgF₂ layer, 90 nm MgF₂ layer and 120 nm MgF₂ layer samples, respectively, after deposition of 100 nm of Al using thermal evaporation, but before the 400° C. anneal in air for 20 mins, while FIGS. 57E, 57F, 57G, 57H show gradient PL images of 30 nm MgF₂ layer, 60 nm MgF₂ layer, 90 nm MgF₂ layer; and 120 nm MgF₂ layer samples, respectively, after the 400° C. anneal in air for 20 mins. The circular dots are Al covered on the front, while the whole rear surface is Al covered. FIGS. 58A to 58G are contour plots corresponding to FIGS. 57A to 57G, respectively.

No corresponding contour plot is provided for FIG. 57H. These results, together this those shown in FIG. 51, indicate that MgF₂ layers of the thicknesses considered effective as barrier layers, but have some degradation in photoluminescence intensity between Al deposition and after annealing. The results shown in FIG. 53 demonstrate that good electrical contact can be achieved for the range of MgF₂ thicknesses used.

### Example 18—Barrier Layer and Optical Performance

Optical simulation was conducted to assess the effect of barrier layers of TiO₂ or MgF₂ with varying thicknesses upon cell performance. The optical simulation based on the Sunsolve Ray Tracer provided by PV lighthouse.

The simulation utilized a tandem solar cell structure 500 as shown in FIG. 59. The layers of the cell are as set out in Table 7.

TABLE 7
Tandem Solar Cell Structure for Simulation

| Reference Numeral | Layer Structure |
|---|---|
| 5140 | Silicone texturing foil |
| 5120 | 40 nm IZO |
| 540 | 10 nm MoO₃ |
| 514 | 10 nm Spiro-TTB |
| 512 | 240 nm perovskite |
| 518 | 1 nm PCBM |
| 516a | 60 nm mesoporous TiO₂ |
| 516b | 50 nm compact TiO₂ |
| 528 | 350 μm Si |
| 544 | Barrier Layer: TiO₂ or MgF₂- |
| | varying thicknesses as shown in |
| | Tables 8 and 9 |
| 536 | 500 nm aluminium |

The tandem solar cell structure 500 features a planar Si surface coated with a silicon texturing foil. The rear side of the cell uses a texturing structure consisting of pyramids with a height of 3.5 micrometres.

Tables 8 and 9 below presents the optical simulation results obtained using barriers layer of TiO₂ or MgF₂ with varying thicknesses. Key parameters shown in the tables are:
Reflectance loss: the light loss caused by reflection at the surface and interfaces of the solar cell layers.
Absorption (Aluminium): the parasitic absorption loss resulting from the aluminium electrode on the rear side of the cell.
Jsc (perovskite)+Jsc (Si): the combined current density generated by the perovskite subcell and silicon subcell.
Average current density: half of the ‘Jsc (perovskite)+Jsc (Si)’.

TABLE 8
Simulation Results for TiO₂ Barrier Layers

| TiO₂ | | | Jsc | |
|---|---|---|---|---|
| barrier | | | (perovskite) | Average |
| layer | Reflectance | Absorption | + | current |
| thick- | loss | (Aluminium) | Jsc (Si) | density |
| ness | (mAcm⁻²) | (mAcm⁻²) | (mAcm⁻²) | (mAcm⁻²) |
| 10 nm | 2.83 | 2.9 | 38.9 | 19.45 |
| 48 nm | 2.93 | 2.4 | 39.24 | 19.62 |
| 86 nm | 3.02 | 2 | 39.56 | 19.78 |
| 124 nm | 3.13 | 1.77 | 39.67 | 19.84 |
| 162 nm | 3.12 | 1.7 | 39.73 | 19.9 |
| 200 nm | 3.12 | 1.78 | 38.67 | 19.34 |

TABLE 9
Simulation Results for MgF₂ Barrier Layers

| MgF₂ | | | Jsc | |
|---|---|---|---|---|
| barrier | | | (perovskite) | Average |
| layer | Reflectance | Absorption | + | current |
| thick- | loss | (Aluminium) | Jsc (Si) | density |
| ness | (mAcm⁻²) | (mAcm⁻²) | (mAcm⁻²) | (mAcm⁻²) |
| 10 nm | 2.89 | 2.3 | 39.1 | 19.55 |
| 48 nm | 3.15 | 1.18 | 39.8 | 19.9 |
| 86 nm | 3.28 | 1.19 | 40.12 | 20.06 |
| 124 nm | 3.34 | 0.55 | 40.12 | 20.06 |
| 162 nm | 3.37 | 0.43 | 40.15 | 20.1 |
| 200 nm | 3.38 | 0.38 | 40.15 | 20.1 |

The simulation results indicate that increasing the thickness of the barrier layer, such as TiO₂ or MgF₂, results in an improvement in optical enhancement and overall current density yield. This can be observed from the value of the ‘Average current density’. The results indicate there is an optimum thickness for optical enhancement, beyond which further increases would actually decrease the current.

For example, Table 8 shows an optimum around 162 nm, with current decreasing with further decrease to 200 nm.

Variations and modifications may be made to the parts previously described without departing from the spirit or ambit of the disclosure.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

It is to be understood that, if any prior art is referred to herein, such reference does not constitute an admission that the prior art forms a part of the common general knowledge in the art, in Australia or any other country.

1. A photovoltaic cell, comprising:
an absorber layer comprising a perovskite material; and
an ultrathin hole-transport layer.

2. A photovoltaic cell according to claim 1, comprising, in order relative to incident light said cell is configured to receive:
a first carrier-selective transport layer;
the absorber layer comprising a perovskite material; and
a second carrier-selective transport layer;
wherein one of the first carrier-selective transport layer or the second carrier-selective transport layer is an ultrathin hole-transport layer.

3. A photovoltaic cell according to claim 1 or 2, wherein said cell is a tandem photovoltaic cell comprising, in order relative to incident light said cell is configured to receive:
a first sub-cell; and
a second sub-cell;
said first sub-cell comprising:
the absorber layer; and
the ultrathin hole-transport layer.

4. A photovoltaic cell according to claim 3 when dependent from claim 2, comprising an interconnecting layer between the second carrier-selective transport layer and the second sub-cell.

5. A photovoltaic cell according to claim 3 when dependent from claim 2, wherein the second carrier-selective transport layer directly contacts the second sub-cell.

6. A photovoltaic cell according to any one of the preceding claims, wherein the ultrathin hole-transport layer has a thickness of less than 100 nm.

7. A photovoltaic cell according to any one of the preceding claims, wherein the ultrathin hole-transport layer has a thickness of less than 50 nm.

8. A photovoltaic cell according to any one of the preceding claims, wherein the ultrathin hole-transport layer has a thickness between about 5 nm and about 35 nm.

9. A photovoltaic cell according to any one of the preceding claims, wherein the ultrathin hole-transport layer has a thickness between about 5 nm and about 25 nm.

10. A photovoltaic cell according to any one of claims 6 to 9, wherein the ultrathin hole-transport layer has a thickness greater than the largest contour interval in surface roughness of a layer underlying the ultrathin hole-transport layer.

11. A photovoltaic cell according to any one of the preceding claims, wherein the hole-transport layer comprises a material selected from the group consisting of: (2,2′,7,7′-Tetra(N,N-di-p-tolyl)amino-9,9-spirobifluorene) (Spiro-TTB); Poly[bis(4-phenyl)(2,4,6-trimethylphenyl)amine](PTAA), Poly(3-hexylthiophene-2,5-diyl) (P3HT); Poly [[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]](PTB7); Poly[(2,6-(4,8-bis(5-(2-ethylhexyl-3-fluoro)thiophen-2-yl)-benzo[1,2-b:4,5-b′]dithiophene))-alt-5,5′-(5,8-bis(4-(2-butyloctyl)thiophen-2-yl)dithieno[3′,2′:3,4;2″,3″:5,6]benzo[1,2-c][1,2,5]thiadiazole)](D18); Poly[(2,6-(4,8-bis(5-(2-ethylhexyl)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5‘-c’]dithiophene-4,8-dione)](PBDB-T); Poly[(5,6-difluoro-2,1,3-benzothiadiazol-4,7-diyl)-alt-(3,3′″-di(2-octyldodecyl)-2,2′;5′,2″;5″,2′″-quaterthiophen-5,5′″-diyl)](PffBT4T-2OD); Tris(8-hydroxyquinoline)aluminium (Alq3); 2,4,5,6-Tetra(9H-carbazol-9-yl)isophthalonitrile (4CzIPN); Tris[2-phenylpyridine]iridium(III) (Ir(ppy)3); F2Irpic, Ir(diFppy)2(pic) (FIrPic); 2,5,8,11-Tetrakis(1,1-dimethylethyl)perylene; 2,5,8,11-Tetra-tert-butylperylene (TBPe); Bis[2-(2-pyridinyl-N)phenyl-C](acetylacetonato)iridium(III) (Ir(ppy)2(acac)); Tris(1-phenylisoquinoline)iridium(III) (Ir(piq)3); Bis(1-phenylisoquinoline)(acetylacetonate)iridium(III) (Ir(piq)2(acac)); 5,6,11,12-Tetraphenylnaphthacene (Rubrene); 1,2-Bis(carbazol-9-yl)-4,5-dicyanobenzene (2CzPN), Tetraphenyldibenzoperiflanthene; Dibenzo{[f,f′]-4,4′,7,7′-tetraphenyl}diindeno[1,2,3-cd:1′,2′,3′-lm]perylene (DBP); 4-(Dicyanomethylene)-2-tert-butyl-6-(1,1,7,7-tetramethyljulolidin-4-yl-vinyl)-4H-pyran (DCJTB); 2-Methyl-9,10-bis(naphthalen-2-yl)anthracene, 2-Methyl-9,10-di(2-naphthyl)anthracene (MADN); 10-(2-Benzothiazolyl)-2,3,6,7-tetrahydro-1,1,7,7-tetramethyl-1H,5H,11H-(1)benzopyropyrano(6,7-8-I,j)quinolizin-11-one(C545T); Bis[2-(2-quinolinyl)phenyl](2,2,6,6-tetramethyl-3,5-heptanedionato)iridium (Ir(dpm)PQ2); Bis(2-(3,5-dimethylphenyl)quinoline-C2,N′)(acetylacetonato)iridium(III) (Ir(dmpq)2(acac)); Tris(1-phenylpyrazolato)iridium (lr(ppz)3); 2,3,4,5,6-pentakis(3,6-di-tert-butyl-9H-carbazol-9-yl)benzonitrile (5TCzBN); 2,3,5,6-Tetrakis(3,6-di-tert-butyl-9H-carbazol-9-yl)benzonitrile (4TCzBN); 10,10′-[5-(6-[1,1′-biphenyl]-4-yl-2-phenyl-4-pyrimidinyl)-1,3-phenylene]bis[9,10-dihydro-9,9-dimethyl-acridine](DMAC-BPP); N4,N4,N4″,N4″-tetra([1,1′-biphenyl]-4-yl)-[1,1′:4′,1″-terphenyl]-4,4″-diamine (TaTm); N,N′-Di(1-naphthyl)-N,N′-diphenyl-(1,1′-biphenyl)-4,4′-diamine (NBP); 10-(4-(4,6-diphenyl-1,3,5-triazin-2-yl)phenyl)-10H-phenoxazine (PXZ-TRZ); Tris(dibenzoylmethane)phenanthroline europium(III) (Eu(dbm)3(Phen)); 4,4′-(Diphenylsilanediyl)bis(N,N-diphenylaniline) (TSBPA); 9,9′,9″-(5-(4,6-Diphenyl-1,3,5-triazin-2-yl)benzene-1,2,3-triyl) tris(9H-carbazole) (TCzTRZ); and 9,9′,9″-(5-(4,6-Diphenyl-1,3,5-triazin-2-yl)benzene-1,2,3-triyl) tris(3,6-dimethyl-9H-carbazole) (TmCzTRZ).

12. A photovoltaic cell according to claim 11, wherein the hole-transport layer comprises a material selected from the group consisting of: Spiro-TTB; PTAA; D18; TaTm; and NBP.

13. A photovoltaic cell according to any one of the preceding claims, comprising a passivating layer between the ultrathin hole-transport layer and the absorber layer.

14. A photovoltaic cell according to claim 13, wherein the passivating layer comprises a material selected from the group consisting of: polymethyl methacrylate (PMMA); n-Octylammonium Bromide (OABr); octylammonium iodide (OAI); octylammonium chloride (OACl); butylammonium iodide; butylammo-nium bromide; and phenethylammonium iodide (PEAI).

15. A photovoltaic cell, comprising:
an absorber layer comprising a perovskite material, said absorber layer having a valence band with a first energy level;
a hole-transport layer, said hole-transport layer having a valence band with a second energy level; and
a protective layer located between the absorber layer and the hole-transport layer, said protective layer having a valence band with an energy level that is between the first and second energy levels.

16. A photovoltaic cell according to claim 15 and comprising, in order relative to incident light said cell is configured to receive:
a first carrier-selective transport layer;
the absorber layer; and
a second carrier-selective transport layer;
wherein one of the first carrier-selective transport layer or the second carrier-selective transport layer is the hole-transport layer.

17. A photovoltaic cell according to claim 15 or 16, wherein said cell is a tandem photovoltaic cell comprising, in order relative to incident light said cell is configured to receive:
a first sub-cell; and
a second sub-cell;
said first sub-cell comprising:
the absorber layer;
the hole-transport layer; and
the protective layer.

18. A photovoltaic cell according to claim 17 when dependent from claim 16, comprising an interconnecting layer between the second carrier-selective transport layer and the second sub-cell.

19. A photovoltaic cell according to claim 17 when dependent from claim 16,
wherein the second carrier-selective transport layer directly contacts the second sub-cell.

20. A photovoltaic cell according to any one of claims 15 to 19, wherein the protective layer comprises a material selected from the group consisting of Poly(N,N′-bis-4-butylphenyl-N,N′-bisphenyl)benzidine (Poly-TPD), N,N′-Bis(naphthalen-1-yl)-N,N′-bis(phenyl)-2,2′-dimethylbenzidine (α-NPD), N,N′-Bis(3-methylphenyl)-N,N′-diphenylbenzidine (TPD).

21. A photovoltaic cell according to claim 20, wherein the protective layer comprises poly-TPD.

22. A photovoltaic cell according to claim 21, wherein the wherein the weight average molecular weight of the poly-TPD greater than 100 kDa.

23. A photovoltaic cell according to claim 21 or 22, wherein the weight average molecular weight of the poly-TPD is in the range of 100 kDa to 500 kDa.

24. A photovoltaic cell according to any one of claims 15 to 23, comprising a passivating layer between the hole-transport layer and the absorber layer.

25. A photovoltaic cell according to claim 24, wherein the passivating layer comprises a material selected from the group consisting of: polymethyl methacrylate (PMMA); n-Octylammonium Bromide (OABr); octylammonium iodide (OAI); octylammonium chloride (OACl); butylammonium iodide; butylammo-nium bromide; and phenethylammonium iodide (PEAI).

26. A photovoltaic cell according to any one of claims 15 to 25, wherein the hole-transport layer is an ultrathin hole-transport layer such that said photovoltaic cell is a photovoltaic cell in accordance with any one of claims 1 to 10.

27. A photovoltaic cell according to: claim 2 or any one of claims 3 to 12 when dependent from claim 2; or claim 16 or any one of claims 17 to 26 when dependent from claim 16, wherein the first carrier-selective transport layer is the hole-transport layer and the second carrier-selective transport layer is the electron-transport layer.

28. A photovoltaic cell according to: claim 2 or any one of claims 3 to 12 when dependent from claim 2; or claim 16 or any one of claims 17 to 26 when dependent from claim 16, wherein the first carrier-selective transport layer is the electron-transport layer and the second carrier-selective transport layer is the hole-transport layer.

29. A photovoltaic cell according to claim 27 or 28, comprising, in order relative to incident light said cell is configured to receive:
a transparent conductor layer on top of the second carrier-selective transport layer; and
a buffer layer between the second carrier-selective transport layer and the transparent conductor layer.

30. A photovoltaic cell according to claim 29 when dependent from 27, wherein the buffer layer comprises MoO₃, WO₃, V₂O₅, SnO₂, or TiO₂.

31. A photovoltaic cell according to claim 29 when dependent from 28, wherein the buffer layer comprises SnO₂, TiO₂, ZnO.

32. A photovoltaic cell according to any one of the preceding claims, wherein the perovskite material comprises a compound of formula (I):
ABX3 (I),
wherein:
A is a cation selected from a group consisting of: methyl ammonium (MA), formamidinium (FA), Cs, or Rb or any combination thereof;
B is a metal cation, Pb; and
X is a halide anion selected from a group consisting of Br, Cl and I so that the ratio of Br:I is in the range of 0:1 to 1:0.

33. A photovoltaic cell according to claim 32, wherein the ratio of Br:I is in the range of 0:1 to 1:1.

34. A photovoltaic cell according to claim 32 or 33, wherein A comprises one or more cations selected so that the molar percentage of A being: formamidinium ranges from 0% to 100%; methyl ammonium ranges from 0% to 100%; Cs ranges from 0% to 30%; and Rb ranges from 0% to 30%.

35. A photovoltaic cell according to claim 32, 33 or 34, wherein the perovskite material is Cs_{0.05}Rb_{0.05}FA_{0.765}MA_{0.135}PbI_{2.55}Br_{0.45}, Cs_{0.1}FA_{0.765}MA_{0.135}PbI_{2.4}Br_{0.6}, Cs_{0.1}FA_{0.765}MA_{0.135}PbI_{2.22}Br_{0.78}, or Cs_{0.1}FA_{0.765}MA_{0.135}PbIBr or Cs_{0.1} Rb_{0.05}FA_{0.765}MA_{0.135}PbI_{2.22}Br_{0.78}Cl_{0.015}.

36. A photovoltaic cell, comprising:
inner layers including:
a lower carrier-selective transport layer;
a crystalline silicon substrate; and
an upper carrier-selective transport layer;
at least one barrier layer; and
an electrode;
wherein said barrier layer is located between the inner layers and the electrode and is configured to suppress diffusion of metal from the electrode into the inner layers.

37. A photovoltaic cell according to claim 36, comprising:
an upper electrode;
the inner layers; and
a lower electrode;
wherein one of said at least one barrier layer is located between either or each of:
the inner layers and the upper electrode and
the inner layers and the lower electrode.

38. A photovoltaic cell according to claim 36, wherein said cell is a tandem photovoltaic cell comprising, in order relative to incident light said cell is configured to receive:
a first sub-cell;
a second sub-cell, said second sub-cell comprising the inner layers;
the at least one barrier layer; and
the electrode,
so that said barrier layer is located between the second sub-cell and the electrode.

39. A photovoltaic cell according to claim 38, said tandem photovoltaic cell being configured such that said photovoltaic cell is a photovoltaic cell in accordance with: claim 3 or any one of claims 4 to 12 when dependent from claim 3; or claim 17 or any one of claims 18 to 35 when dependent from claim 17.

40. A photovoltaic cell according to any one of claims 36 to 39, wherein the barrier layer comprises a material selected from a group consisting of: transition metal oxides, metal halides, transparent conductive oxides, and metal nitrides.

41. A photovoltaic cell according to claim 40, wherein the barrier layer comprises a transition metal oxide selected from a group consisting of: TiO₂, Ta₂O₃, and Ga₂O₃.

42. A photovoltaic cell according to claim 40, wherein the barrier layer comprises a metal halide selected from a group consisting of: LiF and MgF₂.

43. A photovoltaic cell according to claim 40, wherein the barrier layer comprises a metal nitride selected from a group consisting of: TiN and TaN.

44. A photovoltaic cell according to claim 40, wherein the barrier layer is or comprises TiO₂, Ta₂O₃, LiF, MgF₂, TiN, and/or TaN.

45. A photovoltaic cell according to any one of claims 36 to 44, wherein the electrode comprises a metal selected from a group consisting of: Al, Cu and Ag.

46. A photovoltaic cell according to any one of claims 36 to 45, wherein the lower and upper carrier-selective charge transport layers each comprise polycrystalline silicon.

47. A photovoltaic cell according to any one of claims 36 to 46, wherein a passivating layer is located between each of:
the crystalline silicon substrate and the lower carrier-selective transport layer; and
the crystalline silicon substrate and the upper carrier-selective transport layer.

48. A method of fabricating a photovoltaic cell, said cell comprising an absorber layer comprising a perovskite material and an ultrathin hole-transport layer, said method comprising:
depositing the ultrathin hole-transport layer such that said ultrathin hole-transport layer is located above or below the absorber layer in the photovoltaic cell.

49. A method according to claim 48, wherein depositing the ultrathin hole-transport layer comprises a thermal evaporation process.

50. A method according to claim 49, comprising controlling the thickness of the ultra-thin layer deposited, wherein the ultrathin hole-transport layer is deposited at a deposition rate and controlling deposition of the ultrathin hole-transport layer comprises monitoring the deposition rate.

51. A method according to claim 48, 49 or 50, said method comprising:
depositing a bottom electrode layer on a substrate;
depositing a second carrier-selective transport layer on top of the bottom electrode layer;
depositing the absorber layer on top of the second carrier layer; and
depositing a first carrier-selective transport layer on top of the absorber layer;
wherein one of the first carrier-selective transport layer or the second carrier-selective transport layer is the ultrathin hole-transport layer.

52. A method according to claim 48, 49 or 50, wherein said photovoltaic cell is a tandem cell, said method comprising:
providing a second sub-cell,
depositing a first sub-cell on top of the second sub-cell, said first sub-cell comprising: the absorber layer comprising a perovskite material and the ultrathin hole-transport layer.

53. A method according to claim 52, wherein the first sub-cell is deposited directly on top of the second sub-cell.

54. A method according to claim 52, comprising, before depositing the first sub-cell, depositing an interconnecting layer on top of the second sub-cell.

55. A method according to any one of claims 52 to 54, wherein depositing the first sub-cell comprises:
depositing a second carrier-selective transport layer;
depositing the absorber layer on top of the second carrier-selective transport layer; and
depositing a first carrier-selective transport layer on top of the absorber layer.

56. A method according to claim 55, wherein the first carrier-selective transport layer is the ultrathin hole-transport layer.

57. A method according to claim 55, wherein the second carrier-selective transport layer is the ultrathin hole-transport layer.

58. A method of fabricating a photovoltaic cell according to claim 56, wherein depositing of the second carrier-selective transport layer comprises:
depositing an initial sub-layer by Atomic Layer Deposition; and
depositing an upper sub-layer.

59. A method according to claim 57 or 58, wherein said depositing of the first sub-cell comprises:
before depositing the absorber layer, annealing the second carrier-selective transport layer.

60. A method of fabricating a photovoltaic cell according to any one of claims 55 to 59, wherein depositing of the first sub-cell comprises:
fabricating a transparent conductor layer on top of the first carrier-selective transport layer; and
depositing a top electrode on the transparent conductor layer.

61. A method according to claim 55 to 60, wherein said depositing of first sub-cell comprises:
before depositing the absorber layer, depositing a second passivating layer on the second carrier-selective transport layer so that said second passivating layer is between the first carrier-selective transport layer and the absorber layer; and/or
before depositing the first carrier-selective transport layer, depositing a first passivating layer on the absorber layer so that said first passivating layer is between the absorber layer and the second carrier-selective transport layer.

62. A method according to claim 60 or 61, wherein said depositing of the first sub-cell comprises:
before fabricating the transparent conductor layer, depositing a buffer layer on the first carrier-selective transport layer so that said buffer layer is between the first carrier-selective transport layer and the transparent conductor layer.

63. A method according to any one of claims 52 to 62, wherein said providing of the second sub-cell comprises:
providing a crystalline silicon substrate;
depositing an upper carrier-selective transport layer on top of the crystalline silicon substrate;
depositing a lower carrier-selective transport layer below the crystalline silicon substrate; and
depositing a lower electrode layer on the lower carrier-selective transport layer.

64. A method according to claim 63, comprising, after providing the crystalline silicon substrate, passivating the crystalline silicon substrate so that:
upper and lower passivating layers are provided on each side of the crystalline silicon substrate;
the upper passivating layer is between the crystalline silicon substrate and the upper carrier-selective transport layer; and
the lower passivating layer is between the crystalline silicon substrate and the lower carrier-selective transport layer.

65. A method of fabricating a photovoltaic cell, said cell comprising:
an absorber layer comprising a perovskite material, said absorber layer having a valence band with a first energy level;
a hole-transport layer, said hole-transport layer having a valence band with a second energy level; and
a protective layer having a valence band with an energy level that is between the first and second energy levels,
said method comprising:
depositing the hole-transport layer such that said hole-transport layer is located above or below the absorber layer in the photovoltaic cell; and
depositing the protective layer so that said protective layer is located between the absorber layer and the hole-transport layer.

66. A method according to claim 65, wherein depositing the hole-transport layer comprises a thermal evaporation process.

67. A method according to claim 66, wherein the hole transport layer is an ultrathin hole-transport layer.

68. A method according to claim 67, comprising controlling the thickness of the ultra-thin layer deposited, wherein the ultrathin hole-transport layer is deposited at a deposition rate and controlling deposition of the ultrathin hole-transport layer comprises monitoring the deposition rate.

69. A method according to any one of claims 65 to 68, wherein depositing the protective layer comprises a spin-coating process.

70. A method according to any one of claims 65 to 69, comprising:
depositing a bottom electrode layer on a substrate;
depositing a second carrier-selective transport layer on top of the bottom electrode layer;
depositing the absorber layer on top of the second carrier layer;
depositing the protective layer on top of the absorber layer; and
depositing a first carrier-selective transport layer on top of the protective layer;
wherein one of the first carrier-selective transport layer or the second carrier-selective transport layer is the hole-transport layer.

71. A method according to any one of claims 65 to 69, wherein said photovoltaic cell is a tandem cell, said method comprising:
providing a second sub-cell,
depositing a first sub-cell on top of the second sub-cell, said first sub-cell comprising:
the absorber layer;
the hole-transport layer; and
the protective layer.

72. A method according to claim 71, wherein the first sub-cell is deposited directly on top of the second sub-cell.

73. A method according to claim 71, comprising, before depositing first sub-cell, depositing an interconnecting layer on top of the second sub-cell.

74. A method according to any one of claims 71 to 73, wherein depositing the first sub-cell comprises:
depositing a second carrier-selective transport layer;
depositing the absorber layer on top of the second carrier-selective transport layer; and
depositing a first carrier-selective transport layer on top of the absorber layer.

75. A method according to claim 74, wherein the second carrier-selective transport layer is the hole-transport layer.

76. A method according to claim 75, wherein said depositing of first sub-cell comprises:
before depositing the absorber layer, depositing a second passivating layer on the protective layer so that said second passivating layer is between the protective layer and the absorber layer; and/or
before depositing a first carrier-selective transport layer, depositing a first passivating layer on the absorber layer so that said first passivating layer is between the absorber layer the first carrier-selective transport layer.

77. A method according to claim 74, wherein the first carrier-selective transport layer is the hole-transport layer.

78. A method according to claim 77, wherein said depositing of first sub-cell comprises:
before depositing the absorber layer, depositing a second passivating layer on the second carrier-selective transport layer so that said second passivating layer is between the second carrier-selective transport layer and the absorber layer; and/or
before depositing the protective layer, depositing a first passivating layer on the absorber layer so that said first passivating layer is between the absorber layer the protective layer.

79. A method according to claim 77 or 78, wherein depositing of the second carrier-selective transport layer comprises:
depositing an initial sub-layer by Atomic Layer Deposition; and
depositing an upper sub-layer.

80. A method according to claim 77, 78 or 79, wherein said depositing of the first sub-cell comprises:
before depositing the absorber layer, annealing the second carrier-selective transport layer.

81. A method according to any one of claims 74 to 80, wherein depositing of the first sub-cell comprises:
fabricating a transparent conductor layer on top of the first carrier-selective transport layer; and
depositing a top electrode on the transparent conductor layer.

82. A method according to claim 81, wherein said depositing of the first sub-cell comprises:
before fabricating the transparent conductor layer, depositing a buffer layer on the first carrier-selective transport layer so that said buffer layer is between the first carrier-selective transport layer and the transparent conductor layer.

83. A method according to any one of claims 71 to 82, wherein said providing of the second sub-cell comprises:
providing a crystalline silicon substrate;
depositing an upper carrier-selective transport layer on top of the crystalline silicon substrate;
depositing a lower carrier-selective transport layer below the crystalline silicon substrate; and
depositing a lower electrode layer on the lower carrier-selective transport layer.

84. A method according to claim 83, comprising, after providing the crystalline silicon substrate, passivating the crystalline silicon substrate so that:
upper and lower passivating layers are provided on each side of the crystalline silicon substrate;
the upper passivating layer is between the crystalline silicon substrate and the upper carrier-selective transport layer; and
the lower passivating layer is between the crystalline silicon substrate and the lower carrier-selective transport layer.

85. A method of fabricating a photovoltaic cell, comprising:
providing a precursor comprising:
a lower carrier-selective transport layer
a crystalline silicon substrate; and
an upper carrier-selective transport layer;
depositing a barrier layer on one or both of the lower carrier-selective transport layer and the upper carrier-selective transport layer; and
fabricating an electrode on the or each barrier layer, said barrier layer being configured to suppress diffusion of metal from the electrode into layers of the precursor.

86. A method according to claim 85, wherein depositing the barrier layer comprises an Atomic Layer Deposition process.

87. A method according to claim 85 or 86, wherein said photovoltaic cell is a tandem cell, said method comprising:
providing a second sub-cell, said providing comprising:
providing the precursor; and
depositing a first sub-cell on top of the second sub-cell.

88. A method according to claim 87, wherein depositing of the first sub-cell is performed in accordance with a method of any one of claims 52 to 64 and 71 to 84.

89. A method of fabricating a doped precursor for use in fabricating a photovoltaic cell, said method comprising:
providing an initial precursor comprising first and second polycrystalline silicon layers with a crystalline silicon substrate therebetween; and
subjecting the initial precursor to a doping process to form a doped precursor, said doping process comprising:
doping the first polycrystalline silicon layer with a first dopant using a thermal diffusion process to produce a first doped layer; and
arranging the precursor in a back-to-back configuration with another precursor so that the first doped layers of each precursor are abutting;
when in back-to-back configuration, doping the second polycrystalline silicon layer with a second dopant using a thermal diffusion process to produce a second doped layer;
wherein the first dopant is one of a p-type dopant or a n-type dopant and the second dopant is the other of a p-type dopant or a n-type dopant.

90. A method according to claim 89, further comprising: before doping the first polycrystalline silicon layer, annealing the first and second polycrystalline silicon layers in an inert atmosphere.

91. A method according to claim 89 or 90, wherein the first dopant is the p-type dopant and the second dopant is the n-type dopant.

92. A method of fabricating a doped precursor for use in fabricating a photovoltaic cell, said method comprising:
providing an initial precursor comprising first and second polycrystalline silicon layers with a crystalline silicon substrate therebetween;
annealing the first and second polycrystalline silicon layers in an inert atmosphere; and
after annealing, subjecting the initial precursor to a doping process to form a doped precursor, said doping process comprising:
doping the first polycrystalline silicon layer with a first dopant to produce a first doped layer; and
doping the second polycrystalline silicon layer with a second dopant to produce a second doped layer
wherein the first dopant is one of a p-type dopant or a n-type dopant and the second dopant is the other of a p-type dopant or a n-type dopant.

93. A method according to claim 91 or 92, wherein the annealing is performed at a temperature of from about 900° C. to about 1100° C. for about 5 mins to about 120 mins.

94. A method according to claim 91, 92 or 93, wherein the annealing is performed at a temperature of about 1000° C.

95. A method according to any one of claims 91 to 94, wherein the annealing is performed for about 60 mins.

96. A method according to claim 92 or any one of claims 93 to 95 when dependent from claim 92, wherein:
doping the first polycrystalline silicon layer comprises subjecting the first polycrystalline silicon layer to a thermal diffusion process using a p-type dopant to produce a p-type doped layer;
doping the second polycrystalline silicon layer comprises subjecting the second polycrystalline silicon layer to a thermal diffusion process using a n-type dopant to produce a n-type doped layer; and
the doping of the first polycrystalline silicon layer is performed before doping the second polycrystalline silicon layer.

97. A method according to any one of claims 89 to 96, wherein:
doping of the first polycrystalline silicon layer is performed before doping the second polycrystalline silicon layer; and
doping of the first polycrystalline silicon layer is performed such that a first dopant glass formed on the first polycrystalline silicon layer provides a masking layer.

98. A method according to any one of claims 89 to 96, wherein doping of the first polycrystalline silicon layer is performed before doping the second polycrystalline silicon layer; and said method further comprises:
between doping of the first and second polycrystalline silicon layers, forming a dielectric layer on the first polycrystalline silicon layer to provide a masking layer.

99. A method according to claim 98, wherein said dielectric layer is SiO₂.

100. A method according to any one of claims 89 to 99, wherein the first dopant is the p-type dopant and doping the first polycrystalline silicon layer comprises:
diffusing the p-type dopant at a temperature of between about 850° C. to about 1050° C. for about 15 mins to about 60 mins; and
subjecting the first polycrystalline silicon layer to a thermal dopant drive-in process at a temperature of between about 850° C. to about 1050° C. for up to about 60 mins.

101. A method according to claim 100, wherein diffusing the p-type dopant is performed at a temperature of about 980° C.

102. A method according to claim 100 or 101, wherein diffusing the p-type dopant is performed for about 25 mins.

103. A method according to claim 100, 101 or 102, wherein the thermal dopant drive-in process is performed at a temperature of about 980° C.

104. A method according to any one of claims 100 to 103, wherein the thermal dopant drive-in process is performed for about 25 mins.

105. A method according to any one of claims 89 to 104, wherein the second dopant is the n-type dopant and doping the second polycrystalline silicon layer comprises:
diffusing the n-type dopant at a temperature of between about 800° C. to about 1050° C. for about 15 mins to about 60 mins; and
subjecting the second polycrystalline silicon layer to a thermal dopant drive-in process at a temperature of between about 800° C. to about 1050° C. for up to about 60 mins.

106. A method according to claim 105, wherein diffusing the n-type dopant is performed at a temperature of about 820° C.

107. A method according to claim 105 or 106, wherein diffusing the n-type dopant is performed for about 25 mins.

108. A method according to claim 105, 106 or 107, wherein the thermal dopant drive-in process is performed at a temperature of about 900° C.

109. A method according to any one of claims 105 to 108, wherein the thermal dopant drive-in process is performed for about 25 mins.

110. A method according to claim 92 or any one of claims 93 to 95 when dependent from claim 92, wherein:
doping the first polycrystalline silicon layer comprises contacting the first polycrystalline silicon layer with a liquid p-type dopant-source; and
doping the second polycrystalline silicon layer comprises contacting the second polycrystalline silicon layer with a liquid n-type dopant-source.

111. A method according to claim 110, wherein:
contacting the first polycrystalline silicon layer with a liquid p-type dopant-source comprises spin-on coating the first polycrystalline silicon layer with the liquid p-type dopant-source.

112. A method according to claim 110, wherein:
contacting the first polycrystalline silicon layer with a liquid p-type dopant-source comprises spray-on coating the first polycrystalline silicon layer with the liquid p-type dopant-source.

113. A method according to claim 110, 111, or 112, wherein:
contacting the second polycrystalline silicon layer with a liquid n-type dopant-source comprises spin-on coating the second polycrystalline silicon layer with the liquid n-type dopant-source.

114. A method according to claim 110, 111, or 112, wherein:
contacting the second polycrystalline silicon layer with a liquid n-type dopant-source comprises spray-on coating the second polycrystalline silicon layer with the liquid n-type dopant-source.

115. A method according to any one of claims 110 to 114, wherein:
after contacting the first polycrystalline silicon layer with a liquid p-type dopant-source, doping the first polycrystalline silicon layer comprises:
subjecting the first polycrystalline silicon layer to a first annealing at a first temperature of between about 80° C. to about 150° C. for about 10 mins to about 30 mins; and
after the first annealing, subjecting the first polycrystalline silicon layer to a second annealing at a second temperature of between about 150° C. to about 250° C. for about 5 mins to 60 mins.

116. A method according to claim 115, wherein the first annealing is performed at a temperature of about 110° C.

117. A method according to claim 115 or 116, wherein the first annealing is performed for about 15 mins.

118. A method according to claim 115, 116 or 117, wherein the second annealing is performed at a temperature of about 200° C.

119. A method according to any one of claims 115 to 118, wherein the second annealing is performed for about 8 mins.

120. A method according to any one of claims 115 to 119, wherein the first annealing and/or the second annealing is performed in an oxygen-containing atmosphere.

121. A method according to any one of claims 110 to 120, wherein:
after contacting the second polycrystalline silicon layer with a liquid n-type dopant-source, doping the second polycrystalline silicon layer comprises:
subjecting the second polycrystalline silicon layer to a third annealing at a third temperature of between about 80° C. to about 150° C. for about 10 mins to about 30 mins; and
after the third annealing, subjecting the second polycrystalline silicon layer to a fourth annealing at a fourth temperature of between about 150° C. to about 250° C. for about 5 mins to about 60 mins.

122. A method according to claim 121, wherein the third annealing is performed at a temperature of about 110° C.

123. A method according to claim 121 or 122, wherein the third annealing is performed for about 15 mins.

124. A method according to claim 121, 122 or 123, wherein the fourth annealing is performed at a temperature of about 200° C.

125. A method according to any one of claims 121 to 124, wherein the fourth annealing is performed for about 8 mins.

126. A method according to any one of claims 121 to 125, wherein the third annealing and/or the fourth annealing is performed in an oxygen-containing atmosphere.

127. A method according to any one of claims 110 to 126, wherein the doping of the second polycrystalline silicon layer is performed before doping the first polycrystalline silicon layer.

128. A method according to claim 127, comprising:
after doping of the second polycrystalline silicon layer and before doping the first polycrystalline silicon layer, subjecting the precursor to an intermediate annealing in an inert atmosphere.

129. A method according to claim 128, wherein the intermediate annealing is performed at a temperature of from about 350° C. to about 550° C. for about 10 mins to about 60 mins.

130. A method according to claim 128 or 129, wherein the intermediate annealing is performed at a temperature of about 450° C.

131. A method according to claim 128, 4129, or 130, wherein the intermediate annealing is performed for about 25 mins.

132. A method according to any one of claims 89 to 131, wherein providing the initial precursor comprises:
depositing the first and second polycrystalline silicon layers on the crystalline silicon substrate.

133. A method according to claim 132, wherein the depositing is performed using low pressure chemical vapor deposition.

134. A method according to claim 132 or 133, wherein the depositing is performed at a temperature of from about 500° C. to about 650° C. for about 15 mins to about 120 mins.

135. A method according to claim 132, 133, or 134, wherein the depositing is performed at a temperature of about 570° C.

136. A method according to any one of claims 89 to 135, wherein each of the first polycrystalline layer and the second polycrystalline layer has a thickness of about 15 to about 150 nm.

137. A method according to any one of claims 89 to 136, wherein providing the initial precursor comprises passivating the crystalline silicon substrate so that:
passivating layers are provided on each side of the crystalline silicon substrate;
a first passivating layer is between the crystalline silicon substrate and the first polycrystalline silicon layer; and
a second passivating layer is between the crystalline silicon substrate and the second polycrystalline silicon layer.

138. A method according to any one of claims 89 to 137, wherein the p-type dopant is boron.

139. A method according to any one of claims 89 to 138, wherein the n-type dopant is phosphorus.

140. A method according to any one of claims 89 to 139, further comprising, after the doping process:
subjecting either or each of the first doped layer and the second doped layer to a hydrogen passivation process.

141. A method according to claim 140, wherein the hydrogen passivation process comprises:
depositing one or more hydrogen-containing dielectric layers on either or each of the first doped layer and the second doped layer;
subjecting the one or more hydrogen-containing dielectric layers to a thermal annealing step or a firing step to effect hydrogenation of the layer on which said one or more hydrogen-containing dielectric layers is deposited; and
removing the one or more hydrogen-containing dielectric layers from the doped precursor.

142. A method according to claim 141, wherein the one or more hydrogen-containing dielectric layers comprises a first hydrogen-containing dielectric layer and a second hydrogen-containing dielectric layer; wherein:
a first hydrogen-containing dielectric layer is deposited on either or each of the first doped layer and the second doped layer; and
a second first hydrogen-containing dielectric layer is deposited on the or each first hydrogen-containing dielectric layer.

143. A method according to claim 142, wherein the first hydrogen-containing dielectric layer comprises Al₂O₃ and the second hydrogen-containing dielectric layer comprises SiNₓ.

144. A method of fabricating a photovoltaic cell, said method comprising:
providing a doped precursor, said doped precursor fabricated according to the method of any one of claims 89 to 143; and
depositing an electrode layer on one of the p-type doped layer and the n-type doped layer.

145. A method of fabricating a tandem photovoltaic cell, said method comprising:
fabricating a second sub-cell using a doped precursor fabricated according to the method of any one of claims 89 to 143 such that said second sub-cell comprises, in order relative to incident light said photovoltaic cell is configured to receive:
an upper carrier-selective transport layer
the crystalline silicon substrate; and
a lower carrier-selective transport layer;
wherein the upper carrier-selective transport layer comprises one of the p-type doped layer or the n-type doped layer and the lower carrier-selective transport layer comprises the other of the p-type doped layer or the n-type doped layer; and
depositing a first sub-cell on top of the second sub-cell.

146. A method of fabricating a tandem photovoltaic cell, said method comprising:
fabricating a second sub-cell such that said second sub-cell comprises, in order relative to incident light said tandem photovoltaic cell is configured to receive:
an upper carrier-selective transport layer
a crystalline silicon substrate; and
a lower carrier-selective transport layer;
said fabricating comprising:
providing an initial precursor comprising first and second polycrystalline silicon layers with the crystalline silicon substrate therebetween; and
subjecting the initial precursor to a doping process to form a doped precursor, said doping process comprising:
doping the first polycrystalline silicon layer with a p-type dopant to produce a p-type doped layer, said doping comprising contacting the first polycrystalline silicon layer with a liquid p-type dopant-source; and
doping the second polycrystalline silicon layer with a n-type dopant to produce a n-type doped layer, said doping comprising contacting the second polycrystalline silicon layer with a liquid n-type dopant-source;
wherein the upper carrier-selective transport layer comprises one of the p-type doped layer or the n-type doped layer and the lower carrier-selective transport layer comprises the other of the p-type doped layer or the n-type doped layer; and
depositing a first sub-cell on top of the second sub-cell.

147. A method according to claim 146, comprising, before subjecting the initial precursor to the doping process, annealing the first and second polycrystalline silicon layers in an inert atmosphere.

148. A method according to claim 147, wherein the annealing is performed at a temperature of between from about 900° C. to about 1100° C. for about 5 mins to about 120 mins.

149. A method according to claim 147 or 148, wherein the annealing is performed at a temperature of about 1000° C.

150. A method according to claim 147, 148 or 149, wherein the annealing is performed for about 60 mins.

151. A method according to any one of claims 146 to 150, wherein:
contacting the first polycrystalline silicon layer with a liquid p-type dopant-source comprises spin-on coating the first polycrystalline silicon layer with the liquid p-type dopant-source.

152. A method according to any one of claims 146 to 150, wherein:
contacting the first polycrystalline silicon layer with a liquid p-type dopant-source comprises spray-on coating the first polycrystalline silicon layer with the liquid p-type dopant-source.

153. A method according to any one of claims 146 to 152, wherein:
contacting the second polycrystalline silicon layer with a liquid n-type dopant-source comprises spin-on coating the second polycrystalline silicon layer with the liquid n-type dopant-source.

154. A method according to any one of claims 146 to 152, wherein:
contacting the second polycrystalline silicon layer with a liquid n-type dopant-source comprises spray-on coating the second polycrystalline silicon layer with the liquid n-type dopant-source.

155. A method according to any one of claims 146 to 154, wherein:
after contacting the first polycrystalline silicon layer with a liquid p-type dopant-source, doping the first polycrystalline silicon layer comprises:
subjecting the first polycrystalline silicon layer to a first annealing at a first temperature of between about 80° C. to about 150° C. for about 10 mins to about 30 mins; and
after the first annealing, subjecting the first polycrystalline silicon layer to a second annealing at a second temperature of between about 150° C. to about 250° C. for about 5 mins to 60 mins.

156. A method according to claim 155, wherein the first annealing is performed at a temperature of about 110° C.

157. A method according to claim 155 or 156, wherein the first annealing is performed for about 15 mins.

158. A method according to claim 155, 156 or 157, wherein the second annealing is performed at a temperature of about 200° C.

159. A method according to any one of claims 155 to 158, wherein the second annealing is performed for about 8 mins.

160. A method according to any one of claims 155 to 159, wherein the first annealing and/or the second annealing is performed in an oxygen-containing atmosphere.

161. A method according to any one of claims 146 to 160, wherein:
after contacting the second polycrystalline silicon layer with a liquid n-type dopant-source, doping the second polycrystalline silicon layer comprises:
subjecting the second polycrystalline silicon layer to a third annealing at a third temperature of between about 80° C. to about 150° C. for about 10 mins to about 30 mins; and
after the third annealing, subjecting the second polycrystalline silicon layer to a fourth annealing at a fourth temperature of between about 150° C. to about 250° C. for about 5 mins to about 60 mins.

162. A method according to claim 161, wherein the third annealing is performed at a temperature of about 110° C.

163. A method according to claim 161 or 162, wherein the third annealing is performed for about 15 mins.

164. A method according to claim 161, 162, or 163, wherein the fourth annealing is performed at a temperature of about 200° C.

165. A method according to any one of claims 161 to 164, wherein the fourth annealing is performed for about 8 mins.

166. A method according to any one of claims 161 to 165, wherein the third annealing and/or the fourth annealing is performed in an oxygen-containing atmosphere.

167. A method according to any one of claims 146 to 166, wherein the doping of the second polycrystalline silicon layer is performed before doping the first polycrystalline silicon layer.

168. A method according to claim 167, comprising:
after doping of the second polycrystalline silicon layer and before doping the first polycrystalline silicon layer, subjecting the precursor to an intermediate annealing in an inert atmosphere.

169. A method according to claim 168, wherein the intermediate annealing is performed at a temperature of from about 350° C. to about 550° C. for about 10 mins to about 60 mins.

170. A method according to claim 168 or 169, wherein the intermediate annealing is performed at a temperature of about 450° C.

171. A method according to claim 168, 169, or 170, wherein the intermediate annealing is performed for about 25 mins.

172. A method according to any one of claims 146 to 171, wherein providing the initial precursor comprises:
depositing the first and second polycrystalline silicon layers on the crystalline silicon substrate.

173. A method according to claim 172, wherein the depositing is performed using low pressure chemical vapor deposition.

174. A method according to claim 172 or 173, wherein the depositing is performed at a temperature of from about 500° C. to about 650° C. for about 15 mins to about 120 mins.

175. A method according to claim 172, 173, or 174, wherein the depositing is performed at a temperature of about 570° C.

176. A method according to any one of claims 146 to 175, wherein each of the first polycrystalline layer and the second polycrystalline layer has a thickness of about 15 to about 150 nm.

177. A method according to any one of claims 146 to 176, wherein providing the initial precursor comprises passivating the crystalline silicon substrate so that:
passivating layers are provided on each side of the crystalline silicon substrate;
a first passivating layer is between the crystalline silicon substrate and the first polycrystalline silicon layer; and
a second passivating layer is between the crystalline silicon substrate and the second polycrystalline silicon layer.

178. A method according to any one of claims 146 to 177, wherein the p-type dopant is boron.

179. A method according to any one of claims 146 to 178, wherein the n-type dopant is phosphorus.

180. A method according to any one of claims 146 to 179, further comprising, after the doping process:
subjecting either or each of the first doped layer and the second doped layer to a hydrogen passivation process.

181. A method according to claim 180, wherein the hydrogen passivation process comprises:
depositing one or more hydrogen-containing dielectric layers on either or each of the first doped layer and the second doped layer;
subjecting the one or more hydrogen-containing dielectric layers to a thermal annealing step or a firing step to effect hydrogenation of the layer on which said one or more hydrogen-containing dielectric layers is deposited; and
removing the one or more hydrogen-containing dielectric layers from the doped precursor.

182. A method according to claim 181, wherein the one or more hydrogen-containing dielectric layers comprises a first hydrogen-containing dielectric layer and a second hydrogen-containing dielectric layer; wherein:
a first hydrogen-containing dielectric layer is deposited on either or each of the first doped layer and the second doped layer; and
a second first hydrogen-containing dielectric layer is deposited on the or each first hydrogen-containing dielectric layer.

183. A method according to claim 182, wherein the first hydrogen-containing dielectric layer comprises Al₂O₃ and the second first hydrogen-containing dielectric layer comprises SiNₓ.

184. A method according to any one of claims 145 to 183, wherein the first sub-cell is deposited directly onto an upper carrier-selective transport layer of the second sub-cell.

185. A method according to any one of claims 145 to 184, comprising, before depositing the first sub-cell, depositing an interconnecting layer onto an upper carrier-selective transport layer of the second sub-cell.

186. A method according to any one of claims 145 to 185, comprising depositing a lower electrode layer on the lower carrier-selective transport layer.

187. A method according to any one of claims 85 to 88, wherein the precursor is a doped precursor fabricated according a method of any one of claims 89 to 143.

188. A method according to any one of claims 145 to 185, wherein:
the first sub-cell is a first sub-cell according to: claim 3 or any one of claims 4 to 14 and 27 to 35 when dependent from claim 3; claim 17 or any one of claims 18 to 35 when dependent from claim 17; or
said method is a method in accordance with any one of claims 52 to 64 or 71 to 84.

189. A method according to any one of claims 145 to 186, wherein:
the photovoltaic cell is a photovoltaic cell according to any one of claims 38 to 47; or
said method is a method in accordance with claim 87 or 88.

190. A method according to claim 144, wherein:
the photovoltaic cell is a photovoltaic cell according to any one of claims 36 to 47; or
said method is a method in accordance with any one of claims 85 to 88.

191. A photovoltaic cell fabricated according to the method of any one of claims 48 to 88 and 144 to 190.
